(19) United States
(12) Patent Application Publication
(10) Pub. No.: US 2023/0002631 A1
(43) Pub. Date: Jan. 5, 2023

(54) WATER-WASHABLE COMPOSITIONS FOR USE IN 3D PRINTING

(71) Applicant: BASF SE, Ludwigshafen am Rhein (DE)

(72) Inventors: Rui DING, Shanghai (CN); Li CHEN, Shanghai (CN)

(21) Appl. No.: 17/774,496

(22) PCT Filed: Oct. 19, 2020
(86) PCT No.: PCT/EP2020/079382

§ 371 Date: May 5, 2022

(30) Foreign Application Priority Data
Nov. 7, 2019 (CN) PCT/CN2019/116329

(51) Int. Cl. C09D 11/101; C08F 220/58; C08F 220/34; C08F 220/28; C08F 226/06; C09D 11/107; B33Y 70/00; B33Y 10/00; B33Y 40/20; B29C 64/129; B29C 64/35

(52) U.S. Cl. CPC C09D 11/101; C08F 220/58; C08F 220/343; C08F 220/282; C08F 226/06; C09D 11/107; B33Y 70/00; B33Y 10/00; B33Y 40/20; B29C 64/129; B29C 64/35; C08F 2800/20; B29K 2105/0085

(57) ABSTRACT

The present invention relates to radiation curable compositions, comprising (A1) at least one water-soluble reactive diluent (A1); (A2) at least one water-soluble reactive oligomer (A2); (B) at least one reactive component selected from the group consisting of a water insoluble reactive diluent (B1a), a slightly water-soluble reactive diluent (B1b) and a water insoluble, or slightly water-soluble reactive oligomer (B2); and (C) optionally a photoinitiator (C), wherein the amount of component (A1) and (A2) is greater than 20% by weight, especially 30% by weight based on the amount of components (A1), (A2), (B1a), (B1b) and (B2) and the amount of components (B1a), (B1b) and (B2) is greater than 10% by weight, especially 20% by weight based on the amount of components (A1), (A2), (B1a), (B1b) and (B2); radiation curable composition, comprising (A1′) at least one slightly water-soluble reactive diluent (B1b); (A2) at least one water-soluble reactive oligomer (A2); (B) at least one reactive component selected from the group consisting of a water insoluble reactive diluent (B1a) and a water insoluble, or slightly water-soluble reactive oligomer (B2); and (C) optionally a photoinitiator (C), wherein the amount of component (B1b) and (A2) is greater than 40% by weight, especially 50% by weight based on the amount of components (A2), (B1a), (B1b) and (B2) and the amount of components (B1a), (B1b) and (B2) is greater than 10% by weight, especially 20% by weight based on the amount of components (A2), (B1a), (B1b) and (B2). The radiation curable compositions can be cleaned by pure water with no assistance of any solvent or detergent. The printed three-dimensional products have clean, smooth, tack-free surface after washing with water and sufficient post-curing. The fully cured three-dimensional products are high-temperature resistant and have excellent mechanical performance above glass transition temperature, e.g. 200° C.

The present invention relates to radiation curable compositions, comprising

(A1) at least one water-soluble reactive diluent (A1);

(A2) at least one water-soluble reactive oligomer (A2);

(B) at least one reactive component selected from the group consisting of a water insoluble reactive diluent (B1a), a slightly water-soluble reactive diluent (B1b) and a water insoluble, or slightly water-soluble reactive oligomer (B2); and

(C) optionally a photoinitiator (C), wherein the amount of component (A1) and (A2) is greater than 20% by weight, especially 30% by weight based on the amount of components (A1), (A2), (B1a), (B1b) and (B2) and the amount of components (B1a), (B1b) and (B2) is greater than 10% by weight, especially 20% by weight based on the amount of components (A1), (A2), (B1a), (B1b) and (B2); radiation curable composition, comprising

(A1′) at least one slightly water-soluble reactive diluent (B1b);

(A2) at least one water-soluble reactive oligomer (A2);

(B) at least one reactive component selected from the group consisting of a water insoluble reactive diluent (B1a) and a water insoluble, or slightly water-soluble reactive oligomer (B2); and

(C) optionally a photoinitiator (C), wherein the amount of component (B1b) and (A2) is greater than 40% by weight, especially 50% by weight based on the amount of components (A2), (B1a), (B1b) and (B2) and the amount of component (B1a) and (B2) is greater than 10% by weight, especially 20% by weight based on the amount of components (A2), (B1a), (B1b) and (B2).

The radiation curable compositions can be cleaned by pure water with no assistance of any solvent or detergent. The printed three-dimensional products have clean, smooth, tack-free surface after washing with water and sufficient post-curing. The fully cured three-dimensional products are high-temperature resistant and have excellent mechanical performance above glass transition temperature, e.g. 200° C.

U.S. Pat. No. 9,868,871 relates to a water-washable 3D printing resin formulation comprising:

85 percent or more by weight in aggregate of one or more water-soluble ingredients selected from the group comprising an oligomer and monomer

one of at least a (i) photinitiator; (ii) photo acid generator and (iii) photosensitizer;

one or more of a: (i) light blocker and (ii) water-soluble filler; and

wherein any uncured or partially-cured said water-washable 3D printing resin on surfaces of a printed 3D object may be washed away with water.

U.S. Pat. No. 9,944,804 relates to a water-washable 3D printing resin formulation comprising:

1 percent or more by weight in aggregate of one or more water-dispersible ingredients selected from the group comprising an oligomer and monomer

1 percent or more by weight in aggregate of one or more water-insoluble ingredients selected from the group comprising an oligomer and monomer;

one or more of a: (i) photoinitiator and (ii) light blocker; and

wherein, responsive to water being added, said water-dispersible ingredients wrap and carry away any uncured water-insoluble ingredients in micelles or lipozomes.

U.S. Pat. No. 9,944,805 relates to a water-washable 3D printing resin formulation comprising:

about 75 percent or more by weight of one or more water-soluble ingredients selected from the group comprising an oligomer and monomer;

about 5 percent or more by weight of one or more water-dispersible ingredients selected from the group comprising an oligomer and monomer; and

one or more of a: (i) photoinitiator; (ii) light blocker; (iii) photo acid generator, (iv) photosensitizer; and (v) filler.

JP5247134A2 relates to a composition comprising

(A) an epoxy(meth)acrylate of formula

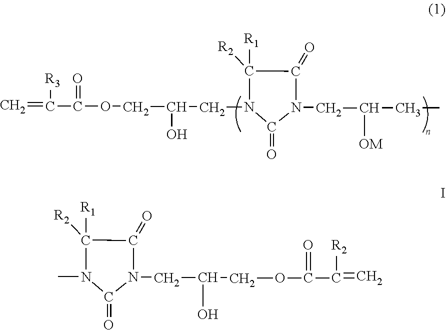

(R₁ and R₂ are H or C₁₋₄alkyl; R₃ is H or methyl; (n) is 1 or greater than or equal to 1 integer; M is H or group of formula II),

(B) a water-soluble reactive monomer (e.g. N-vinylpyrrolidone) as a diluent and

(C) a photopolymerizable initiator (e.g. 2-hydroxy-2-methylpropiophenone).

U.S. Pat. No. 9,861,452 relates to a liquid radiation curable resin composition comprising, relative to the total weight of the composition:

(a) from about 50 to about 80 wt percent of an epoxy component comprising at least two different epoxy-containing compounds, said epoxy component further comprising: a cycloaliphatic epoxy-containing compound, and an epoxy compound having an aromatic glycidyl ether group;

(b) from about 5 to about 30 wt percent of an oxetane component;

(c) a (meth)acrylate component;

(d) a cationic photoinitiator; and

(e) a free-radical photoinitiator;

wherein at least 25 wt percent of the epoxy component is the cycloaliphatic epoxy-containing compound;

wherein the resin liquid radiation curable resin composition has a viscosity of between about 75 and about 300 cps at 30 degrees Celsius; and

wherein the oxetane component consists essentially of mono-functional oxetane compounds.

WO04055123 (CN100473701C) relates to a single phase, energy curable varnish composition comprising: (a) water-soluble ethylenically unsaturated reactive oligomers and monomers; (b) water insoluble ethylenically unsaturated reactive oligomers and monomers; and (c) a resin selected from the group consisting of a water-soluble non-reactive resin, a water insoluble acid or base functional resin and water insoluble ethylenically unsaturated reactive resin, wherein said water insoluble resins contain acid functional groups.

CN107501477A relates to a photocurable material for 3D inkjet printing, and a preparation method thereof, and a printing method, wherein the photocurable material comprises, by weight, 50-98 parts of a monofunctional monomer, 1-50 parts of a linear nonionic water-soluble polymer, 0-20 parts of a polar organic solvent, 0.1-5 parts of a photoinitiator, and 0.5-10 parts of an auxiliary agent. The photocurable material can be used for 3D inkjet printing so as to print the support part, wherein the support part can be removed in the water or the aqueous liquid so as not to affect the precision of the target 3D object.

JPO2111529A relates to a photo-curing resin which is exposed to light to give photo-cured layers, which are laminated into pref. three dimensional construction. Three dimensional mouldings are washed with washing aq. soln. to remove uncured resin remaining on outer surface. As washing soln, surfactant or alkaline aq. soln. or ware are used. Washing is e.g. in washing bath mouldings are dipped in washing soln. under radiating ultrasonics or stirring.

EP0378144A2 relates to liquid resin compositions which are photosensitive comprising

(i) at least one difunctional monomeric or oligomeric acrylate or methacrylate having a viscosity of more than 500 mPas at 25° C.,

(ii) at least one tri-, tetra- or pentaacrylate or -methacrylate selected from the group consisting of the compounds of the formulae

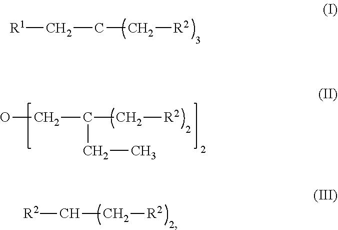

wherein R¹ denotes hydrogen, methyl, hydroxy or a group

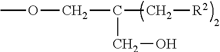

(IV) and R² is a group

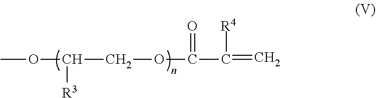

Wherein n is an integer 0, 1, 2 or 3, R³ and R⁴ are each independently of the other hydrogen or methyl, (iii) at least one unsaturated monofunctional monomeric compound of the formula

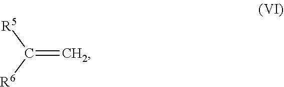

(VI), wherein R⁵ denotes hydrogen or methyl and R⁶ is a group of the formula

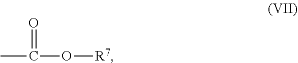

R⁷ being tetrahydrofurfuryl, cyclohexyl, 2-phenoxyethyl, benzyl, isobornyl, glycidyl, dicyclopentenyl, morpholinoethyl, dimethylaminoethyl, diethylaminoethyl or a C₁-C₂₀ linear or branched aliphatic residue, or—if R is hydrogen R denotes additionally pyrrolidinon-2-yl, imidazolyl, carbazolyl, anthracenyl, phenyl, C₅-C₈cycloalkyl, naphthenyl, 2-norbornyl, pyridyl, N-caprolactamyl or toluyl and

(iv) a photo-polymerization initiator for (i), (ii) and/or (iii). In EP450254A1 component (iv) is replaced by anionic dye-iodonium ion compounds, anionic dye-pyrrylium compounds, or cationic dye-borate anion complexes.

EP0425441B1 relates to a liquid, photosensitive mixture containing a) 5-25 percent by weight of a monomeric aliphatic or cycloaliphatic di(meth)acrylate having a molecular weight (MW) of not more than 800, b) 0-15 percent by weight of a monomeric poly(meth)acrylate having a functionality of at least 3 and an MW of not more than 600, c) 0-20 percent by weight of a mono(meth)acrylate or a mono-N-vinyl compound having an MW of not more than 500, d) 20-60 percent by weight of a urethane (meth)acrylate having a functionality of 2 to 4 and an MW of 500 to 10,000, e) 10-50 percent by weight of a monomeric or oligomeric di(meth)acrylate based on bisphenol A or bisphenol F, f) 0.1-10 percent by weight of a photoinitiator and g) 0-5 percent by weight of customary additives, the proportion of the components a) to g) together being 100 percent by weight.

EP0506616B1 relates to a photosensitive liquid mixture comprising

(1) 40 to 60 percent by weight of a urethane (meth)acrylate having a functionality of 2 to 4 and a molecular weight (MW) or 500 to 10,000,

(2) 5 to 40 percent by weight of a hydroxyl-containing aliphatic or cycloaliphatic di(meth)acrylate, (3) 0 to 40 percent by weight of a mono(meth)acrylate or of a mono-N-vinyl compound having a MW of not more than 500,

(4) 0.1 to 10 percent by weight of a photoinitiator,

(5) 0 to 30 percent by weight of an allphatic or cycloaliphatic di(meth)acrylate whlch differs from (2) of an aliphatic tri(meth)acrylate or of an aromatic di- or tri(meth)acrylate, and

(6) 0 to 5 percent by weight of customary additives, such that the proportion of components (1) to (6) together is 100 percent by weight.

JP08183823A relates to a resin comprising:

(a) 100 pts.wt. of unsaturated urethane; and (b) 25-150 pts.wt. of:

(i) N-(meth)acryloyl morpholine; or

(ii) a mixt. contg. N-(meth)acryloyl morpholine and diol di(meth)acrylate.

JP08183824A relates to a resin comprises (a) 100 pts. wt. of unsatd. urethane and (b) 25-150 pts. wt. of (i) N-(meth)acryloyl morpholine or (ii) a mixt. contg. N-(meth)acryloyl morpholine and diol di(meth)acrylate.

JP2019001865 discloses a radiation curable composition which is to be used for stereolithography by an inkjet process and comprises a monofunctional (meth)acrylamide compound (A) having a molecular weight of 200 or less, a (meth)acrylate oligomer (B), and a photopolymerization initiator (C).

EP3309224 relates to an ink composition for use in 3D printing comprising: at least one monofunctional acrylate monomer;

an optional oligomer selected from the group consisting of a difunctional acrylate oligomer, a multifunctional acrylate oligomer and mixtures thereof; and

a photoinitiator.

US2017275486 relates to a curable phase change gellant ink composition comprising: a phase change ink vehicle comprising at least one acrylate monomer, oligomer, or prepolymer;

acryloylmorpholine;

at least one gellant, wherein the gellant is miscible with the phase change ink vehicle;

a photoinitiator; and

an optional colorant.

The majority of radiation curable monomers and oligomers used in 3D printable resin formulations are insoluble in water. The residual resin after 3D printing usually has to be cleaned by organic solvents like isopropanol, ethanol and acetone, which cause many concerns including VOC, risks of handling flammable substances, and hazardous disposal etc. Water washable resins currently available have poor water washability (some need the aid of detergent or surfactant) and weak mechanical and thermal performance.

It is the object of the present invention to provide water washable compositions for use in 3D printing which result in printed three-dimensional products which have clean, smooth, tack-free surface after washing with water and sufficient post-curing and desired mechanical properties.

Accordingly, the present invention relates to radiation curable compositions, comprising

(A1) at least one water-soluble reactive diluent (A1);

(A2) at least one water-soluble reactive oligomer (A2);

(B) at least one reactive component selected from the group consisting of a water insoluble reactive diluent (B1a), a slightly water-soluble reactive diluent (B1b) and a water insoluble, or slightly water-soluble reactive oligomer (B2); and

(C) optionally a photoinitiator (C), wherein the amount of component (A1) and (A2) is greater than 20% by weight, especially 30% by weight based on the amount of components (A1), (A2), (B1a), (B1b) and (B2) and the amount of components (B1a), (B1b) and (B2) is greater than 10% by weight, especially 20% by weight based on the amount of components (A1), (A2), (B1a), (B1b) and (B2).

In another embodiment, the present invention relates to radiation curable compositions, comprising

(A1′) at least one slightly water-soluble reactive diluent (B1b);

(A2) at least one water-soluble reactive oligomer (A2);

(B) at least one reactive component selected from the group consisting of a water insoluble reactive diluent (B1a) and a water insoluble, or slightly water-soluble reactive oligomer (B2); and

(C) optionally a photoinitiator (C), wherein the amount of component (B1b) and (A2) is greater than 40% by weight, especially 50% by weight based on the amount of components (A2), (B1a), (B1b) and (B2) and the amount of component (B1a) and (B2) is greater than 10% by weight, especially 20% by weight based on the amount of components (A2), (B1a), (B1b) and (B2).

In said embodiment the amount of slightly water-soluble reactive diluent (B1b) is preferably greater than 20% by weight. The amount of water-soluble reactive oligomer (A2) is preferably greater than 20% by weight based on the amount of components (A2), (B1a), (B1b) and (B2).

The amount of slightly water-soluble reactive diluent (B1b) and water-soluble reactive oligomer (A2) is more preferably greater than 70% by weight based on the amount of components (A2), (B1a), (B1b) and (B2).

Printed three-dimensional products according to the present invention have clean, smooth, tack-free surface after washing with water and sufficient post-curing. The formulation can be cleaned by pure water with no assistance of any solvent or detergent. The fully cured three-dimensional products are high-temperature resistant and have excellent mechanical performance above glass transition temperature, e.g. 200° C., a tensile strength of 30 to 80 MPa, a tensile modulus 1800-3500 MPa, elongation at break of 2-20%, a T₉ by DMA of 70-170° C.

The fully cured three-dimensional products
are not soluble in water,
may have low water absorption, and/or
have a storage modulus E′ (which is measured by dynamic mechanical analyzer (DMA) and can be used as a parameter to evaluate the stiffness of a material at high temperature) higher than 10 MPa above glass transition temperature, e.g. 200° C., and, hence, may be used as high-temperature resistant functional parts.

The radiation curable composition is preferably a photocurable composition.

Accordingly, the present invention relates to photocurable compositions, comprising

(A1) at least one water-soluble reactive diluent;

(A2) at least one of a water-soluble oligomer;

(B) at least one of a water insoluble, or slightly water-soluble reactive diluent (1) or a water insoluble, or slightly water-soluble reactive oligomer (B2); and

(C) a photoinitiator (C), wherein the amount of component (A1) and (A2) is greater than 20% by weight, especially 30% by weight based on the amount of components (A1), (A2), (1) and (B2) and the amount of components (B1a), (B1b) and (B2) is greater than 10% by weight, especially 20% by weight based on the amount of components (A1), (A2), (1) and (B2); or to photocurable compositions, comprising

(A1′) at least one slightly water-soluble reactive diluent (B1b);

(A2) at least one water-soluble reactive oligomer (A2);

(B) at least one reactive component selected from the group consisting of a water insoluble reactive diluent (B1a) and a water insoluble, or slightly water-soluble reactive oligomer (B2); and

(C) a photoinitiator (C), wherein the amount of component (B1b) and (A2) is greater than 20% by weight, especially 30% by weight based on the amount of components (A2), (B1a), (B1b) and (B2) and the amount of component (B1a) and (B2) is greater than 10% by weight, especially 20% by weight based on the amount of components (A2), (B1a), (B1b) and (B2).

The radiation curable, especially photocurable compositions of the present invention are preferably water-washable. Hot water could improve the clearness after water washing due to the solubility increase of slightly soluble monomers as well as the reduction of resin viscosity.

Preferably, the amount of components (A1) and (A2) is sufficient to allow the 3D objects (products) printed using the photocurable compositions of the present invention to be washed with pure water, which contains no organic solvent, detergent or surfactant, having room temperature (20 to 30° C.) and leaving a dry surface. That is, uncured, or partially cured components of the composition on the surfaces of the printed 3D object are washed away by rinsing with pure water, or immersing in pure water having room temperature optionally by utilization of ultrasonication, agitation, different forms of flow (static, vortex, jet) etc. The photocurable compositions can be cleaned by pure water room temperature with no assistance of any solvent or detergent.

Reactive diluents are substances which reduce the viscosity of a radiation curable composition for processing and become part of the radiation curable composition during its subsequent curing via copolymerization. They are usually added to lacquers to reduce their viscosity. The reactive diluents used in UV and EB (electron beam) curing typically have one to four reactive groups and range in molecular weight from approximately 150 to 500. The reactive diluents are commonly liquids with viscosities from 5 to 200 centipoise at 25° C.

The oligomers used in UV and EB curing are typically viscous liquids ranging from a few thousand to greater than 1 million centipoise in viscosity at 25° C. They also typically possess two to six acrylate groups per molecule and range in molecular weight from approximately 500 to 20,000.

A water-soluble reactive diluent (A1) is a reactive diluent that can dissolve in water at ca. 20° C. in an amount of 10 g/L, or more, especially 33 g/L, or more.

A water-soluble reactive oligomer (A2) is an oligomer that can dissolve in water at ca. 20° C. in an amount of 10 g/L, or more, especially 33 g/L, or more. The term water-soluble reactive oligomer (A1) includes water dilutable oligomers (A2). By water-dilutable oligomer (A2) is meant to designate in the present invention an oligomer that permits to form a homogeneous, single phase mixture when the oligomer (A2) is mixed with water over a concentration range of 5 to 75% by weight of water in the total mass of water and the oligomer (A2). Oligomers which are dispersible in water are not comprised by the term “water-soluble reactive oligomer (A2)”. Some commercially available water-soluble reactive oligomers (A2) may contain reactive diluents, but its water content is less than 10% by weight.

A water insoluble, or slightly water-soluble reactive diluent (B1) is a reactive diluent that can dissolve in water at ca. 20° C. in an amount of less than 10 g/L. A water insoluble reactive diluent (B1a) is a reactive diluent that can dissolve in water at ca. 20° C. in an amount of less than 1.0 g/L. A slightly water-soluble reactive diluent (B1b) is a reactive diluent that can dissolve in water at ca. 20° C. in an amount of from 1.0 g/L to less than 10 g/L.

A water insoluble reactive oligomer (B2) is an oligomer that can dissolve in water at ca. 20° C. in an amount of less than 1.0 g/L. A slightly water-soluble reactive oligomer (B2) is an oligomer that can dissolve in water at ca. 20° C. in an amount of less than 10 g/L.

Water-Soluble Reactive Diluent

The water-soluble reactive diluent (A1) is a reactive diluent that can dissolve in water at ca. 20° C. in an amount of 10 g/L, or more, especially 33 g/L, or more.

The water-soluble reactive diluent (A1) is preferably a mono, or difunctional reactive diluent.

Examples of water-soluble reactive diluents (A1), that dissolve in water at room temperature in an amount of 10 g/L to 33 g/L, are hydroxyethyl methacrylate (11.8 g/L) and 2-(2-ethoxyethoxy)ethyl acrylate(EOEOA) (13.4 g/L). More preferred, are water-soluble reactive diluents (A1) that can dissolve in water at room temperature in an amount of 33 g/L, or more.

Preferably, the water-soluble reactive diluent (A1) is selected from monofunctional (meth)acrylacrylamides,

N-vinyloxazolidinones of formula

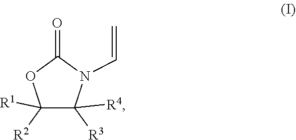

wherein

R¹, R², R³ and R⁴ are independently of each other a hydrogen atom or an organic group having not more than 10 carbon atoms;

polyethylene glycol (200) diacrylate (PEG200DA), polyethylene glycol (400) diacrylate, 2-hydroxyethyl acrylate, hydroxypropyl acrylate, N-vinyl-caprolactam (NVC), N-Vinyl-pyrrolidone (NVP) and N-Vinyl-imidazole (VIM).

Polyethylene glycol (200) diacrylate and polyethylene glycol (400) diacrylate mentioned above are represented by the chemical formulae below.

Polyethylene glycol (200) diacrylate

CH₂═CH—CO—(OC₂H₄)ₙ—OCOCH═CH₂where n≈4

Polyethylene glycol (400) diacrylate

CH₂═CH—CO—(OC₂H₄)ₙ—OCOCH═CH₂where n≈9.

Additional examples of the water-soluble reactive diluents (A1) are acrylic acid, methacrylate acid, β-Carboxyethyl acrylate, 2-sulfoethyl methacrylate and trichloroacrylic acid.

Examples of monofunctional (meth)acrylamides (A1) include acryloylmorpholine, methacryloylmorpholine, N-(hydroxymethyl)acrylamide and N-hydroxyethyl acrylamide.

The at present, most preferred acrylamide, or methacrylamide component (A1) is acryloylmorpholine (ACMO).

In another preferred embodiment the water-soluble reactive diluent (A1) is a

N-vinyloxazolidinone of formula

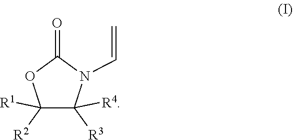

Preferably at least two of

R¹ to R⁴ in formula (I) are a hydrogen atom.

In a particularly preferred embodiment at least two of R¹ to R⁴ in formula (I) are a hydrogen atom and any remaining R¹ to R⁴ are an organic group having not more than 10 carbon atoms.

Preferably the organic group has not more than 4 carbon atoms. In a particularly preferred embodiment the organic group is an alkyl, or alkoxy group. In a preferred embodiment the organic group is a C₁-C₄alkyl group, or a C₁-C₄alkoxy group. In a most preferred embodiment the organic group is a methyl group.

As examples of N-vinyloxazolidinone of formula (I) compounds may be mentioned, wherein

R¹, R², R³ and R⁴ are a hydrogen atom (N-vinyloxazolidinone (NVO)), or

R¹ is a C₁-C₄alkyl group, in particular a methyl group, and R², R³ and R⁴ are a hydrogen atom (N-vinyl-5-methyl oxazolidinone (NVMO)), or

R¹ and R² are a hydrogen atom and R³ and R⁴ are a C₁-C₄alkyl group, in particular a methyl group.

Particularly preferred are NVO and NVMO, most preferred is NVMO.

The water solubility of some of the explicitly mentioned water-soluble reactive diluents is listed in the table below:

| Cpd. | Water solubility | |
|---|---|---|
| Acryloylmorpholine | Fully Miscible | |
| N-Vinyl-pyrrolidone (NVP) | 100 g/L at 68° F. (20° C.) | |
| N-Vinyl-caprolactam (NVC) | 40 | g/L |
| N-Vinyl-imidazole (VIM) | Fully miscible | |
| Triethylene glycol diacrylate (TEGDA) | 18 | g/l |
| N-vinyl-5-methyl oxazolidinone | 91 g/L | (20° C.) |
| (NVMO) | | |
| Polyethylene glycol (200) diacrylate | Water soluble | |
| Tetraethylene glycol dimethacrylate | 12.6 | g/L |
| (T4EGDMA) | | |
| Poly(ethylene glycol) diacrylate | 21 | g/L |
| (average Mn 250; PEGDA250) | | |
| Polyethylene glycol (400) diacrylate | Water soluble | |
| hydroxyethyl acrylate | 100 g/L | (25° C.) |
| hydroxypropyl acrylate | 100 g/L | (25° C.) |

The at present most preferred water-soluble reactive diluents (A1) are selected from acryloylmorpholine, polyethylene glycol (200) diacrylate, N-vinyl-caprolactam (NVC), N-vinyloxazolidinone, N-vinyl-5-methyl oxazolidinone and mixtures thereof.

Water-Soluble Reactive Oligomer (A2)

The water-soluble reactive oligomer (A2) is an oligomer that can dissolve in water at ca. 20° C. in an amount of 10 g/L, or more, especially 33 g/L, or more. The term water-soluble reactive oligomer (A1) include water dilutable oligomers (A2).

The water soluble oligomer (A2) may be a water soluble urethane (meth)acrylate, epoxy (meth)acrylate, polyester (meth)acrylate, (meth)acrylic (meth)acrylate, or a mixture thereof.

In a preferred embodiment of the present invention the oligomer (A2) is a water-soluble (including water-dilutable) (meth)acrylated urethane (A2).

Water-dilutable urethanes are, for example, described in US2011017085. The term “(meth)acryl” is to be understood as to encompass both acryl and methacryl compounds or derivatives as well as mixtures thereof. Acrylated compounds are preferred.

The oligomer (A2) is more preferably a water-dilutable (meth)acrylated polyurethane (A2) containing at least one polyethylene glycol segment and at least one pendant hydrophilic group.

The water-dilutable (meth)acrylated urethane (A) is generally obtained from the reaction of at least one polyisocyanate compound (i), at least one polyol (ii), preferably a polyester polyol (vi), comprising at least one polyethylene glycol segment and at least one pendant hydrophilic group, and at least one (meth)acrylated compound (iv) containing at least one reactive group capable to react with isocyanate groups. Preferred are water dilutable (meth)acrylated aliphatic urethanes.

The polyester polyol (vi) is preferable water-dilutable. Water-dilutable polyester polyols have been described for example in U.S. Pat. No. 5,006,598 and WO94/28043. The polyester polyol (vi) more preferably has a molecular weight of about 200 to 5000. The polyester polyol (vi) is more preferably obtained from the reaction of at least one polyethylene glycol, at least one polyacid and at least one compound containing at least one hydrophilic group, and optionally at least one other polyol. By hydrophilic group is meant to designate a group that is either ionic, such as for example a carboxylate or sulfonate group, or that becomes ionic after reaction with a neutralizing agent forming a salt, such as a carboxylic acid, sulfonic acid, amino group.

The polyethylene glycol preferably has a molecular weight of from 200 to 2000, more preferably of at least 400. Particularly preferred are polyester polyols which contain from 20 to 80 percent by weight, more preferably from 40 to 80 percent by weight, of polyethylene glycol segments and from 5 to 20 percent, more preferably from 5 to 15 percent, by weight of a compound containing at least one hydrophilic group, especially sodium sulfoisophthalic acid, 2,2-dimethylolpropionic acid and 2,2-dimethylolbutanoic acid and/or alpha, omega-polypropylenglycol-diamine-sulfopropylated, sodium salt. Suitable water-dilutable (meth)acrylates are for example those that have been commercialized under the name of UCECOAT® 6558, UCECOAT® 6559, EBECRYL® 2002 and EBECRYL® 2003.

The (meth)acrylate functional urethane oligomer according to another preferred embodiment of the invention, has the structure: end group-polyisocyanate-backbone-polyisocyanate-end group. Reference is made to WO17005613A1.

Preferably said oligomer is obtained as the reaction product of:

(i) a glycol having a number-averaged molecular weight of from 390 g/mol to 25000 g/mol, preferably from 1000 g/mol to 25000 g/mol, more preferably from 1500 g/mol to 20000 g/mol,

(ii) a polyisocyanate, (iii) a (meth)acrylate functionalized compound comprising at least one group capable of reacting with isocyanate groups, and separated from the

(meth)acrylated moiety by a glycol-based spacer.

More preferably said (meth)acrylate functional urethane oligomer is obtainable as the reaction product of:

(iv) a glycol having an number-averaged molecular weight of from 400 g/mol to 10000 g/mol,

(v) a polyisocyanate,

(vi) a (meth)acrylate functionalized compound comprising at least one group capable of reacting with isocyanate groups, and separated from the (meth)acrylated moiety by a glycol-based spacer.

By the term “glycol” as used herein in (i) is meant any class of organic compounds belonging to the polyol family. In the molecule of a glycol, hydroxyl (—OH) groups are attached to different carbon atoms. Preferably, a glycol comprises two hydroxyl groups. This group also covers polyalkylene oxide polyols, such as polyethylene oxide and polycaprolactone polyols.

Other preferred glycols are polyvinyl alcohols. Polyvinyl Alcohol (PVOH, PVA or PVAL) are synthesized by hydrolysis of polyvinylacetate. It is classified into two classes namely partially hydrolysed and fully hydrolysed. These are commercially available from Kuraray under the tradename Poval. Preferred are partially hydrolysed polyvinylalcohols.

By the term “glycol-based spacer” as used herein in (iii) is a polyol. Preferably said glycol-based spacer is a polyethylene glycol or a poly-e-caprolactone.

By the term “polyisocyanate” as used herein is meant an organic compound comprising at least two isocyanate groups. Most preferably said (meth)acrylate functional urethane oligomer is of formula (Ia) or (Ib), wherein x is 1-10, R1 is a glycol-based spacer group, R2 is polyisocyanate derived, R3 is a backbone providing compound.

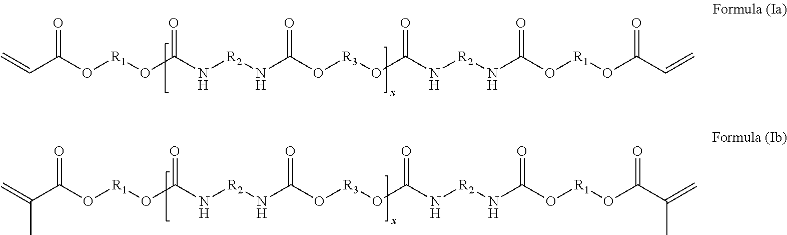

As can be seen from Formula (Ia) and (Ib), the oligomer is preferably end-capped by unsaturated groups.

In a preferred embodiment, the (meth)acrylate functional urethane oligomer according to an embodiment of the invention, is the reaction product of a poly(ethylene glycol), poly(ethylene glycol) mono (meth)acrylate and a polyisocyanate. In a particularly preferred embodiment, the (meth)acrylate functional urethane oligomer according an embodiment of the invention which is the reaction product of a poly(ethylene glycol), poly(ethylene glycol) mono (meth)acrylate and a polyisocyanate, is of formula (II) with n is 45 (PEG 2000) and m=6, x=1-10; preferably x=1-3; n, m and x are average values.

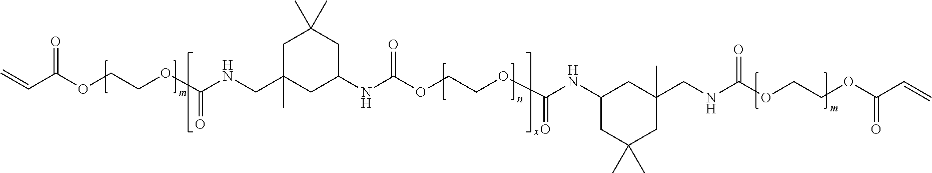

In a another preferred embodiment, the (meth)acrylate functional urethane oligomer according to an embodiment of the invention, is the reaction product of a poly(ethylene glycol), poly-e-caprolactone mono(meth)acrylate and a polyisocyanate.

In one embodiment of the invention, compound (A2) is a water-soluble compound.

According to WO2019052981A1 water-soluble reactive oligomers (A2) may be prepared from:

(i) at least one compound containing free isocyanate groups,

(ii) at least one ethylenically unsaturated compound containing at least one group capable of reacting with an isocyanate and further at least one ethylenically unsaturated group,

(iii-1) at least one compound containing at least one group capable of reacting with isocyanate groups and further at least one hydrophilic group capable of rendering the compound (A2) soluble in water either directly or after the reaction with a neutralizing agent to provide a salt,

(iv) at least one carboxylic acid hydrazide, and

(v) optionally, at least one compound containing at least one group capable of reacting with isocyanate groups but no ethylenically unsaturated groups; or

(i) at least one compound containing free isocyanate groups,

(ii) at least one ethylenically unsaturated compound containing at least one group capable of reacting with an isocyanate and further at least one ethylenically unsaturated group,

(iii-1) at least one compound containing at least one group capable of reacting with isocyanate groups and further at least one hydrophilic group capable of rendering the compound (A2) soluble in water either directly or after the reaction with a neutralizing agent to provide a salt, and

(v) optionally, at least one compound containing at least one group capable of reacting with isocyanate groups but no ethylenically unsaturated groups.

Compounds (i) typically are polyisocyanates. By a ‘polyisocyanate’ (i) is meant to designate organic compounds that comprise at least two and typically up to six isocyanate groups. The polyisocyanate compound usually comprises not more than three isocyanate groups. The polyisocyanate compound (i) is most preferably a diisocyanate. The polyisocyanate compound is generally selected from aliphatic, cycloaliphatic, aromatic and/or heterocyclic polyisocyanates or combinations thereof. Possibly the polyisocyanate (i) contains allophanate groups, biuret and/or isocyanurate groups. Examples of aliphatic and cycloaliphatic polyisocyanates are 1,5 diisocyanatopentane, 1,6-diisocyanatohexane (HDI), 1,1′-methylene bis[4-isocyanatocyclohexane] (H12MDI), 5-isocyanato-1-isocyanatomethyl-1,3,3-trimethyl-cyclohexane (isophorone diisocyanate, IPDI). Aliphatic polyisocyanates containing more than two isocyanate groups are for example the derivatives of above mentioned diisocyanates like 1,6-diisocyanatohexane biuret and isocyanurate. Examples of aromatic polyisocyanates are 1,4-diisocyanatobenzene (BDI), 2,4-diisocyanatotoluene (2,4-TDI), 2,6-diisocyanatotoluene (2,6-TDI), 1,1′-methylenebis[4-isocyanatobenzene](MDI), xylylene diisocyanate (XDI), tetramethylxylylene diisocyanate (TMXDI), 1,5-naphtalene diisocyanate (NDI), tolidine diisocyanate (TODI) and p-phenylene diisocyanate (PPDI).

Preferred in the context of the invention are aliphatic and/or cycloaliphatic polyisocyanates, more preferably diisocyanates. Particularly preferred are aliphatic or cycloaliphatic diisocyanates and more in particular cycloaliphatic diisocyanates. Especially preferred are 1,1′-methylene bis[4-isocyanatocyclohexane] (H12MDI) and/or isophorone diisocyanate (IPDI).

Polymerizable ethylenically unsaturated compounds that have one or more reactive groups capable of reacting with isocyanate groups and at least one (meth)acrylic group are preferred compounds (ii). Compounds (ii) can be selected from compounds containing one or more ethylenically unsaturated function (such as an acrylic and/or methacrylic group) and preferably two or more nucleophilic functions capable of reacting with an isocyanate (typically a hydroxyl group). Examples of such compounds (ii-a) are polyester (meth)acrylates containing hydroxyl groups, polyether (meth)acrylates containing hydroxyl groups, polyether ester (meth)acrylates containing hydroxyl groups and/or polyepoxy (meth)acrylates containing hydroxyl groups. Acrylates are particularly preferred. They most typically are linear compounds comprising on average 2 hydroxyl groups per molecule. Such compounds are well known in the art. Preferred in this category are polyester (meth)acrylates and/or polyepoxy (meth)acrylates with 2 or more, typically on average 2 hydroxyl groups. Aliphatic compounds are preferred. The use of the di-acrylate of bisphenol A is for instance not recommended.

Particularly preferred compounds (ii-a) are those containing one or more ethylenically unsaturated function (such as acrylic and/or methacrylic group) and essentially one nucleophilic function capable of reacting with an isocyanate (typically a hydroxyl group). Even more preferred are (meth)acryloyl mono-hydroxy compounds, and more in particular poly(meth)acryloyl mono-hydroxy compounds. Acrylates are particularly preferred.

Other compounds may be used. Useful compounds (ii-b) include the esterification products of aliphatic and/or aromatic polyols with (meth)acrylic acid having a residual average hydroxyl functionality of about 1. Aliphatic compounds (ii-b) are preferred. The partial esterification products of (meth)acrylic acid with tri-, tetra-, penta- or hexahydric polyols or mixtures thereof are preferred. In this context, it is also possible to use reaction products of such polyols with ethylene oxide and/or propylene oxide or mixtures thereof, or reaction products of such polyols with lactones, which add to these polyols in a ring-opening reaction. Examples of suitable lactones are γ-butyrolactone and, in particular δ-valerolactone and ε-caprolactone. Preferred are those alkoxylated polyols having not more than three alkoxy groups per hydroxyl functionality and ε-caprolactone-modified polyols. These modified or unmodified polyols are partly esterified with acrylic acid, methacrylic acid or mixtures thereof until the desired residual hydroxyl functionality is reached.

Particularly preferred are compounds comprising at least two (meth)acryl functions such as glycerol diacrylate, trimethylolpropane diacrylate, glycerol diacrylate, pentaerythritol triacrylate, ditrimethylolpropane triacrylate, dipentaerythritol pentaacrylate and their (poly)ethoxylated and/or (poly)propoxylated equivalents (of any of these).

Compounds (ii-b) obtained from the reaction of (meth)acrylic acid with aliphatic, cycloaliphatic or aromatic compounds bearing an epoxy functionality together with at least one (meth)acrylic functionality can be used as well. Compounds obtained from the reaction of an aliphatic, cycloaliphatic or aromatic acid with an epoxy group containing (meth)acrylate, such as glycidyl (meth)acrylate, can also be used.

Other suitable compounds (ii-b) are the (meth)acrylic esters with linear and branched polyols in which at least one hydroxy functionality remains free, like

hydroxyalkyl(meth)acrylates having 1 to 20 carbon atoms in the alkyl group. Preferred molecules in this category are hydroxyethyl (meth)acrylate, hydroxypropyl (meth)acrylate, hydroxybutyl (meth)acrylate

Compounds (iii-a) containing hydrophilic groups are capable of rendering the polyurethane dispersible in aqueous medium either directly or after the reaction with a neutralizing agent to provide a salt. Compounds (iii-a) are typically hydroxylated and/or aminated compounds. Typically compounds (iii-a) contain at least one hydroxyl group or at least one primary or secondary amino group, preferably they contain at least two of such hydrophilic groups. In compounds (iii-a) the hydrophilic groups capable of rendering the polyurethane dispersible in aqueous medium can be of ionic and/or of non-ionic nature. Preferably they are of ionic nature, more preferably they are anionic groups, and most preferably they are acidic groups or the salts thereof. Examples of suitable acidic groups include carboxylic acid, sulfonic acid, and/or phoshonic acid groups. Suitable salts are carboxylates, sulfonates and/or phosphonates. Examples of suitable counterions are ammonium, trimethylammonium, triethylammonium, sodium, potassium, lithium and the like. Non-ionic stabilization is often provided by hydrophilic moieties including polyethyleneoxide, polypropyleneoxide, or block copolymers made therefrom. Preferred hydrophilic groups are carboxylic acid groups and the salts thereof. Compounds (iii-a) are therefore typically hydrophilic compounds.

Typically compounds (iii-a) are saturated hydroxycarboxylic acids containing at least one hydroxyl group and at least one carboxylic acid group. In general the number of hydroxyl groups in said compound is at least two and preferably at most three. In general the number of carboxylic acid groups in said compound is at most three. Preferably the hydroxycarboxylic acid in question is a saturated aliphatic hydroxycarboxylic acid having at least one hydroxyl group. Particularly preferred are aliphatic saturated mono-, di- and/or or tricarboxylic acids having at least one hydroxyl group per molecule. Most preferred are the aliphatic saturated mono-carboxylic acids containing at least one, often at least two hydroxyl groups.

Suitable saturated aliphatic hydroxycarboxylic acids (iii-a) are e.g. represented by the general formula (HO)xR(COOH)y, wherein R represents a straight or branched hydrocarbon residue having from 1 to 12 carbon atoms, wherein x is an integer from 1 to 3 and y is an integer from 1 to 3.

Typically the sum of x+y is at most 5. Examples of these hydroxycarboxylic acids include citric acid, maleic acid, lactic acid and tartaric acid. Preferred are those hydroxycarboxylic acids wherein y=1 in the above general formula. The most preferred are the α,α-dimethylolalkanoic acids, wherein x=2 and y=1 in the above general formula, such as for example, 2,2-dimethylolpropionic acid and/or 2,2-dimethylolbutanoic acid.

Possibly compounds (iii) are saturated polyester polyols (iii-b) containing compound (iii-a) moieties and/or saturated polycarbonate polyols (iii-c) containing compound (iii-a) moieties. By “moieties” is meant in particular monomer units.

As example of non-ionic compounds (iii-d) we can mention hydroxy-functional compounds bearing non-ionic dispersing groups. The non-ionic dispersing groups can be alkylene oxide groups as described for instance in EP1328565. Preferred are ethylene oxide groups, but alternatively propylene oxide groups or mixtures of ethylene oxide and propylene oxide groups are useful as well.

Examples include but are not limited to mono-hydric alcohols (compounds with one hydroxyl function), poly-hydric alcohols (‘polyols’ and often diols), primary and/or secondary amines. Compounds (v) with 2 or more, typically on average 2 functional groups to react with an isocyanate group can act as chain extender. They can be polyols, primary amines and/or amines with secondary amino groups.

Suitable polyols (v-a) of low molecular weight are: ethylene glycol, propylene glycol, 1,3-propanediol, 1,3-butanediol, 1,4-butanediol, 1,5-pentanediol, 1,6-hexanediol, 1,7-heptanediol, 1,8-octanediol, neopentyl glycol, diethylene glycol, dipropylene glycol, triethylene glycol, tetraethylene glycol, dibutylene glycol, 2-methyl-1,3-pentanediol, 2-ethyl-2-butyl-1,3-propanediol, 2-ethyl-1,6-hexanediol, 2,2,4-trimethyl-1,3-pentanediol, 1,4-cyclohexanedimethanol, ethylene oxide adducts or propylene oxide adducts of bisphenol A or hydrogenated bisphenol A, or mixtures thereof (of any of these). Polyols such as glycerol, trimethylolethane, trimethylolpropane, di-trimethylolethane, di-trimethylolpropane and pentaerythritol and/or dipentaerythritol may also be used. They are examples of low molecular weight polyols.

The polyol can also be selected from high molecular weight polyols (v-b) having a number average molecular weight of at least 400, low molecular weight polyols having a calculated number average weight of lower than 400 or any mixtures thereof. The high molecular weight polyol preferably has a number average molecular weight which does not exceed 5,000, preferably not 2,000, more preferably not 1,000 dalton as calculated based on the hydroxyl index of the polyol. Examples of such high molecular weight polyols are polyester polyols, polyether polyols, polycarbonate polyols, fatty dimer diols, polybutadiene polyols, silicone polyols and polyacrylate polyols, as well as combinations thereof. Suitable polyether polyols comprise polyethylene glycols, polypropylene glycols and polytetramethylene glycols, or block copolymers thereof. Suitable polycarbonate polyols include the reaction products of diols such as ethylene glycol, 1,3-propanediol, 1,3-butanediol, 1,4-butanediol, 1,5-pentanediol, 1,6-hexanediol, diethylene glycol, triethylene glycol, dipropylene glycol, tripropylene glycol or tetraethylene glycol with phosgene, with dialkylcarbonates such as dimethycarbonate, with diarylcarbonates such as diphenylcarbonate or with cyclic carbonates such as ethylene and/or propylene carbonate.

Suitable fatty dimer diols are obtained from the hydrogenation of dimer acids, preferably those comprising 36 carbon atoms.

Suitable polyacrylate polyols include those prepared by the radical polymerization of (meth)acrylic and/or (meth)acrylamide monomers initiated by a thermal radical initiator in the presence of a hydroxylated mercaptan and followed by the end-group transesterification with a short chain diol, such as 1,4-butanediol.

Preferred are polyester polyols and/or polycarbonate polyols. In a preferred embodiment, the polyol component of the composition according to the invention is free of polyether polyol. Polyester polyols are particularly preferred, especially the hydroxyl terminated reaction products of polyhydric, preferably dihydric, alcohols with polycarboxylic, preferably dicarboxylic, acids or their corresponding anhydrides, as well as those obtained from the ring opening polymerization of lactones. The polycarboxylic acids which may be used for the formation of these polyester polyols may be aliphatic, cycloaliphatic, aromatic and/or heterocyclic and they may be substituted, saturated or unsaturated. Examples of dicarboxylic acids are succinic acid, glutaric acid, adipic acid, suberic acid, azelaic acid, sebacic acid, dodecanedicarboxylic acid, hexahydrophthalic acid, isophthalic acid, terephthalic acid, ortho-phthalic acid, tetrachlorophthalic acids, 1,5-naphthalene-dicarboxylic acid, fumaric acid, maleic acid, itaconic acid, citraconic acid, mesaconic acid, tetrahydrophthalic acid, trimellitic acid, trimesic acid and pyromellitic acid, or mixtures thereof.

The polyhydric alcohols which are preferably used for the preparation of the polyester polyols are often chosen from one or more compounds (v-a).

Particularly preferred however are polyester polyols made primarily from the polycondensation of (1) isophthalic acid and of (2) adipic acid and/or isophthalic acid. Possibly a mix of one or more compounds (v-a) and one or more compounds (v-b) is used.

Compounds (v) can also be chosen from amines or amino alcohols (v-c) and more in particular from one or more primary or secondary amines. Primary or secondary amines often have an amino functionality from 1 to 6, typically 1 to 4, preferably 1 to 3 and most preferably 1 to 2. Chain extending polyamines typically have an average functionality from 2 to 4, more preferably 2 to 3. The amine (v-c) is suitably a water-soluble aliphatic, alicyclic, aromatic or heterocyclic primary and/or secondary polyamine or hydrazine having up to 60, preferably up to 12 carbon atoms. The total amount of chain extending compounds (v-c) used is generally calculated according to the amount of residual isocyanate groups present in the compound (A) prepolymer. The ratio of isocyanate groups in the prepolymer to the amine groups in the chain extender (v-c) during the chain extension is generally in the range of from about 1:0.3 to about 1:0.9, preferably from about 1:0.5 to about 1:0.7 on an equivalent basis. This ratio is more preferably at most 0.7 in order to have sufficient available NCO group to react with the hydrazide (iv).

Examples of suitable chain extending amines (v-c) include: hydrazine, ethylene diamine, piperazine, 1,4-butanediamine, 1,6-hexanediamine, 1,8-octanediamine, 1,10-decane-diamine, 1,12-dodecanediamine, 2-methylpentamethylenediamine, triethylene triamine, isophorone diamine (or 1-amino-3-aminomethyl-3,5,5-trimethyl-cyclohexane), aminoethylethanolamine, polyethylene amines, polyoxyethylene amines and polyoxypropylene amines (e.g. Jeffamines from Huntsman), as well as mixtures thereof (of any of these).

In an embodiment no compounds (v) are used. In another embodiment one or more compounds (v) are used. If chain extenders are used then they most typically are selected from the above mentioned primary and/or secondary amines. Examples of suitable water-dilutable urethane(meth)acrylates are for instance UCECOAT® 6569, EBECRYL® 2002 and EBECRYL® 11. Examples of suitable epoxy(meth)acrylates include e.g. UCECOAT® 7640.

Examples of commercially available water-soluble urethane (meth)acrylate oligomers are shown in the table below:

| Supplier/ | | | Viscosity |
|---|---|---|---|
| Tradename | Chemical identity | Functionality | mPa · S |
| IGM | | | |
| Photomer ® | a water dilutable | 2 | 57500 |
| Aqua 6901 | urethane diacrylate | | |
| Photomer ® | a water dilutable | 2 | 35000 |
| Aqua 6902 | urethane diacrylate | | |
| Photomer ® | a water-dilutable | 6 | 30000 |
| Aqua 6903 | hexafunctional urethane | | |
| | acrylate | | |
| Soltech | | | |
| SWA 8015 | Urethane acrylate | 4 | 15000 (60° C.) |
| SWA 8016 | Urethane acrylate | 9 | 15000 (60° C.) |
| SWA 8035 | Urethane acrylate | 6 | 3500 (60° C.) |
| | (15% ACMO) | | |
| SWA 8038 | Urethane acrylate | 5 | 3000 |
| BASF | | | |
| Laromer ® | aliphatic epoxy-modified | 2 | 600-1200 |
| EA 8765 R | acrylate oligomer | | |
| Miwon | | | |
| Miramer ® | Aliphatic urethane | 3 | 7200 (60° C.) |
| 3100 | acrylate (30% diluent) | | |
| Rahn | | | |
| Genomer ® | a water soluble acrylate | 3 | 1000-1300 |
| 7311 | | | |
| Dymax | | | |
| Bomar ® | a water dilutable aliphatic | 3 | 7000 (25° C.) |
| XR-9416 | urethane trifunctional | | |
| | acrylate oligomer | | |
| Allnex | | | |
| UCECOAT ® | a water dilutable aliphatic | | |
| 6569 | urethane acrylate | | |
| IRR932 | a water dilutable aliphatic | 2-3 | 6000 (60° C.) |
| | urethane acrylate (5% | | |
| | H₂O) | | |

UCECOAT® 6569 can be diluted with up to 50% by weight water (water solubility=500 g/L) for viscosity reduction. If total water content exceeds 50%, the product stability may be decreased.

The amount of components (A1) and (A2) can be reduced to 20% by weight as long as the component(s) (B) are slightly water-soluble.

Water Insoluble, or Slightly Water-Soluble Reactive Diluent (B1)

A water insoluble, or slightly water-soluble reactive diluent (B1) is a reactive diluent that can dissolve in water at ca. 20° C. in an amount of less than 10 g/L. A water insoluble reactive diluent (B1a) is a reactive diluent that can dissolve in water at ca. 20° C. in an amount of less than 1.0 g/L. A slightly water-soluble reactive diluent (B1b) is a reactive diluent that can dissolve in water at ca. 20° C. in an amount of from 1.0 g/L to less than 10 g/L.

Examples of the water insoluble reactive diluent (B1a) include caprolactone acrylate, phenoxy benzyl acrylate, 3,3,5-trimethyl cyclohexyl acrylate, o-phenylphenol EO acrylate,

4-tert-butylcyclohexyl acrylate, benzyl (meth)acrylate, biphenyl methyl acrylate, lauryl (meth)acrylate, phenoxyethyl (meth)acrylate, ethoxylated nonylphenol acrylate, propoxylated nonylphenol acrylate, 1,6-hexanediol di(meth)acrylate, neopentylglycol (PO)2 diacrylate, neopentyl glycol dimethacrylate, bisphenol A (EO)₄ diacrylate, stearyl (meth)acrylate, pentaerythritol triacrylate, glycerine (PO)₃ triacrylate, trimethylolpropane (PO)₃ triacrylate, ditrimethylolpropane tetraacrylate, pentaerythritol tetraacrylate, tris(2-hydroxyethyl)isocyanurate triacrylate, adamantyl acrylate, 2-methyl-2-adamantyl acrylate, 2-ethyl-2-adamantyl acrylate, norbornyl (meth)acrylate, isobornyl (meth)acrylate, tetrahydrofurfuryl (meth)acrylate, cyclohexyl (meth)acrylate, cyclopentyl (meth)acrylate, cycloheptyl (meth)acrylate, cyclooctyl (meth)acrylate, cyclodecyl (meth)acrylate, dicyclodecyl (meth)acrylate, 3,3,5-trimethylcyclohexyl (meth)acrylate, 4-t-butylcyclohexyl (meth)acrylate, trimethylolpropane triacrylate (TMPTA), trimethylolpropane trimethacrylate (TMPTMA), trimethylolpropane ethoxy triacrylate (TMPEO3TA) and tricyclodecanedimethanol diacrylate.

Examples of water insoluble reactive diluent (B1a) are shown in the table below:

| Cpd. | Water solubility (g/L at 20° C.) |
|---|---|
| trimethylolpropane triacrylate (TMPTA) | 0.55 |
| trimethylolpropane ethoxy triacrylate | 0.88 |
| trimethylolpropane trimethacrylate | 0.02 |
| (TMPTMA), | |
| tricyclodecanedimethanol diacrylate | <1 |

The slightly water-soluble reactive diluent (B1b) may be a compound of formula

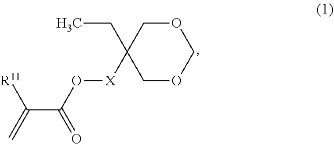

wherein R¹¹ is hydrogen or a methyl group, and X denotes a single bond or a divalent linking group, such as, for example, —(CH₂CH₂—O)ₙ— (n=1 to 30). Specific preferred examples of compounds represented by Formula (1) include, but of course are not limited to, compounds (A-1-1) and (A-1-2) shown below.

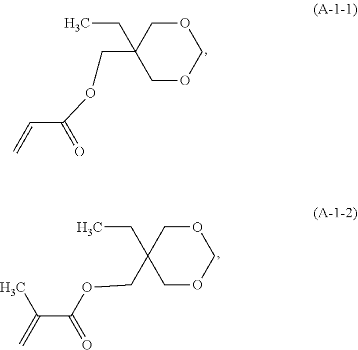

Trimethylolpropane formal acrylate (A-1-1) is particularly preferable.

Additional examples of the slightly water-soluble reactive diluent (B1b) are hydroxypropyl methacrylate, tripropylene glycol diacrylate, 2-[[(butylamino)carbonyl]oxy]ethyl acrylate and triethylene glycol dimethacrylate (TEGDMA).

Examples of the slightly water-soluble reactive diluent (B1b) are shown in the table below:

| Cpd. | Water solubility (g/L at 20° C.) |
|---|---|
| cyclic trimethylolpropane formal | 9.3 |
| acrylate | |
| triethylene glycol dimethacrylate | 3.6 |
| (TEGDMA) | |
| tripropylene glycol diacrylate | 4.0 |
| tricyclodecanedimethanol diacrylate | <1 |
| hydroxypropyl methacrylate | <10 |
| 2-[[(butylamino)carbonyl]oxy]ethyl | 5.0 |
| acrylate | |

Water Insoluble, or Slightly Water-Soluble Oligomer (B2)

The oligomer (B2) is selected from polyester (meth)acrylates, polyether (meth)acrylates, carbonate (meth)acrylates, epoxy (meth)acrylates and urethane (meth)acrylates, including amine-modified oligomers. The oligomer (B2) may be single oligomer, or a mixture of two, or more oligomers.

Urethane (meth)acrylates are obtainable for example by reacting polyisocyanates with hydroxyalkyl (meth)acrylates and optionally chain extenders such as diols, polyols, diamines, polyamines, dithiols or polythiols.

Urethane (meth)acrylates of this kind comprise as synthesis components substantially:
(1) at least one organic aliphatic, aromatic or cycloaliphatic di- or polyisocyanate,
(2) at least one compound having at least one isocyanate-reactive group and at least one radically polymerizable unsaturated group, and
(3) optionally, at least one compound having at least two isocyanate-reactive groups.

Suitable components (1) are, for example, aliphatic, aromatic, and cycloaliphatic diisocyanates and polyisocyanates having an NCO functionality of at least 2, preferably 2 to 5, and more preferably more than 2 to 4.

Polyisocyanates contemplated include polyisocyanates containing isocyanurate groups, uretdione diisocyanates, polyisocyanates containing biuret groups, polyisocyanates containing urethane groups or allophanate groups, polyisocyanates comprising oxadiazinetrione groups, uretonimine-modified polyisocyantes of linear or branched C₄-C₂₀ alkylene diisocyanates, cycloaliphatic diisocyanates having a total of 6 to 20 C atoms, or aromatic diisocyanates having a total of 8 to 20 C atoms, or mixtures thereof.

Examples of customary diisocyanates are aliphatic diisocyanates such as tetramethylene diisocyanate, hexamethylene diisocyanate (1,6-diisocyanatohexane), trimethylhexamethylene diisocyanate, octamethylene diisocyanate, decamethylene diisocyanate, dodecamethylene diisocyanate, tetradecamethylene diisocyanate, derivatives of lysine diisocyanate, tetramethylxylylene diisocyanate, trimethylhexane diisocyanate or tetramethylhexane diisocyanate, cycloaliphatic diisocyanates such as 1,4-, 1,3- or 1,2-diisocyanatocyclohexane, 4,4′- or 2,4′-di(isocyanatocyclohexyl)methane, 1-isocyanato-3,3,5-trimethyl-5-(isocyanatomethyl)cyclohexane (isophorone diisocyanate), 1,3- or 1,4-bis(isocyanatomethyl)cyclohexane or 2,4- or 2,6-diisocyanato-1-methylcyclohexane, and also aromatic diisocyanates such as tolylene 2,4- or 2,6-diisocyanate and the isomer mixtures thereof, m- or p-xylylene diisocyanate, 2,4′- or 4,4′-diisocyanato-diphenylmethane and the isomer mixtures thereof, phenylene 1,3- or 1,4-diisocyanate, 1-chlorophenylene 2,4-diisocyanate, naphthylene 1,5-diisocyanate, diphenylene 4,4′-diisocyanate, 4,4′-diisocyanato-3,3′-dimethylbiphenyl, 3-methyldiphenylmethane 4,4′-diisocyanate, tetramethylxylylene diisocyanate, 1,4-diisocyanatobenzene or diphenyl ether 4,4′-diisocyanate.

Mixtures of the stated diisocyanates may also be present.

Contemplated as component (2) in accordance with the invention is at least one compound (2) which carries at least one isocyanate-reactive group and at least one radically polymerizable group.

The compounds (2) preferably have precisely one isocyanate-reactive group and 1 to 5, more preferably 1 to 4, and very preferably 1 to 3 radically polymerizable groups.

The components (2) preferably have a molar weight of below 10 000 g/mol, more preferably below 5000 g/mol, very preferably below 4000 g/mol, and more particularly below 3000 g/mol. Special components (b) have a molar weight of below 1000 or even below 600 g/mol.

Isocyanate-reactive groups may be, for example, —OH, —SH, —NH₂, and —NHR¹⁰⁰, where R¹⁰⁰ is hydrogen or an alkyl group containing 1 to 4 carbon atoms, such as methyl, ethyl, n-propyl, isopropyl, n-butyl, isobutyl, sec-butyl or tert-butyl, for example. Components (2) may be, for example, monoesters of α,β-unsaturated carboxylic acids, such as acrylic acid, methacrylic acid, crotonic acid, itaconic acid, fumaric acid, maleic acid, acrylamidoglycolic acid and methacrylamidoglycolic acid, and polyols, which have preferably 2 to 20 C atoms and at least two hydroxyl groups, such as ethylene glycol, diethylene glycol, triethylene glycol, propylene 1,2-glycol, propylene 1,3-glycol, 1,1-dimethyl-1,2-ethanediol, dipropylene glycol, triethylene glycol, tetraethylene glycol, pentaethylene glycol, tripropylene glycol, 1,2-, 1,3- or 1,4-butanediol, 1,5-pentanediol, neopentyl glycol, 1,6-hexanediol, 2-methyl-1,5-pentanediol, 2-ethyl-1,4-butanediol, 1,4-dimethylolcyclohexane, 2,2-bis(4-hydroxycyclohexyl)propane, glycerol, trimethylolethane, trimethylolpropane, trimethylolbutane, pentaerythritol, ditrimethylolpropane, erythritol, sorbitol, polyethylene glycol having a molar mass of between 106 and 2000, polypropylene glycol having a molar weight of between 134 and 2000, polyTHF having a molar weight of between 162 and 2000 or poly-1,3-propanediol having a molar weight of between 134 and 400. In addition it is also possible to use esters or amides of (meth)acrylic acid with amino alcohols such as 2-aminoethanol, 2-(methylamino)ethanol, 3-amino-1-propanol, 1-amino-2-propanol or 2-(2-aminoethoxy)ethanol, for example, 2-mercaptoethanol or polyaminoalkanes, such as ethylenediamine or diethylenetriamine, or vinylacetic acid.

Also suitable, furthermore, albeit less preferably, are unsaturated polyetherols or polyesterols or polyacrylate polyols having an average OH functionality of 2 to 10.

Examples of amides of ethylenically unsaturated carboxylic acids with amino alcohols are hydroxyalkyl(meth)acrylamides such as N-hydroxymethylacrylamide, N-hydroxymethylmethacrylamide, N-hydroxyethylacrylamide, N-hydroxyethylmethacrylamide, 5-hydroxy-3-oxapentyl(meth)acrylamide, N-hydroxyalkylcrotonamides such as N-hydroxymethylcrotonamide, or N-hydroxyalkylmaleimides such as N-hydroxyethylmaleimide.

Preference is given to using 2-hydroxyethyl (meth)acrylate, 2- or 3-hydroxypropyl (meth)acrylate, 1,4-butanediol mono(meth)acrylate, neopentyl glycol mono(meth)acrylate, 1,5-pentanediol mono(meth)acrylate, 1,6-hexanediol mono(meth)acrylate, glycerol mono(meth)acrylate and di(meth)acrylate, trimethylolpropane mono(meth)acrylate and di(meth)acrylate, pentaerythritol mono(meth)acrylate, di(meth)acrylate, and tri(meth)acrylate, and also 2-aminoethyl (meth)acrylate, 2-aminopropyl (meth)acrylate, 3-aminopropyl (meth)acrylate, 4-aminobutyl (meth)acrylate, 6-aminohexyl (meth)acrylate, 2-thioethyl (meth)acrylate, 2-aminoethyl(meth)acrylamide, 2-aminopropyl(meth)acrylamide, 3-aminopropyl(meth)acrylamide, 2-hydroxyethyl(meth)acrylamide, 2-hydroxypro-pyl(meth)acrylamide, or 3-hydroxypropyl(meth)acrylamide. Particularly preferred are 2-hydroxyethyl acrylate, 2-hydroxyethyl methacrylate, 2- or 3-hydroxypropyl acrylate, 1,4-butanediol monoacrylate, 3-(acryloyloxy)-2-hydroxypropyl (meth)acrylate, and also the monoacrylates of polyethylene glycol with a molar mass of 106 to 238.

Contemplated as component (3) are compounds which have at least two isocyanate-reactive groups, examples being —OH, —SH, —NH₂ or —NH R¹⁰¹, in which R¹⁰¹ therein, independently of one another, may be hydrogen, methyl, ethyl, isopropyl, n-propyl, n-butyl, isobutyl, sec-butyl or tert-butyl.

Compounds (3) having precisely 2 isocyanate-reactive groups are preferably diols having 2 to 20 carbon atoms, examples being ethylene glycol, 1,2-propanediol, 1,3-propanediol, 1,1-dimethylethane-1,2-diol, 2-butyl-2-ethyl-1,3-propanediol, 2-ethyl-1,3-propanediol, 2-methyl-1,3-propanediol, neopentyl glycol, neopentyl glycol hydroxypivalate, 1,2-, 1,3- or 1,4-butanediol, 1,6-hexanediol, 1,10-decanediol, bis(4-hydroxycyclohexane)isopropylidene, tetramethylcyclobutanediol, 1,2-, 1,3- or 1,4-cyclohexanediol, cyclooctanediol, norbornanediol, pinanediol, decalindiol, 2-ethyl-1,3-hexanediol, 2,4-diethyloctane-1,3-diol, hydroquinone, bisphenol A, bisphenol F, bisphenol B, bisphenol S, 2,2-bis(4-hydroxycyclohexyl)propane, 1,1-, 1,2-, 1,3-, and 1,4-cyclohexanedimethanol, 1,2-, 1,3-, or 1,4-cyclohexanediol, polyTHF having a molar mass of between 162 and 2000, poly-1,2-propanediol or poly-1,3-propanediol having a molar mass of between 134 and 1178 or polyethylene glycol having a molar mass of between 106 and 2000, and also aliphatic diamines, such as methylene- and isopropylidene-bis(cyclohexylamine), piperazine, 1,2-, 1,3- or 1,4-diaminocyclohexane, 1,2-, 1,3-, or 1,4-cyclohexanebis(methylamine), etc., dithiols or polyfunctional alcohols, secondary or primary amino alcohols, such as ethanolamine, monopropanolamine, etc. or thio alcohols, such as thioethylene glycol.

Particularly suitable here are the cycloaliphatic diols, such as, for example, bis(4-hydroxycyclohexane)isopropylidene, tetramethylcyclobutanediol, 1,2-, 1,3-, or 1,4-cyclohexanediol, 1,1-, 1,2-, 1,3-, and 1,4-cyclohexanedimethanol, cyclooctanediol or norbornanediol.

Further compounds (3) may be compounds having at least three isocyanate-reactive groups.

For example, these components may have 3 to 6, preferably 3 to 5, more preferably 3 to 4, and very preferably 3 isocyanate-reactive groups.

The molecular weight of these components is generally not more than 2000 g/mol, preferably not more than 1500 g/mol, more preferably not more than 1000 g/mol, and very preferably not more than 500 g/mol.

The urethane (meth)acrylates preferably have a number-average molar weight Mₙ of 500 to 20 000, in particular of 500 to 10 000 and more preferably 600 to 3000 g/mol (determined by gel permeation chromatography using tetrahydrofuran and polystyrene as standard).

Epoxy (meth)acrylates are obtainable by reacting epoxides with (meth)acrylic acid. Examples of suitable epoxides include epoxidized olefins, aromatic glycidyl ethers or aliphatic glycidyl ethers, preferably those of aromatic or aliphatic glycidyl ethers.

Examples of possible epoxidized olefins include ethylene oxide, propylene oxide, isobutylene oxide, 1-butene oxide, 2-butene oxide, vinyloxirane, styrene oxide or epichlorohydrin, preference being given to ethylene oxide, propylene oxide, isobutylene oxide, vinyloxirane, styrene oxide or epichlorohydrin, particular preference to ethylene oxide, propylene oxide or epichlorohydrin, and very particular preference to ethylene oxide and epichlorohydrin.

Aromatic glycidyl ethers are, for example, bisphenol A diglycidyl ether, bisphenol F diglycidyl ether, bisphenol B diglycidyl ether, bisphenol S diglycidyl ether, hydroquinone diglycidyl ether, alkylation products of phenol/dicyclopentadiene, e.g., 2,5-bis[(2,3-epoxypropoxy)phenyl]octahydro-4,7-methano-5H-indene (CAS No. [13446-85-0]), tris[4-(2,3-epoxypropoxy)phenyl]methane isomers (CAS No. [66072-39-7]), phenol-based epoxy novolaks (CAS No. [9003-35-4]), and cresol-based epoxy novolaks (CAS No. [37382-79-9]).

Examples of aliphatic glycidyl ethers include 1,4-butanediol diglycidyl ether, 1,6-hexanediol diglycidyl ether, trimethylolpropane triglycidyl ether, pentaerythritol tetraglycidyl ether, 1,1,2,2-tetrakis[4-(2,3-epoxypropoxy)phenyl]ethane (CAS No. [27043-37-4]), diglycidyl ether of polypropylene glycol (α,ω-bis(2,3-epoxypropoxy)poly(oxypropylene), CAS No. [16096-30-3]) and of hydrogenated bisphenol A (2,2-bis[4-(2,3-epoxypropoxy)cyclohexyl]propane, CAS No. [13410-58-7]).

The epoxy (meth)acrylates preferably have a number-average molar weight Mₙ of 200 to 20 000, more preferably of 200 to 10 000 g/mol, and very preferably of 250 to 3000 g/mol; the amount of (meth)acrylic groups is preferably 1 to 5, more preferably 2 to 4, per 1000 g of epoxy (meth)acrylate (determined by gel permeation chromatography using polystyrene as standard and tetrahydrofuran as eluent).

Carbonate (meth)acrylates comprise on average preferably 1 to 5, especially 2 to 4, more preferably 2 to 3 (meth)acrylic groups, and very preferably 2 (meth)acrylic groups.

The number-average molecular weight Mₙ of the carbonate (meth)acrylates is preferably less than 3000 g/mol, more preferably less than 1500 g/mol, very preferably less than 800 g/mol (determined by gel permeation chromatography using polystyrene as standard, tetrahydrofuran as solvent).

The carbonate (meth)acrylates are obtainable in a simple manner by transesterifying carbonic esters with polyhydric, preferably dihydric, alcohols (diols, hexanediol for example) and subsequently esterifying the free OH groups with (meth)acrylic acid, or else by transesterification with (meth)acrylic esters, as described for example in EP-A 92 269. They are also obtainable by reacting phosgene, urea derivatives with polyhydric, e.g., dihydric, alcohols.

Also conceivable are (meth)acrylates of polycarbonate polyols, such as the reaction product of one of the aforementioned diols or polyols and a carbonic ester and also a hydroxyl-containing (meth)acrylate.

Examples of suitable carbonic esters include ethylene carbonate, 1,2- or 1,3-propylene carbonate, dimethyl carbonate, diethyl carbonate or dibutyl carbonate.

Examples of suitable hydroxyl-containing (meth)acrylates are 2-hydroxyethyl (meth)acrylate, 2- or 3-hydroxypropyl (meth)acrylate, 1,4-butanediol mono(meth)acrylate, neopentyl glycol mono(meth)acrylate, glyceryl mono- and di(meth)acrylate, trimethylolpropane mono- and di(meth)acrylate, and pentaerythritol mono-, di-, and tri(meth)acrylate.

Particularly preferred carbonate (meth)acrylates are those of the formula:

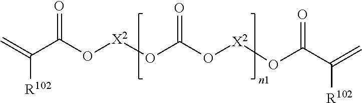

in which R¹⁰² is H or CH₃, X² is a C₂-C₁₈ alkylene group, and n1 is an integer from 1 to 5, preferably 1 to 3.

R¹⁰² is preferably H and X² is preferably C₂ to C₁₀ alkylene, examples being 1,2-ethylene, 1,2-propylene, 1,3-propylene, 1,4-butylene, and 1,6-hexylene, more preferably C₄ to C₈ alkylene. With very particular preference X² is C₆ alkylene.

The carbonate (meth)acrylates are preferably aliphatic carbonate (meth)acrylates.

Among the oligomers (B2) urethane (meth)acrylates are particularly preferred.

A urethane (meth)acrylate may refer to a single urethane (meth)acrylate or to a mixture of different urethane (meth)acrylates. Suitable urethane (meth)acrylates can be monofunctional, but preferably are difunctional, or of higher functionality. The functionality refers to the number of (meth)acrylate functional groups exhibited by the compound.

Preferred are urethane (meth)acrylates made from polyetherdiols, or polyester diols, aliphatic, aromatic, or cyclic diisocyanates and hydroxyalkyl (meth)acrylates. More preferred are urethane (meth)acrylates made from polyester diols, aromatic, or cyclic diisocyanates and hydroxyalkyl (metha)crylates.

The diisocyanates are preferably selected from 4,4′-, 2,4′- and/or 2,2′-methylenedicyclohexyl diisocyanate (H12MDI), isophorone diisocyanates (IPDI) and tolylene 2,4- and/or 2,6-diisocyanate (TDI).

The hydroxyalkyl (meth)acrylates are preferably selected from 2-hydroxyethyl acrylate, 2-hydroxyethyl methacrylate, 2- or 3-hydroxypropyl acrylate, 2- or 3-hydroxypropyl methacrylate, 4-hydroxybutyl methacrylate, and 4-hydroxybutyl acrylate.

Also preferred are urethane (meth)acrylates made from lactones of formula

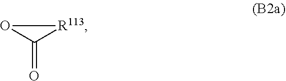

aliphatic, aromatic, or cyclic diisocyanates and hydroxyalkyl (meth)acrylates. More preferred are urethane (meth)acrylates made from caprolactone, aliphatic, or cyclic diisocyanates and hydroxyalkyl (meth)acrylates.

The diisocyanates are preferably selected from di(isocyanatocyclohexyl)methane, 2,2,4- and 2,4,4-trimethylhexane diisocyanate, and especially 4,4′-, 2,4′- and/or 2,2′-methylenedicyclohexyl diisocyanate (H12MDI).

The hydroxyalkyl (meth)acrylates are preferably selected from 2-hydroxyethyl acrylate, 2-hydroxyethyl methacrylate, 2- or 3-hydroxypropyl acrylate, 2- or 3-hydroxypropyl methacrylate, 4-hydroxybutyl methacrylate, and 4-hydroxybutyl acrylate.

Also preferred are those having polyfunctionality of (meth)acrylates or mixed acrylic and methacrylic functionality.

In a preferred embodiment the polyester urethane (meth)acrylate (B2) is obtained by reacting
(D1) a hydroxyalkylacrylate, or hydroxyalkylmethacrylate,
(D2) an aliphatic diisocyanate, an aliphatic polyisocyanate, a cycloaliphatic diisocyanate, a cycloaliphatic polyisocyanate, an aromatic diisocyanate, or an aromatic polyisocyanate, or mixtures thereof, especially an aliphatic diisocyanate, cycloaliphatic diisocyanate, or an aromatic diisocyanate, or mixtures thereof,
(D3) a polyester polyol, which is derived from aliphatic dicarboxylic acids and aliphatic diols, and (D4) optionally a secondary polyol, especially glycerol.

The hydroxyalkylacrylate, or hydroxyalkylmethacrylate (D1) is preferably a compound of formula

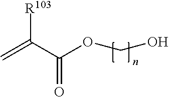

wherein R¹⁰³ is a hydrogen atom, or a methyl group, and n is 2 to 6, especially 2 to 4. Examples of (D1) include 2-hydroxyethyl acrylate, 2-hydroxyethyl methacrylate, 2- or 3-hydroxypropyl acrylate, 2- or 3-hydroxypropyl methacrylate, 4-hydroxybutyl methacrylate and 4-hydroxybutyl acrylate. 2-Hydroxyethyl acrylate is most preferred.

Hydroxyalkylacrylates, or hydroxyalkylmethacrylates (D1) having shorter alkyl chains (n is 2 to 4, especially 2) lead to a higher E modulus of the UV cured composition. Hydroxyalkylmethacrylates (D1) lead to a higher E modulus as compared to hydroxyalkylacrylates.

The organic diisocyanate (D2) used for making the polyester urethane acrylate is either an aliphatic, a cycloaliphatic, or an aromatic diisocyanate.

Examples of customary aliphatic and cycloaliphatic diisocyanates are tri-, tetra-, penta-, hexa-, hepta- and/or octamethylene diisocyanate, 2-methylpentamethylene 1,5-diisocyanate, 2-ethyltetramethylene 1,4-diisocyanate, hexamethylene 1,6-diisocyanate (HDI), pentamethylene 1,5-diisocyanate, butylene 1,4-diisocyanate, trimethylhexamethylene 1,6-diisocyanate, 1-isocyanato-3,3,5-trimethyl-5-isocyanatomethylcyclohexane (isophorone diisocyanate, IPDI), 1,4- and/or 1,3-bis(isocyanatomethyl)cyclohexane (HXDI), 1,4-cyclohexane diisocyanate, 1-methyl-2,4- and/or 1-methyl-2,6-cyclohexane diisocyanate, 4,4′-, 2,4′- and/or 2,2′-methylenedicyclohexyl diisocyanate (H12MDI).

Preferred aliphatic and cycloaliphatic polyisocyanates are hexamethylene 1,6-diisocyanate (HDI), 1-isocyanato-3,3,5-trimethyl-5-isocyanatomethylcyclohexane (isophorone diisocyanate, IPDI) and 4,4′-, 2,4′- and/or 2,2′-methylenedicyclohexyl diisocyanate (H12MDI); particular preference is given to H12MDI and IPDI or mixtures thereof.

Suitable aromatic diisocyanates include naphthylene 1.5-diisocyanate (NDI), tolylene 2,4- and/or 2,6-diisocyanate (TDI), diphenylmethane 2,2′-, 2,4′- and/or 4,4′-diisocyanate (MDI), 3,3′-dimethyl-4,4′-diisocyanato-diphenyl (TODI), p-phenylene diisocyanate (PDI), diphenylethan-4,4′-diisoyanate (EDI), diphenylmethandiisocyanate, 3,3′-dimethyl-diphenyl-diisocyanate, 1,2-diphenylethandiisocyanate and/or phenylene diisocyanat.

The at present most preferred diisocyanates are 4,4′-, 2,4′- and/or 2,2′-methylenedicyclohexyl diisocyanate (H12MDI), isophorone diisocyanates (IPDI), or tolylene 2,4- and/or 2,6-diisocyanate (TDI).

Polyester polyols (D3) derived from dicarboxylic acid and diols are preferred and, for example, described in US20160122465. The dicarboxylic acids used for making the polyester polyol include aliphatic, or cycloaliphatic dicarboxylic acids, or combinations thereof. Among them, aliphatic dicarboxylic acids are preferred. Suitable aliphatic dicarboxylic acids which can be used alone or in mixture typically contain from 4 to 12 carbon atoms and include: succinic acid, glutaric acid, adipic acid, pimelic acid, suberic acid, and the like. Adipic acid is preferred.

The diols used for making the polyester polyol include aliphatic, or cycloaliphatic diols, or combinations thereof, preferably aliphatic diols containing 2 to 8 carbon atoms and more preferably 2 to 6 carbon atoms. Some representative examples of aliphatic diols that can be used include ethylene glycol, 1,3-propanediol, 1,4-butanediol, 1,5-pentanediol, 1,6-hexanediol and the like.

In a preferred embodiment, only one kind of aliphatic dicarboxylic acid is used in making the polyester polyol. In another preferred embodiment, one or two kinds of aliphatic diols are used in making the polyester polyol. Most preferably, the polyester polyol is derived from adipic acid and ethylene glycol and 1,4-butanediol (poly(ethylene 1,4-butylene adipate) diol, PEBA). In the PEBA, the molar ratio of ethylene glycol to 1,4-butanediol is from 0.05:1 to 10:1, preferably from 0.2:1 to 5:1, more preferably 0.5:1 to 1.5:1, most preferred from 0.75:1 to 1.25:1.

The linear polyester polyol will typically have a number average molecular weight within the range of 4×10² to 7.0×10³, preferably 8×10² to 6.0×10³, more preferably 1×10³ to 5.0×10³. In a preferred embodiment, the linear polyol is polyester polyol derived from one kind of aliphatic dicarboxylic acid and two kinds of aliphatic diols and has a number average molecular weight of from 2.0×10³ to 4.0×10³. In another preferred embodiment, the linear polyol is polyester polyol derived from one kind of aliphatic dicarboxylic acid and one kind of aliphatic diol and has a number average molecular weight of from 1.5×10³ to 4.0×10³, and more preferably from 1.8×10³ to 3.5×10³. All molecular weights specified in this text have the unit of [g/mol] and refer, unless indicated otherwise, to the number average molecular weight (Mn).

The polyester urethane acrylates, or methacrylates (B2) have viscosities in the range of 2000 to 20000 mPas at 60° C.

A secondary polyol, such as, for example, glycerol, may be used, to finetune the mechanical properties of the inventive urethane (meth)acrylates by introducing linear or branched structural elements.

In another preferred embodiment the polyester urethane (meth)acrylate (B2) is obtained by reacting a hydroxyalkyl(meth)acrylate of formula

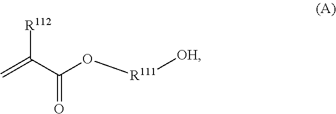

with a lactone of formula

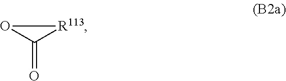

and at least one cycloaliphatic or asymmetric aliphatic diisocyanate, wherein R¹¹¹ is a divalent alkylene radical having 2 to 12 carbon atoms and which may optionally be substituted by C₁-C₄alkyl groups and/or interrupted by one or more oxygen atoms, R¹² in each case independently of any other is methyl or hydrogen, R¹¹³ is a divalent alkylene radical having 1 to 12 carbon atoms and which may optionally be substituted by C₁ to C₄ alkyl groups and/or interrupted by one or more oxygen atoms. Reference is made to WO14191228A1
R¹¹¹ is preferably selected from the group consisting of 1,2-ethylene, 1,2- or 1,3-propylene, 1,2-, 1,3-, or 1,4-butylene, 1,1-dimethyl-1,2-ethylene, 1,2-dimethyl-1,2-ethylene, 1,5-pentylene, 1,6-hexylene, 1,8-octylene, 1,10-decylene, and 1,12-dodecylene.

R¹¹³ is preferably selected from the group consisting of methylene, 1,2-ethylene, 1,2-propylene, 1,3-propylene, 1,2-butylene, 1,3-butylene, 1,4-butylene, 1,5-pentylene, 1,5-hexylene, 1,6-hexylene, 1,8-octylene, 1,10-decylene, 1,12-dodecylene, 2-oxa-1,4-butylene, 3-oxa-1,5-pentylene, and 3-oxa-1,5-hexylene.

The hydroxyalkyl(meth)acrylate of formula (A) is preferably selected from the group consisting of 2-hydroxyethyl(meth)acrylate, 2- or 3-hydroxypropyl(meth)acrylate, 1,4-butanediol mono(meth)acrylate, neopentyl glycol mono(meth)acrylate, 1,5-pentanediol mono(meth)acrylate, and 1,6-hexanediol mono(meth)acrylate.

The lactone of formula

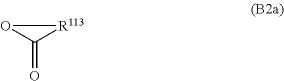

is preferably selected from the group consisting of β-propiolactone, γ-butyrolactone, γ-ethyl-gamma-butyrolactone, γ-valerolactone, delta-valerolactone, ε-caprolactone, 7-methyloxepan-2-one, 1,4-dioxepan-5-one, oxacyclotridecan-2-one, and 13-butyl-oxacyclotridecan-2-one.

Cycloaliphatic diisocyanates are 1,4-, 1,3-, or 1,2-diisocyanatocyclohexane, 4,4′-, 2,4′- and/or 2,2′-methylenedicyclohexyl diisocyanate (H12MDI),

bis(isocyanatomethyl)bicyclo[2.2.1]heptane (NBDI), 1-isocyanato-3,3,5-trimethyl-5-(isocyanatomethyl)cyclohexane(isophorone diisocyanate), 1,3- or 1,4-bis(isocyanatomethyl)cyclohexane or 2,4- or 2,6-diisocyanato-1-methylcyclohexane, and also 3(or 4),8(or 9)-bis(isocyanatomethyl)tricyclo[5.2.1.02.6]decane isomer mixtures.

Asymmetric aliphatic diisocyanates are derivatives of lysine diisocyanate, or tetramethylxylylene diisocyanate, trimethylhexane diisocyanate, or tetramethylhexane diisocyanate.

Very particular preference is given to di(isocyanatocyclohexyl)methane, 2,2,4- and 2,4,4-trimethylhexane diisocyanate, and especially 4,4′-, 2,4′- and/or 2,2′-methylenedicyclohexyl diisocyanate (H12MDI).

The urethane (meth)acrylates can be in particular produced by reacting s-caprolactone, 4,4-, 2,4′- and/or 2,2′-methylenedicyclohexyl diisocyanate (H12MDI) and hydroxyethylacrylate.

In another preferred embodiment the polyester urethane (meth)acrylate (B2) is obtained by reacting a polyalkylene glycol with a lactone of formula

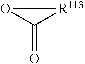

(B2a), at least one cycloaliphatic or asymmetric aliphatic diisocyanate, and an hydroxyalkyl(meth)acrylate of formula (A).

The hydroxyalkyl(meth)acrylate of formula (A) is preferably selected from the group consisting of 2-hydroxyethyl(meth)acrylate, 2- or 3-hydroxypropyl(meth)acrylate, 1,4-butanediol mono(meth)acrylate, neopentyl glycol mono(meth)acrylate, 1,5-pentanediol mono(meth)acrylate, and 1,6-hexanediol mono(meth)acrylate.

The urethane (meth)acrylates can be in particular produced by reacting a polyalkylene glycol, preferably a polyethylene glycol, with s-caprolactone, 4,4′-, 2,4′- and/or 2,2′-methylenedicyclohexyl diisocyanate (H12MDI) and hydroxyethylacrylate.

Examples of commercially available water insoluble reactive oligomers (B2) are Urethane (meth)acrylates:
Genomer® 4247, 4205, 4297, 4690 (Rahn), BR-952 (Dymax), Ebecryl® 5129 8702 (Allnex);

Epoxy acrylates:
Genomer® 2281, Ebecryl® 3708, Laromer® 8986 (BASF); and

Dendritic acrylates:

BDT-1015.

Examples of slightly water-soluble oligomers (B2) are Ebecryl® 4587 (Allnex), Miramer® 2601 NT, 2100 (Miwon) and SWA8401 (Soltech).

In a particularly preferred embodiment the present invention is directed to photocurable compositions comprising acryloylmorpholine (ACMO) as water-soluble reactive diluent (A1).

In said embodiment the photocurable composition may comprise

(A1) ACMO as a water-soluble reactive diluent (A1) in an amount of 9-59% by weight;

(A2) at least one water-soluble reactive oligomer (A2) in an amount of 11-59% by weight;

(B) a slightly water-soluble reactive diluent (B1b) in an amount of 9-59% by weight; and

(C) a photoinitiator (C) in an amount of 0.5-5% by weight. The amount of components (A1), (A2), (B1b) and (C) adds up to 100% by weight.

An example of such a formulation is shown in the table below:

| Component | Compound | % by weight |
|---|---|---|
| (A1) | ACMO | 9-59 |
| (A2) | Water dilutable aliphatic urethane acrylate, | 11-59 |
| | such as, for example, UCECOAT ® 6569 | |
| (B1b) | Cyclic trimethylolpropane formal acrylate | 9-59 |
| (C) | Photoinitiator | 0.5-5 |

In said embodiment the photocurable composition may alternatively comprise

(A1) acryloylmorpholine in an amount of 9-59% by weight and a 2^{nd} water soluble reactive diluent in an amount of 0.9-39% by weight as water-soluble reactive diluent (A1);

(A2) at least one water-soluble reactive oligomer (A2) in an amount of 11-59% by weight;

(B) a water-insoluble reactive diluent (B1a) in an amount of 0.9-39% by weight; and

(C) a photoinitiator (C) in an amount of 0.5-5% by weight. The amount of components (A1), (A2), (B1a) and (C) adds up to 100% by weight.

An example of such a formulation is shown in the table below:

| Component | Compound | % by weight |
|---|---|---|
| (A1) | ACMO | 9-59 |
| (A1) | Polyethylene glycol (200) diacrylate | 0.9-39 |
| (A2) | Water dilutable aliphatic urethane acrylate, | 11-59 |
| | such as, for example, UCECOAT ® 6569 | |
| (B1a) | Trimethylolpropane triacrylate | 0.9-39 |
| (C) | Photoinitiator | 0.5-5 |

In said embodiment the photocurable composition may alternatively comprise

(A1) ACMO in an amount of 9-59% by weight as water-soluble reactive diluent (A1);

(A2) at least one water-soluble reactive oligomer (A2) in an amount of 11-59% by weight;

(B) a water-insoluble reactive diluent (B1a) in an amount of 0.9-39% by weight, a slightly water-soluble reactive diluent (B1b) in an amount of 9-59% by weight and a 2^{nd} water-soluble reactive diluent (B1b) in an amount of 0.9-39% by weight; and

(C) a photoinitiator (C) in an amount of 0.5-5% by weight. The amount of components (A1), (A2), (B1a), (B1b) and (C) adds up to 100% by weight.

An example of such a formulation is shown in the table below:

| Component | Compound | % by weight |
|---|---|---|
| (A1) | ACMO | 9-59 |
| (A2) | Water dilutable aliphatic urethane acrylate, | 11-59 |
| | such as, for example, UCECOAT ® 6569 | |
| (B1b) | Cyclic trimethylolpropane formal acrylate | 9-59 |
| (B1a) | Trimethylolpropane triacrylate (TMPTA) | 0.9-39 |
| (B1b) | Triethylene glycol dimethacrylate | 0.9-39 |
| | (TEGDMA) | |
| (C) | Photoinitiator | 0.5-5 |

In said embodiment the photocurable composition may alternatively comprise

(A1) ACMO in an amount of 9-59% by weight as water-soluble reactive diluent (A1) and a 2^{nd} water soluble reactive diluent in an amount of 0.9-39% by weight;

(A2) at least one water-soluble reactive oligomer (A2) in an amount of 11-59% by weight;

(B) a water-insoluble reactive diluent (B1a) in an amount of 0.9-39% by weight, a slightly water-soluble reactive diluent (B1b) in an amount of 9-59% by weight; and

(C) a photoinitiator (C) in an amount of 0.5-5% by weight. The amount of components (A1), (A2), (B1a), (B1b) and (C) adds up to 100% by weight.

An example of such a formulation is shown in the table below:

| Component | Compound | % by weight |
|---|---|---|
| (A1) | ACMO | 9-59 |
| (A2) | Water dilutable aliphatic urethane acrylate, | 11-59 |
| | such as, for example, UCECOAT ® 6569 | |
| (B1b) | Cyclic trimethylolpropane formal acrylate | 9-59 |
| (B1a) | Trimethylolpropane triacrylate (TMPTA) | 0.9-39 |
| (A1) | Poly(ethylene glycol) diacrylate (average | 0.9-39 |
| | Mn 250; PEGDA250) | |
| (C) | Photoinitiator | 0.5-5 |

In another particularly preferred embodiment the present invention is directed to photocurable compositions comprising N-vinyl-S-methyl oxazolidinone (NVMO) as water-soluble reactive diluent (A1).

In said embodiment the photocurable composition may comprise

(A1) NVMO as a water-soluble reactive diluent (A1) in an amount of 9-59% by weight;

(A2) at least one water-soluble reactive oligomer (A2) in an amount of 11-59% by weight;

(B) a water-insoluble reactive oligomer (B2) in an amount of 0.9-39% by weight; and

(C) a photoinitiator (C) in an amount of 0.5-5% by weight. The amount of components (A1), (A2), (B2) and (C) adds up to 100% by weight.

An example of such a formulation is shown in the table below:

| Component | Compound | % by weight |
|---|---|---|
| (A1) | N-vinyl-5-methyl oxazolidinone (NVMO) | 9-59 |
| (A2) | Water dilutable aliphatic urethane acrylate, | 11-59 |
| | such as, for example, UCECOAT ® 6569 | |
| (B1) | 2-functional aliphatic urethane | 0.9-39 |
| | methacrylate, such as, for example, | |
| | GENOMER ® 4247 | |
| (C) | Photoinitiator | 0.5-5 |

In said embodiment the photocurable composition may alternatively comprise

(A1) NVMO as a water-soluble reactive diluent (A1) in an amount of 9-59% by weight;

(A2) at least one water-soluble reactive oligomer (A2) in an amount of 11-59% by weight;

(B) a slightly water-soluble reactive diluent (B1b) in an amount of 0.9-29% by weight and a water-insoluble reactive oligomer (B2) in an amount of 0.9-29% by weight; and

(C) a photoinitiator (C) in an amount of 0.5-5% by weight. The amount of components (A1), (A2), (B1b), (B2) and (C) adds up to 100% by weight.

An example of such a formulation is shown in the table below:

| Component | Compound | % by weight |
|---|---|---|
| (A1) | N-vinyl-5-methyl oxazolidinone (NVMO) | 9-59 |
| (A2) | Water dilutable aliphatic urethane acrylate, | 11-59 |
| | such as, for example, UCECOAT ® 6569 | |
| (B2) | 2-functional aliphatic urethane | 0.9-29 |
| | methacrylate, such as, for example, | |
| | GENOMER ® 4247 | |
| (B1b) | Triethylene glycol dimethacrylate | 0.9-29 |
| | (TEGDMA) | |
| (C) | Photoinitiator | 0.5-5 |

In said embodiment the photocurable composition may alternatively comprise

(A1) NVMO as a water-soluble reactive diluent (A1) in an amount of 9-59% by weight;

(A2) at least one water-soluble reactive oligomer (A2) in an amount of 11-59% by weight;

(B) a 1^{st} water-insoluble reactive diluent (B1a) in an amount of 0.9-29% by weight, a 2^{nd} water-insoluble reactive diluent (B1a) in an amount of 0.9-29% by weight and a water-insoluble reactive oligomer (B2) in an amount of 0.9-29% by weight; and

(C) a photoinitiator (C) in an amount of 0.5-5% by weight. The amount of components (A1), (A2), (B1a), (B2) and (C) adds up to 100% by weight.

An example of such a formulation is shown in the table below:

| Component | Compound | % by weight |
|---|---|---|
| (A1) | N-vinyl-5-methyl oxazolidinone (NVMO) | 9-59 |
| (A2) | UCECOAT ® 6569 | 11-59 |
| (B2) | GENOMER ® 4247 (urethane methacrylate) | 0.9-29 |
| (B1a) | Trimethylolpropane triacrylate (TMPTA) | 0.9-29 |
| (B1a) | Ethoxylated (3) trimethylolpropane | 0.9-29 |
| | triacrylate | |
| (C) | Photoinitiator | 0.5-5 |

In another particularly preferred embodiment the present invention is directed to photocurable compositions comprising N-Vinyl-caprolactam (NVC) as water-soluble reactive diluent (A1).

In said embodiment the photocurable composition may alternatively comprise

(A1) NVC as a water-soluble reactive diluent (A1) in an amount of 9-59% by weight;

(A2) at least one water-soluble reactive oligomer (A2) in an amount of 11-59% by weight;

(B) a 1^{st} water-insoluble reactive oligomer (B2) in an amount of 0.9-59% by weight and a 2^{nd} water-insoluble reactive oligomer (B2) in an amount of 0.9-39% by weight; and

(C) a photoinitiator (C) in an amount of 0.5-5% by weight. The amount of components (A1), (A2), (B1a), (B2) and (C) adds up to 100% by weight.

| Component | Compound | % by weight |
|---|---|---|
| (A1) | N-Vinyl-caprolactam (NVC) | 9-59 |
| (A2) | UCECOAT ® 6569 | 11-59 |
| (B2) | GENOMER ® 4247 (urethane | 0.9-39 |
| | methacrylate) | |
| (B2) | Ebecryl ® 4587 (urethane acrylate) | 0.9-59 |
| (C) | Photoinitiator | 0.5-5 |

In another particularly preferred embodiment the present invention is directed to photocurable compositions no water-soluble reactive diluent (A1).

In said embodiment the photocurable composition may comprise

(A2) at least one water-soluble reactive oligomer (A2) in an amount of 11-59% by weight;

(B) a water-insoluble reactive diluent (B1a) in an amount of 0.9-29% by weight, a slightly water-soluble reactive diluent (1b) in an amount of 9-59% by weight and a water-insoluble reactive oligomer (B2) in an amount of 0.9-29% by weight; and

(C) a photoinitiator (C) in an amount of 0.5-5% by weight. The amount of components (A2), (B1a), (B1b), (B2) and (C) adds up to 100% by weight.

| | | % by |
|---|---|---|
| Component | Compound | weight |
| (A2) | Water dilutable aliphatic urethane acrylate, | 11-59 |
| | such as, for example, UCECOAT ® 6569 | |
| (B1b) | Cyclic trimethylolpropane formal acrylate | 9-59 |
| (B1a) | Trimethylolpropane triacrylate (TMPTA) | 0.9-29 |
| (B2) | 2-functional aliphatic urethane methacrylate, | 0.9-29 |
| | such as, for example, GENOMER ® 4247 | |
| (C) | Photoinitiator | 0.5-5 |

In said embodiment the photocurable composition may alternatively comprise

(A2) at least one water-soluble reactive oligomer (A2) in an amount of 11-59% by weight;

(B) a water-insoluble reactive diluent (B1a) in an amount of 0.9-29% by weight, a 1^{st} slightly water-soluble reactive diluent (B1b) in an amount of 9-59% by weight, a 2^{nd} slightly water-soluble reactive diluent (B1b) in an amount of 0.9-9% by weight and a water-insoluble reactive oligomer (B2) in an amount of 0.9-29% by weight; and

(C) a photoinitiator (C) in an amount of 0.5-5% by weight. The amount of components (A2), (B1a), (B1b), (B2) and (C) adds up to 100% by weight.

| Component | Compound | % by weight |
|---|---|---|
| (B1b) | 2-[[(Butylamino)carbonyl]oxy]ethyl acrylate | 0.9-9 |
| | (Genomer ® 1122) | |
| (A2) | UCECOAT ® 6569 | 11-59 |
| (B1b) | Cyclic trimethylolpropane formal acrylate | 9-59 |
| | (LR 8887) | |
| (B1a) | Trimethylolpropane triacrylate (TMPTA) | 0.9-29 |
| (B2) | GENOMER ® 4247 (urethane methacrylate) | 0.9-29 |
| (C) | Photoinitiator | 0.5-5 |

It should be noted that some slightly water soluble reactive diluents (e.g. Laromer 8887) are soluble in water in warm water, i.e. at around 50° C. These monomers are key to keep good water washability even without water soluble monomers.

Photoinitiator (C)

The photoinitiator (C) may be a single compound, or a mixture of compounds. Examples of photoinitiators (C) are known to the person skilled in the art and for example published by Kurt Dietliker in “A compilation of photoinitiators commercially available for UV today”, Sita Technology Textbook, Edinburgh, London, 2002.

Examples of suitable acylphosphine oxide compounds are of the formula XII

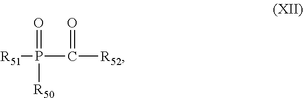

R₅₀ is unsubstituted cyclohexyl, cyclopentyl, phenyl, naphthyl or biphenylyl; or is cyclohexyl, cyclopentyl, phenyl, naphthyl or biphenylyl substituted by one or more halogen, C₁-C₁₂alkyl, C₁-C₁₂alkoxy, C₁-C₁₂alkylthio or by NR₅₃R₅₄;

or R₅₀ is unsubstituted C₁-C₂₀alkyl or is C₁-C₂₀alkyl which is substituted by one or more halogen, C₁-C₁₂alkoxy, C₁-C₁₂alkylthio, NR₅₃R₅₄ or by —(CO)—O—C₁-C₂₄alkyl;

R₅₁ is unsubstituted cyclohexyl, cyclopentyl, phenyl, naphthyl or biphenylyl; or is cyclohexyl, cyclopentyl, phenyl, naphthyl or biphenylyl substituted by one or more halogen, C₁-C₁₂alkyl, C₁-C₁₂alkoxy, C₁-C₁₂alkylthio or by NR₅₃R₅₄; or R₅₁ is —(CO)R′₅₂; or

R₅₁ is C₁-C₁₂alkyl which is unsubstituted or substituted by one or more halogen, C₁-C₁₂alkoxy, C₁-C₁₂alkylthio, or by NR₅₃R₅₄;

R₅₂ and R′₅₂ independently of each other are unsubstituted cyclohexyl, cyclopentyl, phenyl, naphthyl or biphenylyl, or are cyclohexyl, cyclopentyl, phenyl, naphthyl or biphenylyl substituted by one or more halogen, C₁-C₄alkyl or C₁-C₄alkoxy; or R₅₂ is a 5- or 6-membered heterocyclic ring comprising an S atom or N atom;

R₅₃ and R₅₄ independently of one another are hydrogen, unsubstituted C₁-C₁₂alkyl or C₁-C₁₂alkyl substituted by one or more OH or SH wherein the alkyl chain optionally is interrupted by one to four oxygen atoms; or R₅₃ and R₅₄ independently of one another are C₂-C₁₂-alkenyl, cyclopentyl, cyclohexyl, benzyl or phenyl;

In a particularly preferred embodiment the photoinitiator (C) is a compound of the formula (XII), such as, for example, bis(2,4,6-trimethylbenzoyl)-phenylphosphine oxide; 2,4,6-trimethylbenzoyl-diphenyl-phosphine oxide; ethyl (2,4,6 trimethylbenzoyl phenyl) phosphinic acid ester; (2,4,6-trimethylbenzoyl)-2,4-dipentoxyphenylphosphine oxide and bis(2,6-dimethoxybenzoyl)-2,4,4-trimethylpentylphosphine oxide.

Interesting further are mixtures of the compounds of the formula (XII) with compounds of the formula (XI) as well as mixtures of different compounds of the formula (XII).

Examples are mixtures of bis(2,6-dimethoxybenzoyl)-2,4,4-trimethylpentylphosphine oxide with 1-hydroxy-cyclohexyl-phenyl-ketone, of bis(2,4,6-trimethylbenzoyl)-phenylphosphine oxide with 2-hydroxy-2-methyl-1-phenyl-propan-1-one, of bis(2,4,6-trimethyl-benzoyl)-phenylphosphine oxide with ethyl (2,4,6 trimethylbenzoyl phenyl) phosphinic acid ester, etc.

Examples of suitable benzophenone compounds are compounds of the formula

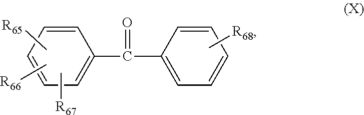

R₆₅, R₆₆ and R₆₇ independently of one another are hydrogen, C₁-C₄alkyl, C₁-C₄-halogenalkyl, C₁-C₄alkoxy, Cl or N(C₁-C₄alkyl)₂;

R₆₈ is hydrogen, C₁-C₄alkyl, C₁-C₄halogenalkyl, phenyl, N(C₁-C₄alkyl)₂, COOCH₃,

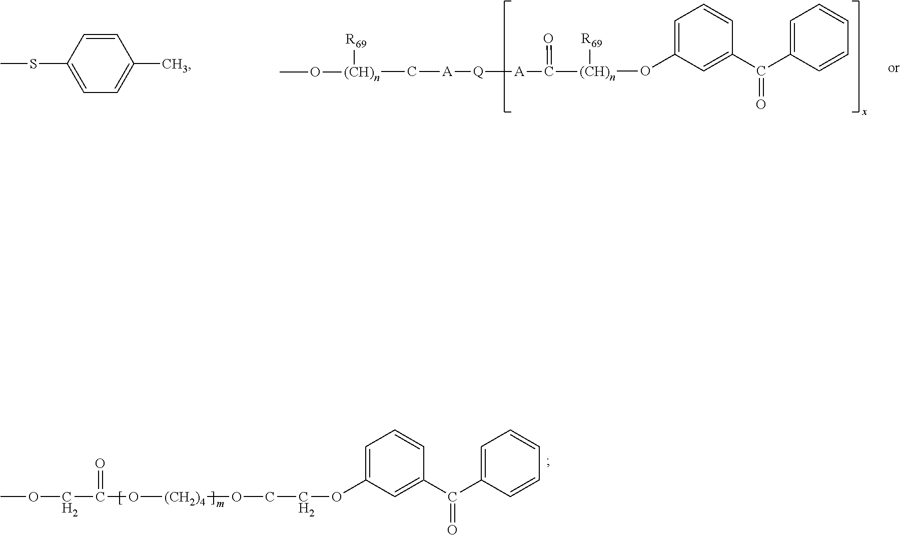

Q is a residue of a polyhydroxy compound having 2 to 6 hydroxy groups;

x is a number greater than 1 but no greater than the number of available hydroxyl groups in Q;

A is —[O(CH₂)_{b}CO]_{y}— or —[O(CH₂)_{b}CO]_{(y-1)}[O(CHR₆₉CHR_{69′})ₐ]_{y}—;

R₆₉ and R_{69′} independently of one another are hydrogen, methyl or ethyl; and if n (or a) is greater than 1 the radicals R₆₉ may be the same as or different from each other;

a is a number from 1 to 2;

b is a number from 4 to 5;

y is a number from 1 to 10;

n is; and

m is an integer 2-10.

Specific examples are benzophenone, Esacure TZT® available from IGM, (a mixture of 2,4,6-trimethylbenzophenone and 4-methylbenzophenone), 4-phenylbenzophenone, 4-methoxybenzophenone, 4,4′-dimethoxybenzophenone, 4,4′-dimethylbenzophenone, 4,4′-dichlorobenzophenone, 4,4′-dimethylaminobenzophenone, 4,4′-diethylaminobenzophenone, 4-methylbenzophenone, 2,4,6-trimethylbenzophenone, 4-(4-methylthiophenyl)benzophenone, 3,3′-dimethyl-4-methoxybenzophenone, methyl-2-benzoylbenzoate, 4-(2-hydroxyethylthio)benzophenone, 4-(4-tolylthio)benzophenone, 4-benzoyl-N,N,N-trimethylbenzenemethanaminium chloride, 2-hydroxy-3-(4-benzoylphenoxy)-N,N,N-trimethyl-1-propanaminium chloride monohydrate, 4-(13-acryloyl-1,4,7,10,13-pentaoxatridecyl)benzophenone, 4-benzoyl-N,N-dimethyl-N-[2-(1-oxo-2-propenyl)oxy]ethylbenzenemethanaminium chloride; [4-(2-hydroxy-ethylsul-fanyl)-phenyl]-(4-isopropylphenyl)-methanone; biphenyl-[4-(2-hydroxy-ethylsulfanyl)-phenyl]-methanone; biphenyl-4-yl-phenyl-methanone; biphenyl-4-yl-p-tolyl-methanone; biphenyl-4-yl-m-tolyl-methanone; [4-(2-hydroxy-ethylsulfanyl)-phenyl]-p-tolyl-methanone; [4-(2-hydroxy-ethylsulfanyl)-phenyl]-(4-isopropyl-phenyl)-methanone; [4-(2-hydro-xy-ethylsulfanyl)-phenyl]-(4-methoxy-phenyl)-methanone; 1-(4-benzoyl-phenoxy)-prop-an-2-one; [4-(2-hydroxy-ethylsulfanyl)-phenyl]-(4-phenoxy-phenyl)-methanone; 3-(4-benzoyl-phenyl)-2-dimethylamino-2-methyl-1-phenyl-propan-1-one; (4-chloro-phenyl)-(4-octylsulfanyl-phenyl)-methanone; (4-chloro-phenyl)-(4-dodecylsulfanyl-phenyl)-methanone; (4-bromo-phenyl)-(4-octylsulfanyl-phenyl)-methanone; (4-dodecylsulfanyl-phen-yl)-(4-methoxy-phenyl)-methanone; (4-benzoyl-phenoxy)-acetic acid methyl ester; biphenyl-[4-(2-hydroxy-ethylsulfanyl)-phenyl]-methanone; 1-[4-(4-benzoylphenylsulfanyl)phenyl]-2-methyl-2-(4-methylphenylsulfonyl)propan-1-one (Esacure®1001 available from IGM).

Examples of suitable alpha-hydroxy ketone, alpha-alkoxyketone or alpha-aminoketone compounds are of the formula

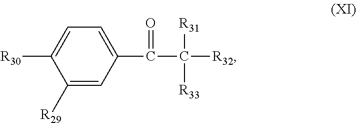

wherein

R₂₉ is hydrogen or C₁-C₁₈alkoxy;

R₃₀ is hydrogen, C₁-C₁₈alkyl, C₁-C₁₂hydroxyalkyl, C₁-C₁₈alkoxy, OCH₂CH₂—OR₃₄, morpholino, S—C₁-C₁₈alkyl, a group —HC═CH₂, —C(CH₃)═CH₂,

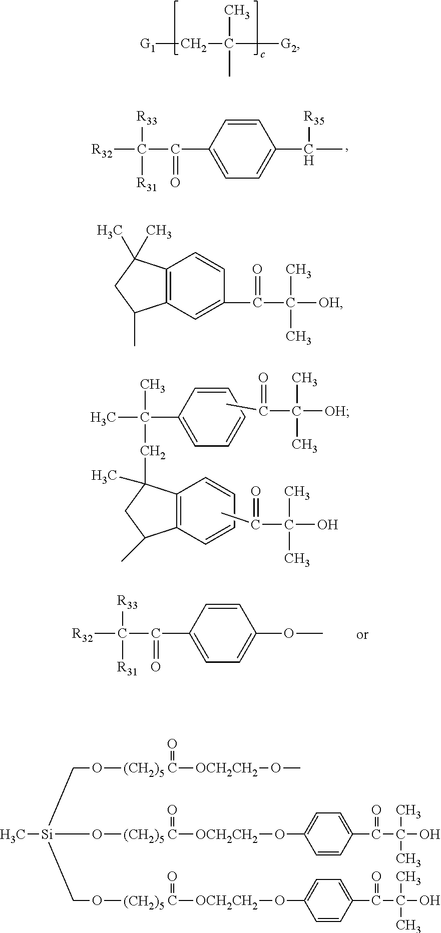

D, E and f are 1-3;

c is 2-10;

G₁ and G₂ independently of one another are end groups of the polymeric structure, preferably hydrogen or methyl;

R₃₄ is hydrogen,

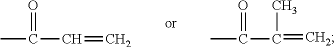

R₃₁ is hydroxy, C₁-C₁₆alkoxy, morpholino, dimethylamino or —O(CH₂CH₂O)₉—C₁-C₁₆alkyl;

g is 1-20;

R₃₂ and R₃₃ independently of one another are hydrogen, C₁-C₆alkyl, C₁-C₁₆alkoxy or —O(CH₂CH₂O)₉—C₁-C₁₆alkyl; or are unsubstituted phenyl or benzyl; or phenyl or benzyl substituted by C₁-C₁₂-alkyl; or R₃₂ and R₃₃ together with the carbon atom to which they are attached form a cyclohexyl ring;

R₃₅ is hydrogen, OR₃₆ or NR₃₇R₃₈;

R₃₆ is hydrogen, C₁-C₁₂alkyl which optionally is interrupted by one or more non-consecutive O-atoms and which uninterrupted or interrupted C₁-C₁₂alkyl optionally is substituted by one or more OH,

or

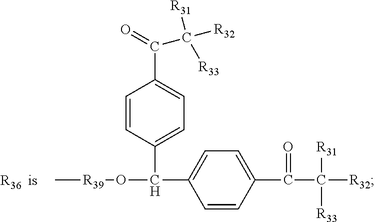

R₃₇ and R₃₈ independently of each other are hydrogen or C₁-C₁₂alkyl which is unsubstituted or is substituted by one or more OH;

R₃₉ is C₁-C₁₂alkylene which optionally is interrupted by one or more non-consecutive O, —(CO)—NH—C₁-C₁₂alkylene-NH—(CO)— or

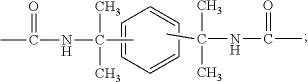

with the proviso that R₃₁, R₃₂ and R₃₃ not all together are C₁-C₁₆alkoxy or —O(CH₂CH₂O)_{g}—C₁-C₁₆alkyl.

Specific examples are 1-hydroxy-cyclohexyl-phenyl-ketone or a mixture of 1-hydroxy-cyclohexyl-phenyl-ketone with benzophenone), 2-methyl-1[4-(methylthio)phenyl]-2-morpholinopropan-1-one, 2-benzyl-2-dimethylamino-1-(4-morpholinophenyl)-butan-1-one, 2-dimethylamino-2-(4-methyl-benzyl)-1-(4-morpholin-4-yl-phenyl)-butan-1-one, (3,4-dimethoxy-benzoyl)-1-benzyl-1-dimethylamino propane, 1-[4-(2-hydroxyethoxy)-phenyl]-2-hydroxy-2-methyl-1-propan-1-one, 2,2-dimethoxy-1,2-diphenylethan-1-one, 2-hydroxy-2-methyl-1-phenyl-propan-1-one, 2-hydroxy-1-{4-[4-(2-hydroxy-2-methyl-propionyl)-benzyl]-phenyl}-2-methyl-propan-1-one, 2-hydroxy-1-{4-[4-(2-hydroxy-2-methyl-propionyl)-phenoxy]-phenyl}-2-methyl-propan-1-one, Esacure KIP provided by IGM, 2-hydroxy-1-{1-[4-(2-hydroxy-2-methyl-propionyl)-phenyl]-1,3,3-trimethyl-indan-5-yl}-2-methyl-propan-1-one.

Examples of suitable phenylglyoxylate compounds are of the formula

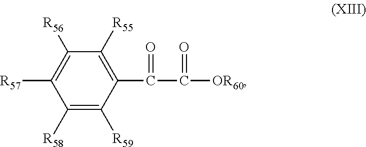

wherein

R₆₀ is hydrogen, C₁-C₁₂alkyl or

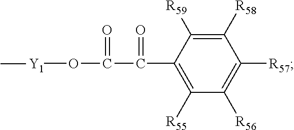

R₅₅, R₅₆, R₅₇, R₅₈ and R₅₉ independently of one another are hydrogen, unsubstituted C₁-C₁₂alkyl or C₁-C₁₂alkyl substituted by one or more OH, C₁-C₄alkoxy, phenyl, naphthyl, halogen or by CN; wherein the alkyl chain optionally is interrupted by one or more oxygen atoms; or R₅₅, R₅₆, R₅₇, R₅₈ and R₅₉ independently of one another are C₁-C₄alkoxy, C₁-C₄alkythio or NR₅₂R₅₃;

R₅₂ and R₅₃ independently of one another are hydrogen, unsubstituted C₁-C₁₂alkyl or C₁-C₁₂alkyl substituted by one or more OH or SH wherein the alkyl chain optionally is interrupted by one to four oxygen atoms; or R₅₂ and R₅₃ independently of one another are C₂-C₁₂-alkenyl, cyclopentyl, cyclohexyl, benzyl or phenyl; and

Y₁ is C₁-C₁₂alkylene optionally interrupted by one or more oxygen atoms.

Specific examples of the compounds of the formula XIII are oxo-phenyl-acetic acid 2-[2-(2-oxo-2-phenyl-acetoxy)-ethoxy]-ethyl ester (Irgacure®754), methyl α-oxo benzeneacetate.

Examples of suitable oxime ester compounds are of the formula

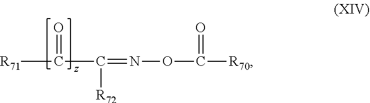

wherein z is 0 or 1;

R₇₀ is hydrogen, C₃-C₈cycloalkyl; C₁-C₁₂alkyl which is unsubstituted or substituted by one or more halogen, phenyl or by CN; or R₇₀ is C₂-C₅alkenyl; phenyl which is unsubstituted or substituted by one or more C₁-C₆alkyl, halogen, CN, OR₇₃, SR₇₄ or by NR₇₅R₇₆; or R₇₀ is C₁-C₈alkoxy, benzyloxy; or phenoxy which is unsubstituted or substituted by one or more C₁-C₆alkyl or by halogen;

R₇₁ is phenyl, naphthyl, benzoyl or naphthoyl, each of which is substituted by one or more halogen, C₁-C₁₂alkyl, C₃-C₈cycloalkyl, benzyl, phenoxycarbonyl, C₂-C₁₂alkoxycarbonyl, OR₇₃, SR₇₄, SOR₇₄, SO₂R₇₄ or by NR₇₅R₇₆, wherein the substituents OR₇₃, SR₇₄ and NR₇₅R₇₆ optionally form 5- or 6-membered rings via the radicals R₇₃, R₇₄, R₇₅ and/or R₇₆ with further substituents on the phenyl or naphthyl ring; or each of which is substituted by phenyl or by phenyl which is substituted by one or more OR₇₃, SR₇₄ or by NR₇₅R₆₆; or R₇₁ is thioxanthyl, or

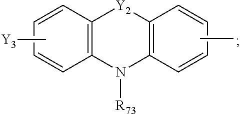

R₇₂ is hydrogen; unsubstituted C₁-C₂₀alkyl or C₁-C₂₀alkyl which is substituted by one or more halogen, OR₇₃, SR₇₄, C₃-C₈cycloalkyl or by phenyl; or is C₃-C₈cycloalkyl; or is phenyl which is unsubstituted or substituted by one or more C₁-C₆alkyl, phenyl, halogen, OR₇₃, SR₇₄ or by NR₇₅R₇₆; or is C₂-C₂₀alkanoyl or benzoyl which is unsubstituted or substituted by one or more C₁-C₈alkyl, phenyl, OR₇₃, SR₇₄ or by NR₇₅R₇₆; or is C₂-C₁₂alkoxycarbonyl, phenoxycarbonyl, CN, CONR₇₅R₇₆, NO₂, C₁-C₄haloalkyl, S(O)_{y}—C₁-C₈alkyl, or S(O)_{y}-phenyl,

y is 1 or 2;

Y₂ is a direct bondor no bond;

Y₃ is NO₂ or

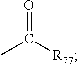

R₇₃ and R₇₄ independently of one another are hydrogen, C₁-C₂₀alkyl, C₂-C₁₂alkenyl, C₃-C₈cycloalkyl, C₃-C₈cycloalkyl which is interrupted by one or more, preferably 2, O, phenyl-C₁-C₃alkyl; or are C₁-C₈alkyl which is substituted by OH, SH, CN, C₁-C₈alkoxy, C₁-C₈alkanoyl, C₃-C₈cycloalkyl, by C₃-C₈cycloalkyl which is interrupted by one or more O, or which C₁-C₈alkyl is substituted by benzoyl which is unsubstituted or substituted by one or more C₁-C₈alkyl, halogen, OH, C₁-C₄alkoxy or by C₁-C₄alkylsulfanyl; or are phenyl or naphthyl, each of which is unsubstituted or substituted by halogen, C₁-C₁₂alkyl, C₁-C₁₂alkoxy, phenyl-C₁-C₃alkyloxy, phenoxy, C₁-C₁₂alkylsulfanyl, phenylsulfanyl, N(C₁-C₁₂alkyl)₂, diphenylamino or by

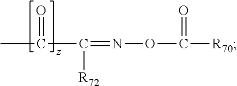

R₇₅ and R₇₆ independently of each other are hydrogen, C₁-C₂₀alkyl, C₂-C₄hydroxyalkyl, C₂-C₁₀alkoxyalkyl, C₂-C₅alkenyl, C₃-C₈cycloalkyl, phenyl-C₁-C₃alkyl, C₁-C₈alkanoyl, C₃-C₁₂alkenoyl, benzoyl; or are phenyl or naphthyl, each of which is unsubstituted or substituted by C₁-C₁₂alkyl, benzoyl or by C₁-C₁₂alkoxy; or R₇₅ and R₇₆ together are C₂-C₆alkylene optionally interrupted by O or NR₇₃ and optionally are substituted by hydroxyl, C₁-C₄alkoxy, C₂-C₄alkanoyloxy or by benzoyloxy;

R₇₇ is C₁-C₁₂alkyl, thienyl or phenyl which is unsubstituted or substituted by C₁-C₁₂alkyl, OR₇₃, morpholino or by N-carbazolyl.

Specific examples are 1,2-octanedione 1-[4-(phenylthio)phenyl]-2-(O-benzoyloxime), ethanone 1-[9-ethyl-6-(2-methylbenzoyl)-9H-carbazol-3-yl]-1-(O-acetyloxime), 9H-thioxanthene-2-carboxaldehyde 9-oxo-2-(O-acetyloxime), ethanone 1-[9-ethyl-6-(4morpholinobenzoyl)-9H-carbazol-3-yl]-1-(O-acetyloxime), ethanone 1-[9-ethyl-6-(2-methyl-4-(2-(1,3-dioxo-2-dimethyl-cyclopent-5-yl)ethoxy)-benzoyl)-9H-carbazol-3-yl]-1-(0-acetyloxime) (Adeka N-1919), ethanone 1-[9-ethyl-6-nitro-9H-carbazol-3-yl]-1-[2-methyl-4-(1-methyl-2-methoxy)ethoxy)phenyl]-1-(O-acetyloxime) (Adeka NC1831), etc.

It is also possible to add cationic photoinitiators, such as benzoyl peroxide (other suitable peroxides are described in U.S. Pat. No. 4,950,581, column 19, lines 17-25), or aromatic sulfonium, phosphonium or iodonium salts, such as are described, for example, in U.S. Pat. No. 4,950,581, column 18, line 60 to column 19, line 10.

Suitable sulfonium salt compounds are of formula

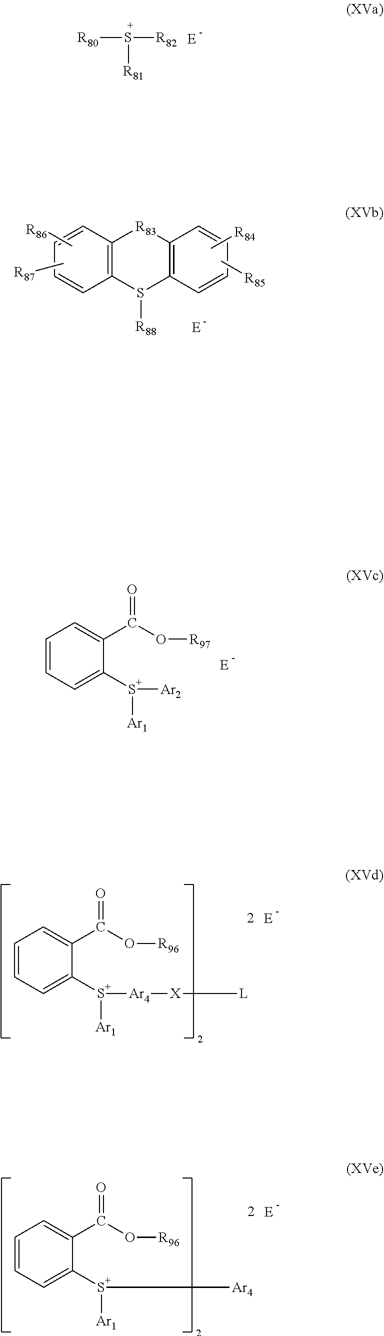

wherein

R₈₀, R₈₁ and R₈₂ are each independently of the others unsubstituted phenyl, or phenyl substituted by —S-phenyl,

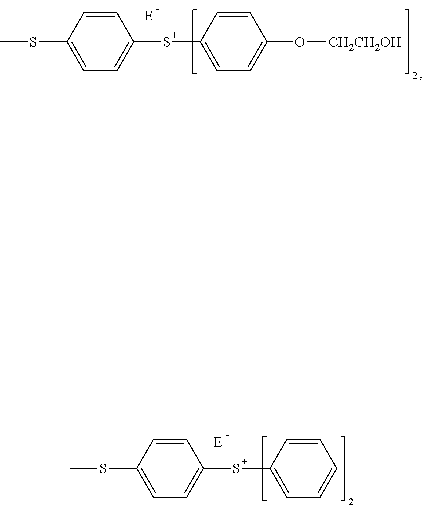

or by

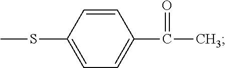

R₈₃ is a direct bond, S, O, CH₂, (CH₂)₂, CO or NR₈₉;

R₈₄, R₈₅, R₈₆ and R₈₇ independently of one another are hydrogen, C₁-C₂₀alkyl, C₃-C₈cycloalkyl, C₁-C₂₀alkoxy, C₂-C₂₀alkenyl, CN, OH, halogen, C₁-C₆alkylthio, phenyl, naphthyl, phenyl-C₁-C₇alkyl, naphtyl-C₁-C₃alkyl, phenoxy, naphthyloxy, phenyl-C₁-C₇alkyloxy, naphtyl-C₁-C₃alkyloxy, phenyl-C₂-C₆alkenyl, naphthyl-C₂-C₄alkenyl, S-phenyl, (CO)R₈₉, O(CO)R₈₉, (CO)OR₈₉, SO₂R₈₉ or OSO₂R₈₉;

R₈₈ is C₁-C₂₀alkyl, C₁-C₂₀hydroxyalkyl,

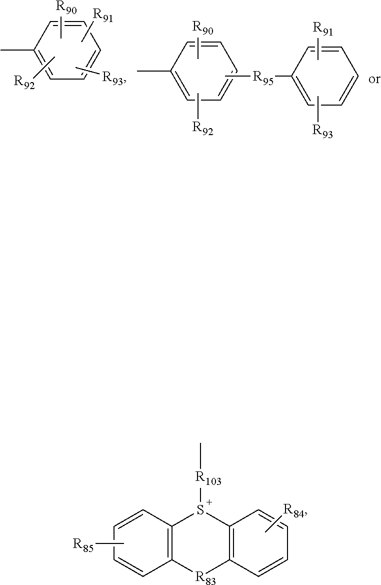

R₈₉ is hydrogen, C₁-C₁₂alkyl, C₁-C₁₂hydroxyalkyl, phenyl, naphthyl or biphenylyl;

R₉₀, R₉₁, R₉₂ and R₉₃ independently of one another have one of the meanings as given for R₈₄; or R₉₀ and R₉₁ are joined to form a fused ring system with the benzene rings to which they are attached;

R₉₅ is a direct bond, S, O or CH₂;

R₉₆ is hydrogen, C₁-C₂₀alkyl; C₂-C₂₀alkyl interrupted by one or more O; or is -L-M-R₉₈ or -L-R₉₈;

R₉₇ has one of the meanings as given for R₉₆ or is

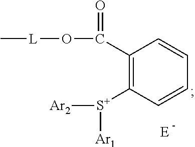

R₉₈ is a monovalent sensitizer or photoinitiator moiety;

Ar₁ and Ar₂ independently of one another are phenyl unsubstituted or substituted by C₁-C₂₀alkyl, halogen or OR₉₉;

or are unsubstituted naphthyl, anthryl, phenanthryl or biphenylyl;

or are naphthyl, anthryl, phenanthryl or biphenylyl substituted by C₁-C₂₀alkyl, OH or OR₉₉; or are —Ar₄-A₁-Ar₃ or

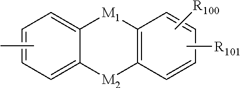

Ar₃ is unsubstituted phenyl, naphthyl, anthryl, phenanthryl or biphenylyl;

or is phenyl, naphthyl, anthryl, phenanthryl or biphenylyl substituted by C₁-C₂₀alkyl, OR₉₉ or benzoyl;

Ar₄ is phenylene, naphthylene, anthrylene or phenanthrylene;

A₁ is a direct bond, S, O or C₁-C₂₀alkylene;

X is CO, C(O)O, OC(O), O, S or NR₉₉;

L is a direct bond, S, O, C₁-C₂₀alkylene or C₂-C₂₀alkylene interrupted by one or more non-consecutive O;

R₉₉ is C₁-C₂₀alkyl or C₁-C₂₀hydroxyalkyl; or is C₁-C₂₀alkyl substituted by O(CO)R₁₀₂;

M₁ is S, CO or NR₁₀₀;

M₂ is a direct bond, CH₂, O or S;

R₁₀₀ and R₁₀₁ independently of one another are hydrogen, halogen, C₁-C₈alkyl, C₁-C₈alkoxy or phenyl;

R₁₀₂ is C₁-C₂₀alkyl; R₁₀₃ is

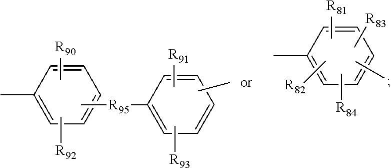

and

E is an anion, especially PF₆, SbF₆, AsF₆, BF₄, (C₆F₅)₄B, Cl, Br, HSO₄, CF₃—SO₃, F—SO₃,

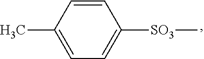

CH₃—SO₃, ClO₄, PO₄, NO₃, SO₄, CH₃—SO₄, or

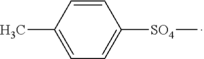

Specific examples of sulfonium salt compounds are for example Irgacure®270 (BASF SE); Cyracure® UVI-6990, Cyracure®UVI-6974 (Union Carbide), Degacure®KI 85 (Degussa), SP-55, SP-150, SP-170 (Asahi Denka), GE UVE 1014 (General Electric), SarCat® KI-85 (=triarylsulfonium hexafluorophosphate; Sartomer), SarCat® CD 1010 (=mixed triarylsulfonium hexafluoroantimonate; Sartomer); SarCat® CD 1011(=mixed triarylsulfonium hexafluorophosphate; Sartomer),

Suitable iodonium salt compounds are of formula

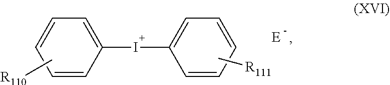

wherein

R₁₁₀ and R₁₁₁ are each independently of the other hydrogen, C₁-C₂₀alkyl, C₁-C₂₀alkoxy, OH-substituted C₁-C₂₀alkoxy, halogen, C₂-C₁₂alkenyl, C₃-C₈cycloalkyl, especially methyl, isopropyl or isobutyl; and

E is an anion, especially PF₆, SbF₆, AsF₆, BF₄, (C₆F₅)₄B, Cl, Br, HSO₄, CF₃—SO₃, F—SO₃,

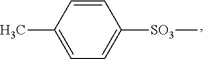

CH₃—SO₃, ClO₄, PO₄, NO₃, SO₄, CH₃—SO₄ or

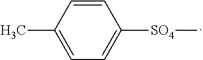

Specific examples of iodonium salt compounds are e.g. tolylcumyliodonium tetrakis(pentafluorophenyl)borate, 4-[(2-hydroxy-tetradecyloxy)phenyl]phenyliodonium hexafluoroantimonate or hexafluorophosphate, tolylcumyliodonium hexafluorophosphate, 4-isopropylphenyl-4′-methylphenyliodonium hexafluorophosphate, 4-isobutylphenyl-4′-methylphenyliodonium hexafluorophosphate (Irgacure®250, BASF SE), 4-octyloxyphenyl-phenyliodonium hexafluorophosphate or hexafluoroantimonate, bis(dodecylphenyl)iodonium hexafluoroantimonate or hexafluorophosphate, bis(4-methylphenyl)iodonium hexafluorophosphate, bis(4-methoxyphenyl)iodonium hexafluorophosphate, 4-methylphenyl-4′-ethoxyphenyliodonium hexafluorophosphate, 4-methylphenyl-4′-dodecylphenyliodonium hexafluorophosphate, 4-methylphenyl-4′-phenoxyphenyliodonium hexafluorophosphate.

Of all the iodonium salts mentioned, compounds with other anions are, of course, also suitable. The preparation of iodonium salts is known to the person skilled in the art and described in the literature, for example U.S. Pat. Nos. 4,151,175, 3,862,333, 4,694,029, EP 562897, U.S. Pat. Nos. 4,399,071, 6,306,555, WO 98/46647 J. V. Crivello, “Photoinitiated Cationic Polymerization” in: UV Curing: Science and Technology, Editor S. P. Pappas, pages 24-77, Technology Marketing Corporation, Norwalk, Conn. 1980, ISBN No. 0-686-23773-0; J. V. Crivello, J. H. W. Lam, Macromolecules, 10, 1307 (1977) and J. V. Crivello, Ann. Rev. Mater. Sci. 1983, 13, pages 173-190 and J. V. Crivello, Journal of Polymer Science, Part A: Polymer Chemistry, Vol. 37, 4241-4254 (1999).

Acylphosphinoxides, such as, for example, bis(2,4,6-trimethylbenzoyl)-phenylphosphine oxide, 2,4,6-trimethylbenzoyl-diphenyl-phosphine oxide and ethyl phenyl(2,4,6-trimethylbenzoyl)phosphinate, are preferred for curing with light sources having emission peak(s) in the UV-A range and (near) VIS range (Laser, LEDs, LCD). alpha-Hydroxy ketone type compounds, such as, for example, 1-hydroxy-cyclohexyl-phenyl-ketone, 2-hydroxy-2-methyl-1-phenyl-propan-1-one, 2-hydroxy-1-{4-[4-(2-hydroxy-2-methyl-propionyl)-benzyl]-phenyl}-2-methyl-propan-1-one, 1-[4-(2-hydroxyethoxy)-phenyl]-2-hydroxy-2-methyl-1-propan-1-one, Esacure KIP provided by Lamberti, 2-hydroxy-1-{1-[4-(2-hydroxy-2-methyl-propionyl)-phenyl]-1,3,3-trimethyl-indan-5-yl}-2-methyl-propan-1-one and mixtures thereof, are preferred for curing with UV laser having emission peak at 355 nm (SLA).

If the light source emitts radiation over a broad range, UV and visible range (e.g. mercury bilbs), or light sources of different wavelengths are combined (e.g. LEDs, laser), the absorption range of one photoinitiator might not cover the entire range. This can be achieved by combining two different photoinitiator types, e.g. alpha-hydroxy ketones (1-hydroxy-cyclohexyl-phenyl-ketone, 2-hydroxy-2-methyl-1-phenyl-propan-1-one, or 2-hydroxy-1-{4-[4-(2-hydroxy-2-methyl-propionyl)-benzyl]-phenyl}-2-methyl-propan-1-one) with acyl phosphinoxides (bis(2,4,6-trimethylbenzoyl)-phenylphosphine oxide, 2,4,6-trimethylbenzoyl-diphenyl-phosphine oxide and ethyl phenyl(2,4,6-trimethylbenzoyl)phosphinate. If visible radiation is used for curing specific photoinitiators like titanocenes, such as, for example, bis (cyclopentadienyl) bis [2,6-difluoro-3-(1-pyrryl)phenyl titanium (Omnirad 784) are required.

The photoinitiators are used typically in a proportion of from about 0.5 to 10% by weight, especially 0.1 to 5.0% by weight based on the total weight of composition.

Halogen is fluorine, chlorine, bromine and iodine.

C₁-C₂₄alkyl (C₁-C₂₀alkyl, especially C₁-C₁₂alkyl) is typically linear or branched, where possible. Examples are methyl, ethyl, n-propyl, isopropyl, n-butyl, sec.-butyl, isobutyl, tert.-butyl, n-pentyl, 2-pentyl, 3-pentyl, 2,2-dimethylpropyl, 1,1,3,3-tetramethylpentyl, n-hexyl, 1-methylhexyl, 1,1,3,3,5,5-hexamethylhexyl, n-heptyl, isoheptyl, 1,1,3,3-tetramethylbutyl, 1-methylheptyl, 3-methylheptyl, n-octyl, 1,1,3,3-tetramethylbutyl and 2-ethylhexyl, n-nonyl, decyl, undecyl, dodecyl, tridecyl, tetradecyl, pentadecyl, hexadecyl, heptadecyl, or octadecyl. C₁-C₈alkyl is typically methyl, ethyl, n-propyl, isopropyl, n-butyl, sec.-butyl, isobutyl, tert.-butyl, n-pentyl, 2-pentyl, 3-pentyl, 2,2-dimethyl-propyl, n-hexyl, n-heptyl, n-octyl, 1,1,3,3-tetramethylbutyl and 2-ethylhexyl. C₁-C₄alkyl is typically methyl, ethyl, n-propyl, isopropyl, n-butyl, sec.-butyl, isobutyl, tert.-butyl.

C₂-C₁₂alkenyl (C₂-C₅alkenyl) groups are straight-chain or branched alkenyl groups, such as e.g. vinyl, allyl, methallyl, isopropenyl, 2-butenyl, 3-butenyl, isobutenyl, n-penta-2,4-dienyl, 3-methyl-but-2-enyl, n-oct-2-enyl, or n-dodec-2-enyl.

C₁-C₁₂alkoxy groups (C₁-C₈alkoxy groups) are straight-chain or branched alkoxy groups, e.g. methoxy, ethoxy, n-propoxy, isopropoxy, n-butoxy, sec-butoxy, tert-butoxy, amyloxy, isoamyloxy or tert-amyloxy, heptyloxy, octyloxy, isooctyloxy, nonyloxy, decyloxy, undecyloxy and dodecyloxy.

C₁-C₁₂alkylthio groups (C₁-C₈ alkylthio groups) are straight-chain or branched alkylthio groups and have the same preferences as the akoxy groups, except that oxygen is exchanged against sulfur.

C₁-C₁₂alkylene is bivalent C₁-C₁₂alkyl, i.e. alkyl having two (instead of one) free valencies, e.g. trimethylene or tetramethylene.

A cycloalkyl group is typically C₃-C₈cycloalkyl, such as, for example, cyclopentyl, cyclohexyl, cycloheptyl, or cyclooctyl, which may be unsubstituted or substituted.

In several cases it is advantageous to in addition to the photoinitiator employ a sensitizer compound. Examples of suitable sensitizer compounds are disclosed in WO 06/008251, page 36, line 30 to page 38, line 8, the disclosure of which is hereby incorporated by reference. As sensitizer inter alia benzophenone compounds as described above can be employed.

In several cases it is advantageous to in addition to the photoinitiator employ a sensitizer compound. Examples of suitable sensitizer compounds are disclosed in WO 06/008251, page 36, line 30 to page 38, line 8, the disclosure of which is hereby incorporated by reference. As sensitizer inter alia benzophenone compounds as described above can be employed.

If desired, the photocurable compositions may comprise further mixture constituents which are preferably selected from
at least one component D which is in turn selected from

(D.4) defoamers and deaerating agents;

(D.5) lubricants and leveling agents;

(D.6) thermally curing and/or radiation-curing auxiliaries;

(D.7) substrate wetting auxiliaries;

(D.8) wetting and dispersing auxiliaries;

(D.9) hydrophobizing agents;

(D.10) in-can stabilizers; and

(D.11) auxiliaries for improving scratch resistance;
at least one component E which is in turn selected from

(E.1) dyes; and

(E.2) pigments;
at least one component F which is in turn selected from light, heat and oxidation stabilizers.

The effect of the defoamers and deaerating agents (D.4), lubricants and leveling agents (D.5), thermally curing or radiation-curing auxiliaries (D.6), substrate wetting auxiliaries (D.7), wetting and dispersing auxiliaries (D.8), hydrophobizing agents (D.9), in-can stabilizers (D.10) and auxiliaries for improving scratch resistance (D.11) listed under component D usually cannot be strictly distinguished from one another. For instance, lubricants and leveling agents often additionally act as defoamers and/or deaerating agents and/or as auxiliaries for improving scratch resistance. Radiation-curing auxiliaries can in turn act as lubricants and leveling agents and/or deaerating agents and/or also as substrate wetting auxiliaries. In accordance with the above statements, a certain additive may therefore be attributed to more than one of the groups (D.4) to (D.11) described below.

The defoamers of group (D.4) include silicon-free and silicon-containing polymers. The silicon-containing polymers are, for example, unmodified or modified polydialkylsiloxanes or branched copolymers, comb copolymers or block copolymers composed of polydialkylsiloxane and polyether units, the latter being obtainable from ethylene oxide or propylene oxide.

The deaerating agents of group (D.4) include, for example, organic polymers, for instance polyethers and polyacrylates, dialkylpolysiloxanes, especially dimethylpolysiloxanes, organically modified polysiloxanes, for instance arylalkyl-modified polysiloxanes, or else fluorosilicones. The action of defoamers is based essentially on preventing foam formation or destroying foam which has already formed. Deaerating agents act essentially in such a way that they promote the coalescence of finely distributed gas or air bubbles to larger bubbles in the medium to be deaerated, for example the inventive mixtures, and hence accelerate the escape of the gas (or of the air). Since defoamers can often also be used as deaerating agents and vice versa, these additives have been combined together under group (D.4).

The auxiliaries of group (D.4) are typically used in a proportion of from about 0.05 to 3.0% by weight, preferably from about 0.5 to 2.0% by weight, based on the total weight of the composition.

The group (D.5) of the lubricants and leveling agents includes, for example, silicon-free but also silicon-containing polymers, for example polyacrylates or modified low molecular weight polydialkylsiloxanes. The modification consists in replacing some of the alkyl groups with a wide variety of organic radicals. These organic radicals are, for example, polyethers, polyesters or else long-chain alkyl radicals, the former finding most frequent use.

The polyether radicals of the correspondingly modified polysiloxanes are typically formed by means of ethylene oxide and/or propylene oxide units. The higher the proportion of these alkylene oxide units is in the modified polysiloxane, the more hydrophilic is generally the resulting product.

The auxiliaries of group (D.5) are typically used in a proportion of from about 0.005 to 1.0% by weight, preferably from about 0.01 to 0.2% by weight, based on the total weight of the composition.

Group (D.6) includes, as radiation-curing auxiliaries, in particular polysiloxanes with terminal double bonds which are, for example, part of an acrylate group. Such auxiliaries can be made to crosslink by actinic or, for example, electron beam radiation. These auxiliaries generally combine several properties in one. In the uncrosslinked state, they can act as defoamers, deaerating agents, lubricants and leveling agents and/or substrate wetting aids; in the crosslinked state, they increase in particular the scratch resistance, for example of coatings or films which can be produced with the inventive mixtures. The improvement in the shine performance, for example, coatings or films can essentially be regarded as the effect of the action of these auxiliaries as defoamers, devolatilizers and/or lubricants and leveling agents (in the uncrosslinked state). Thermally curing auxiliaries of group (D.6) comprise, for example, primary OH groups which can react with isocyanate groups.

The thermally curing auxiliaries used can, for example, be the products BYK®-370, BYK®-373 and BYK®-375 obtainable from BYK. The auxiliaries of group (D.6) are typically used in a proportion of from about 0.1 to 5.0% by weight, preferably from about 0.1 to 3.0% by weight, based on the total weight of the composition.

The auxiliaries of group (D.7) of the substrate wetting aids serve in particular to increase the wettability of the substrate.

The auxiliaries of group (D.7) are typically used in a proportion of from about 0.01 to 3.0% by weight, preferably from about 0.01 to 1.5% by weight and especially from 0.03 to 1.5% by weight, based on the total weight of the composition.

The auxiliaries of group (D.8) of the wetting and dispersing aids serve in particular to prevent the leaching and floating and also the settling of pigments, and are therefore useful, if necessary, in pigmented compositions in particular.

These auxiliaries stabilize pigment dispersions essentially by electrostatic repulsion and/or steric hindrance of the additized pigment particles, the interaction of the auxiliary with the surrounding medium (for example binder) playing a major role in the latter case. Since the use of such wetting and dispersing aids is common practice, for example, in the technical field of printing inks and paints, the selection of such a suitable auxiliary in the given case generally presents no difficulties to the person skilled in the art.

The dosage of the auxiliaries of group (D.8) depends mainly upon the surface area of the pigments to be covered and upon the mean molar mass of the auxiliary.

For inorganic pigments and low molecular weight auxiliaries, a content of the latter of from about 0.5 to 2.0% by weight based on the total weight of pigment and auxiliary is typically assumed. In the case of high molecular weight auxiliaries, the content is increased to from about 1.0 to 30% by weight.

In the case of organic pigments and low molecular weight auxiliaries, the content of the latter is from about 1.0 to 5.0% by weight based on the total weight of pigment and auxiliary. In the case of high molecular weight auxiliaries, this content may be in the range from about 10.0 to 90% by weight. In every case, therefore, preliminary experiments are recommended, which can, though, be accomplished by the person skilled in the art in a simple manner.

The hydrophobizing agents of group (D.9) can be used with a view, for example, to providing prints or coatings obtained with inventive mixtures with water-repellent properties.

The auxiliaries of group (D.9) are used typically in a proportion of from about 0.05 to 5.0% by weight, preferably from about 0.1 to 3.0% by weight, based on the total weight of the composition.

In-can stabilizers of group (D.10) provide increased storage stability from manufacturing to Curing. Examples of in-can Stabilizers of Group (D.10) are:

Phosphites and Phosphonites (Processing Stabilizer),

Quinone Methides of the Formula

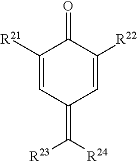

(providing long term shelf life stability), wherein

R²¹ and R²² independently of each other are C₁-C₁₈alkyl, C₅-C₁₂cycloalkyl, C₇-C₁₅-phenylalkyl, optionally substituted C₆-C₁₀aryl;

R²³ and R²⁴ independently of each other are H, optionally substituted C₆-C₁₀-aryl, 2-,3-,4-pyridyl, 2-,3-furyl or thienyl, COOH, COOR²⁵, CONH₂, CONHR²⁵, CONR²⁵R²⁶, —CN, —COR²⁵, —OCOR²⁵, —OPO(OR²⁵)₂, wherein R²⁵ and R²⁶ are independently of each other C₁-C₈alkyl, or phenyl. Quinone methides are preferred, wherein R²¹ and R²² are tert-butyl;

R²³ is H, and R²⁴ is optionally substituted phenyl, COOH, COOR²⁵, CONH₂, CONHR²⁵, CONR²⁵R²⁶, —CN, —COR²⁵, —OCOR²⁵, —OPO(OR²⁵)₂, wherein R²⁵ and R²⁶ are C₁-C₈alkyl, or phenyl. The quinone methides may be used in combination with highly sterically hindered nitroxyl radicals as described, for example, in US20110319535.

In-can stabilizers of group (D.10) are used typically in a proportion of from about 0.01 to 0.3% by weight, preferably from about 0.04 to 0.15% by weight, based on the total weight of the composition.

The group (D.11) of the auxiliaries for improving scratch resistance includes, for example, the products TEGO® Rad 2100, TEGO® Rad 2200, TEGO® Rad 2500, TEGO® Rad 2600 and TEGO® Rad 2700 which are obtainable from Tego.

For these auxiliaries, useful amounts are likewise those mentioned in group (D.6), i.e. these additives are typically used in a proportion of from about 0.1 to 5.0% by weight, preferably from about 0.1 to 3.0% by weight, based on the total weight of the composition.

The group (E.1) of the dyes includes, for example, dyes from the class of the azo dyes, metal complex dyes, basic dyes such as di- and triarylmethane dyes and salts thereof, azomethine derivatives, polymethines, antraquinone dyes and the like. An overview of suitable dyes which can be used in the inventive mixture is given by the book by H. Zollinger, “Color Chemistry”, Wiley-VCH, Weinheim, 3^{rd} edition 2003.

It is in particular also possible to add to the inventive mixtures photochromic, thermochromic or luminescent dyes, and dyes which have a combination of these properties. In addition to the typical fluorescent dyes, fluorescent dyes should also be understood to mean optical brighteners. Optical brighteners may be used for the optimization of the absorption characteristics (critical energy and depth of penetration) of the photocurable composition.

Examples of the latter include the class of the bisstyrylbenzenes, especially of the cyanostyryl compounds, and correspond to the formula

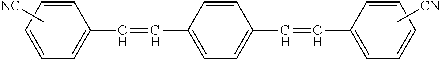

Further suitable optical brighteners from the class of the stilbenes are, for example, those of the formulae

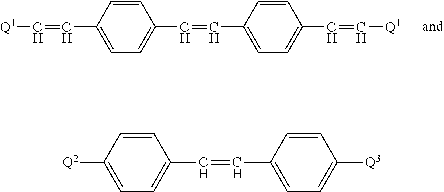

in which Q¹ is in each case C₁-C₄-alkoxycarbonyl or cyano, Q² is benzoxazol-2-yl, which may be mono- or disubstituted by C₁-C₄-alkyl, especially methyl, Q³ is C₁-C₄-alkoxycarbonyl or 3-(C₁-C₄-alkyl)-1,2,4-oxadiazol-3-yl.

Further suitable optical brighteners from the class of the benzoxazoles obey, for example, the formulae

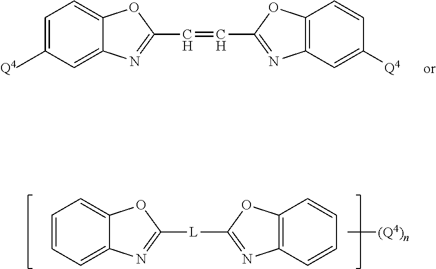

in which Q⁴ is in each case C₁-C₄-alkyl, especially methyl, L is a radical of the formula

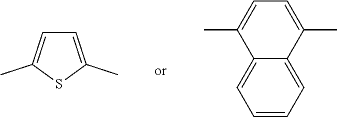

and n is an integer from 0 to 2.

Suitable optical brighteners from the class of the coumarins have, for example, the formula

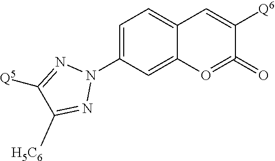

in which

Q⁵ is C₁-C₄-alkyl and

Q⁶ is phenyl or 3-halopyrazol-1-yl, especially 3-chloropyrazol-1-yl.

Further suitable optical brighteners from the class of the pyrenes correspond, for example, to the formula

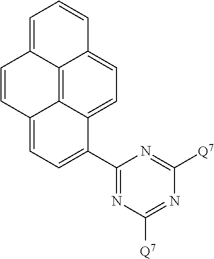

in which

Q⁷ is in each case C₁-C₄-alkoxy, especially methoxy.

The abovementioned brighteners can be used either alone or in a mixture with one another.

The abovementioned optical brighteners are generally commercially available products known per se. They are described, for example, in Ullmann's Encyclopedia of Industrial Chemistry, 5^{th} edition, volume A18, pages 156 to 161, or can be obtained by the methods described there.

In particular, if desired, one or more optical brighteners from the class of the bisstyrylbenzenes is used, especially of the cyanostyrylbenzenes. The latter may be used as individual compounds, but also as a mixture of the isomeric compounds.

In this case, the isomers correspond to the formulae

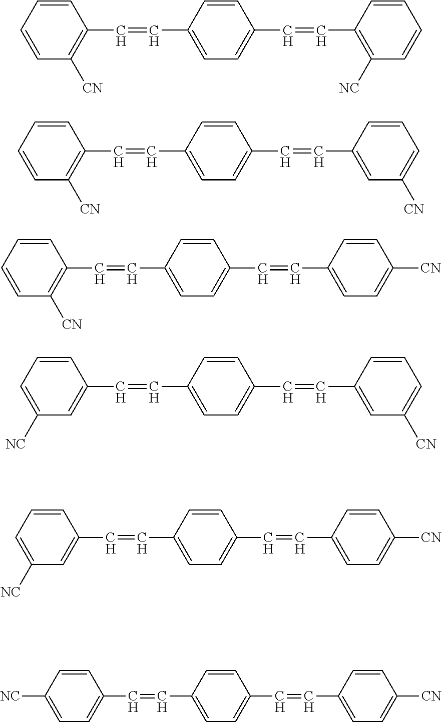

Optical brighteners are sold, for example, commercially as Ultraphor® SF 004, Ultraphor® SF MO, Ultraphor® SF MP and Ultraphor® SF PO from BASF SE.

The group (E.2) of the pigments includes both inorganic and organic pigments. An overview of inorganic colored pigments which can be used in the inventive mixtures is given by the book by H. Endriß “Aktuelle anorganische Bunt-Pigmente” [“Current inorganic colored pigments” ] (publisher U. Zorll, Curt-R.-Vincentz-Verlag Hanover 1997), and the book by G. Buxbaum, “Industrial Inorganic Pigments”, Wiley-VCH, Weinheim, 3^{rd} edition 2005. In addition, useful further pigments which are not listed in the aforementioned book are also Pigment Black 6 and Pigment Black 7 (carbon black), Pigment Black 11 (iron oxide black, Fe₃O₄), Pigment White 4 (zinc oxide, ZnO), Pigment White 5 (lithopone, ZnS/BaSO₄), Pigment White 6 (titanium oxide, TiO₂) and Pigment White 7 (zinc sulfide, ZnS).

An overview of organic pigments which can be added to the inventive mixtures is provided by the book by W. Herbst and K. Hunger “Industrielle organische Pigmente” [“Industrial Organic Pigments” ], Wiley-VCH, Weinheim, 3rd edition 2004.

It is also possible to add to the inventive mixtures magnetic, electrically conductive, photochromic, thermochromic or luminescent pigments, and also pigments which have a combination of these properties.

Examples of light, heat and/or oxidation stabilizers as component F include: alkylated monophenols, such as 2,6-di-tert-butyl-4-methylphenol, 2-tert-butyl-4,6-dimethylphenol, 2,6-di-tert-butyl-4-ethylphenol, 2,6-di-tert-butyl-4-n-butylphenol, 2,6-di-tert-butyl-4-isobutylphenol, 2,6-dicyclopentyl-4-methylphenol, 2-(α-methylcyclohexyl)-4,6-dimethylphenol, 2,6-dioctadecyl-4-methylphenol, 2,4,6-tricyclohexylphenol, 2,6-di-tert-butyl-4-methoxymethylphenol, nonylphenols which have a linear or branched side chain, for example 2,6-dinonyl-4-methylphenol, 2,4-dimethyl-6-(1′-methylundec-1′-yl)phenol, 2,4-dimethyl-6-(1′-methylheptadec-1′-yl)phenol, 2,4-dimethyl-6-(1′-methyltridec-1′-yl)phenol and mixtures of these compounds, alkylthiomethylphenols, such as 2,4-dioctylthiomethyl-6-tert-butylphenol, 2,4-dioctylthiomethyl-6-methylphenol, 2,4-dioctylthiomethyl-6-ethylphenol and 2,6-didodecylthiomethyl-4-nonylphenol,

hydroquinones and alkylated hydroquinones, such as 2,6-di-tert-butyl-4-methoxyphenol, 2,5-di-tert-butylhydroquinone, 2,5-di-tert-amylhydroquinone, 2,6-diphenyl-4-octadecyloxyphenol, 2,6-di-tert-butylhydroquinone, 2,5-di-tert-butyl-4-hydroxyanisole, 3,5-di-tert-butyl-4-hydroxyanisole, 3,5-di-tert-butyl-4-hydroxyphenyl stearate and bis(3,5-di-tert-butyl-4-hydroxyphenyl)adipate,

tocopherols, such as α-tocopherol, β-tocopherol, γ-tocopherol, δ-tocopherol and mixtures of these compounds, and tocopherol derivatives, such as tocopheryl acetate, succinate, nicotinate and polyoxyethylenesuccinate (“tocofersolate”),

hydroxylated diphenyl thioethers, such as 2,2′-thiobis(6-tert-butyl-4-methylphenol), 2,2′-thiobis(4-octylphenol), 4,4′-thiobis(6-tert-butyl-3-methylphenol), 4,4′-thiobis(6-tert-butyl-2-methylphenol), 4,4′-thiobis(3,6-di-sec-amylphenol) and 4,4′-bis(2,6-dimethyl-4-hydroxyphenyl) disulfide,

alkylidenebisphenols, such as 2,2′-methylenebis(6-tert-butyl-4-methylphenol), 2,2′-methylenebis(6-tert-butyl-4-ethylphenol), 2,2′-methylenebis[4-methyl-6-(α-methylcyclohexyl)phenol], 2,2′-methylenebis(4-methyl-6-cyclohexylphenol), 2,2′-methylenebis(6-nonyl-4-methylphenol), 2,2′-methylenebis(4,6-di-tert-butylphenol), 2,2-ethylidenebis(4,6-di-tert-butylphenol), 2,2′-ethylidenebis(6-tert-butyl-4-isobutylphenol), 2,2′-methylenebis[6-(α-methylbenzyl)-4-nonylphenol], 2,2′-methylenebis[6-(α,α-dimethylbenzyl)-4-nonylphenol], 4,4′-methylenebis(2,6-di-tert-butylphenol), 4,4′-methylenebis(6-tert-butyl-2-methylphenol), 1,1-bis(5-tert-butyl-4-hydroxy-2-methylphenyl)butane, 2,6-bis(3-tert-butyl-5-methyl-2-hydroxybenzyl)-4-methylphenol, 1,1,3-tris(5-tert-butyl-4-hydroxy-2-methylphenyl)butane, 1,1-bis(5-tert-butyl-4-hydroxy-2-methylphenyl)-3-n-dodecylmercaptobutane, ethylene glycol bis[3,3-bis(3′-tert-butyl-4′-hydroxyphenyl)butyrate], bis(3-tert-butyl-4-hydroxy-5-methylphenyl)dicyclopentadiene, bis[2-(3′-tert-butyl-2′-hydroxy-5′-methylbenzyl)-6-tert-butyl-4-methylphenyl]terephthalate, 1,1-bis(3,5-dimethyl-2-hydroxyphenyl)butane, 2,2-bis(3,5-di-tert-butyl-4-hydroxyphenyl)propane, 2,2-bis(5-tert-butyl-4-hydroxy-2-methylphenyl)-4-n-dodecylmercaptobutane and 1,1,5,5-tetrakis(5-tert-butyl-4-hydroxy-2-methylphenyl)pentane, O—, N- and S-benzyl compounds, such as 3,5,3′,5′-tetra-tert-butyl-4,4′-dihydroxydibenzyl ether, octadecyl 4-hydroxy-3,5-dimethylbenzylmercaptoacetate, tridecyl 4-hydroxy-3,5-di-tert-butylbenzylmercaptoacetate, tris(3,5-di-tert-butyl-4-hydroxybenzyl)amine, bis(4-tert-butyl-3-hydroxy-2,6-dimethylbenzyl) dithioterephthalate, bis(3,5-di-tert-butyl-4-hydroxybenzyl) sulfide and isooctyl-3,5-di-tert-butyl-4-hydroxybenzylmercaptoacetate, aromatic hydroxybenzyl compounds, such as 1,3,5-tris(3,5-di-tert-butyl-4-hydroxybenzyl)-2,4,6-trimethylbenzene, 1,4-bis(3,5-di-tert-butyl-4-hydroxybenzyl)-2,3,5,6-tetramethylbenzene and 2,4,6-tris(3,5-di-tert-butyl-4-hydroxybenzyl)phenol, triazine compounds, such as 2,4-bis(octylmercapto)-6-(3,5-di-tert-butyl-4-hydroxyanilino)-1,3,5-triazine, 2-octylmercapto-4,6-bis(3,5-di-tert-butyl-4-hydroxyanilino)-1,3,5-triazine, 2-octylmercapto-4,6-bis(3,5-di-tert-butyl-4-hydroxyphenoxy)-1,3,5-triazine, 2,4,6-tris(3,5-di-tert-butyl-4-hydroxyphenoxy)-1,2,3-triazine, 1,3,5-tris(3,5-di-tert-butyl-4-hydroxybenzyl) isocyanurate, 1,3,5-tris(4-tert-butyl-3-hydroxy-2,6-dimethylbenzyl) isocyanurate, 2,4,6-tris(3,5-di-tert-butyl-4-hydroxyphenylethyl)-1,3,5-triazine, 1,3,5-tris-(3,5-di-tert-butyl-4-hydroxyphenylpropionyl)hexahydro-1,3,5-triazine, 1,3,5-tris(3,5-dicyclohexyl-4-hydroxybenzyl) isocyanurate and 1,3,5-tris(2-hydroxyethyl) isocyanurate, benzylphosphonates, such as dimethyl 2,5-di-tert-butyl-4-hydroxybenzylphosphonate, diethyl 3,5-di-tert-butyl-4-hydroxybenzylphosphonate, dioctadecyl 3,5-di-tert-butyl-4-hydroxybenzylphosphonate and dioctadecyl 5-tert-butyl-4-hydroxy-3-methylbenzylphosphonate,

acylaminophenols, such as 4-hydroxylauroylanilide, 4-hydroxystearoylanilide and octyl N-(3,5-di-tert-butyl-4-hydroxyphenyl)carbamate,

propionic and acetic esters, for example of monohydric or polyhydric alcohols, such as methanol, ethanol, n-octanol, isooctanol, octadecanol, 1,6-hexanediol, 1,9-nonanediol, ethylene glycol, 1,2-propanediol, neopentyl glycol, thiodiethylene glycol, diethylene glycol, triethylene glycol, pentaerythritol, tris(hydroxyethyl) isocyanurate, N,N′-bis(hydroxyethyl)oxamide, 3-thiaundecanol, 3-thiapentadecanol, trimethylhexanediol, trimethylolpropane and 4-hydroxymethyl-1-phospha-2,6,7-trioxabicyclo[2.2.2]octane, propionamides based on amine derivatives, such as N,N′-bis(3,5-di-tert-butyl-4-hydroxyphenylpropionyl)hexamethylenediamine, N,N′-bis(3,5-di-tert-butyl-4-hydroxyphenylpropionyl)trimethylenediamine and N,N′-bis(3,5-di-tert-butyl-4-hydroxyphenylpropionyl)hydrazine,

ascorbic acid (Vitamin C) and ascorbic acid derivatives, such as ascorbyl palmitate, laurate and stearate, and ascorbyl sulfate and phosphate,

antioxidants based on amine compounds, such as N,N′-diisopropyl-p-phenylenediamine, N,N′-di-sec-butyl-p-phenylenediamine, N,N′-bis(1,4-dimethylpentyl)-p-phenylenediamine, N,N′-bis(1-ethyl-3-methylpentyl)-p-phenylenediamine, N,N′-bis(1-methylheptyl)-p-phenylenediamine, N,N′-dicyclohexyl-p-phenylenediamine, N,N′-diphenyl-p-phenylenediamine, N,N′-bis(2-naphthyl)-p-phenylenediamine, N-isopropyl-N′-phenyl-p-phenylenediamine, N-(1,3-dimethylbutyl)-N′-phenyl-p-phenylenediamine, N-(1-methylheptyl)-N′-phenyl-p-phenylenediamine, N-cyclohexyl-N′-phenyl-p-phenylenediamine, 4-(p-toluenesulfamoyl)diphenylamine, N,N′-dimethyl-N,N′-di-sec-butyl-p-phenylenediamine, diphenylamine, N-allyldiphenylamine, 4-isopropoxydiphenylamine, N-phenyl-1-naphthylamine, N-(4-tert-octylphenyl)-1-naphthylamine, N-phenyl-2-naphthylamine, octyl-substituted diphenylamine, such as p,p′-di-tert-octyldiphenylamine, 4-n-butylaminophenol, 4-butyrylaminophenol, 4-nonanoylaminophenol, 4-dodecanoylaminophenol, 4-octadecanoylaminophenol, bis[4-methoxyphenyl)amine, 2,6-di-tert-butyl-4-dimethylaminomethylphenol, 2,4-diaminodiphenylmethane, 4,4′-diaminodiphenylmethane, N,N,N′,N′-tetramethyl-4,4′-diaminodiphenylmethane, 1,2-bis[(2-methylphenyl)amino]ethane, 1,2-bis(phenylamino)propane, (o-tolyl)biguanide, bis[4-(1′,3′-dimethylbutyl)phenyl]amine, tert-octyl-substituted N-phenyl-1-naphthylamine, a mixture of mono- and dialkylated tert-butyl/tert-octyldiphenylamine, a mixture of mono- and dialkylated nonyldiphenylamine, a mixture of mono- and dialkylated dodecyldiphenylamine, a mixture of mono- and dialkylated isopropyl/isohexyldiphenylamine, a mixture of mono- and dialkylated tert-butyldiphenylamine, 2,3-dihydro-3,3-dimethyl-4H-1,4-benzothiazine, phenothiazine, a mixture of mono- and dialkylated tert-butyl/tert-octylphenothiazine, a mixture of mono- and dialkylated tert-octylphenothiazine, N-allylphenothiazine, N,N,N′,N′-tetraphenyl-1,4-diaminobut-2-ene, N,N-bis(2,2,6,6-tetramethylpiperidin-4-yl)hexamethylenediamine, bis(2,2,6,6-tetramethylpiperidin-4-yl) sebacate, 2,2,6,6-tetramethylpiperidin-4-one and 2,2,6,6-tetramethylpiperidin-4-ol, phosphites and phosphonites, such as triphenylphosphite, diphenyl alkyl phosphite, phenyl dialkyl phosphite, tris(nonylphenyl) phosphite, trilauryl phosphite, trioctadecyl phosphite, distearyl pentaerythritol diphosphite, tris(2,4-di-tert-butylphenyl) phosphite, diisodecyl pentaerythritol diphosphite, bis(2,4-di-tert-butylphenyl) pentaerythritol diphosphite, bis(2,6-di-tert-butyl-4-methylphenyl) pentaerythritol diphosphite, diisodecyloxy pentaerythritol diphosphite, bis(2,4-di-tert-butyl-6-methylphenyl) pentaerythritol diphosphite, bis(2,4,6-tris(tert-butylphenyl)) pentaerythritol diphosphite, tristearyl sorbitol triphosphite, tetrakis(2,4-di-tert-butylphenyl) 4,4′-biphenylenediphosphonite, 6-isooctyloxy-2,4,8,10-tetra-tert-butyl-12H-dibenzo[d,g]-1,3,2-dioxaphosphocine, 6-fluoro-2,4,8,10-tetra-tert-butyl-12-methyl-dibenzo[d,g]-1,3,2-dioxaphosphocine, bis(2,4-di-tert-butyl-6-methylphenyl) methyl phosphite and bis(2,4-di-tert-butyl-6-methylphenyl) ethyl phosphite,

2-(2′-hydroxyphenyl)benzotriazoles, such as 2-(2′-hydroxy-5′-methylphenyl)benzotriazole, 2-(3′,5′-di-tert-butyl-2′-hydroxyphenyl)benzotriazole, 2-(5′-tert-butyl-2′-hydroxyphenyl)benzotriazole, 2-(2′-hydroxy-5′-(1,1,3,3-tetramethylbutyl)phenyl)benzotriazole, 2-(3′,5′-di-tert-butyl-2′-hydroxyphenyl)-5-chlorobenzotriazole, 2-(3′-tert-butyl-2′-hydroxy-5′-methylphenyl)-5-chlorobenzotriazole, 2-(3′-sec-butyl-5′-tert-butyl-2′-hydroxyphenyl)benzotriazole, 2-(2′-hydroxy-4′-octyloxyphenyl)benzotriazole, 2-(3′,5′-di-tert-amyl-2′-hydroxyphenyl)benzotriazole, 2-(3′,5′-bis-(α,α-dimethylbenzyl)-2′-hydroxyphenyl)benzotriazole, a mixture of 2-(3′-tert-butyl-2′-hydroxy-5′-(2-octyloxycarbonylethyl)phenyl)-5-chlorobenzotriazole, 2-(3′-tert-butyl-5′-[2-(2-ethylhexyloxy)carbonylethyl]-2′-hydroxyphenyl)-5-chlorobenzotriazole, 2-(3′-tert-butyl-2′-hydroxy-5′-(2-methoxycarbonylethyl)phenyl)-5-chlorobenzotriazole, 2-(3′-tert-butyl-2′-hydroxy-5′-(2-methoxycarbonylethyl) phenyl)benzotriazole, 2-(3′-tert-butyl-2′-hydroxy-5′-(2-octyloxycarbonylethyl)phenyl)benzotriazole, 2-(3′-tert-butyl-5′-[2-(2-ethylhexyloxy)carbonylethyl]-2′-hydroxyphenyl)benzotriazole, 2-(3′-dodecyl-2′-hydroxy-5′-methylphenyl)benzotriazole and 2-(3′-tert-butyl-2′-hydroxy-5′-(2-isooctyloxycarbonylethyl)phenylbenzotriazole, 2,2′-methylenebis[4-(1,1,3,3-tetramethylbutyl)-6-benzotriazol-2-ylphenol]; the product of complete esterification of 2-[3′-tert-butyl-5′-(2-methoxycarbonylethyl)-2′-hydroxyphenyl]-2H-benzotriazole with polyethylene glycol 300; [R—CH₂CH₂—COO(CH₂)₃]₂, where R=3′-tert-butyl-4′-hydroxy-5′-2H-benzotriazol-2-ylphenyl],

sulfur-containing peroxide scavengers and sulfur-containing antioxidants, such as esters of 3,3′-thiodipropionic acid, for example the lauryl, stearyl, myristyl and tridecyl esters, mercaptobenzimidazole and the zinc salt of 2-mercaptobenzimidazole, dibutylzinc dithiocarbamate, dioctadecyl disulfide and pentaerythritol tetrakis(β-dodecylmercapto)propionate,

2-hydroxybenzophenones, such as the 4-hydroxy, 4-methoxy, 4-octyloxy, 4-decycloxy, 4-dodecyloxy, 4-benzyloxy, 4,2′,4′-trihydroxy and 2′-hydroxy-4,4′-dimethoxy derivatives, esters of unsubstituted and substituted benzoic acids, such as 4-tert-butylphenyl salicylate, phenyl salicylate, octylphenyl salicylate, dibenzoylresorcinol, bis(4-tert-butylbenzoyl)resorcinol, benzoylresorcinol, 2,4-di-tert-butylphenyl 3,5-di-tert-butyl-4-hydroxybenzoate, hexadecyl-3,5-di-tert-butyl-4-hydroxybenzoate, octadecyl-3,5-di-tert-butyl-4-hydroxybenzoate and 2-methyl-4,6-di-tert-butylphenyl-3,5-di-tert-butyl-4-hydroxybenzoate,

acrylates, such as ethyl α-cyano-β,β-diphenylacrylate, isooctyl α-cyano-β,β-diphenylacrylate, methyl α-methoxycarbonylcinnamate, methyl α-cyano-β-methyl-p-methoxycinnamate, butyl-α-cyano-β-methyl-p-methoxycinnamate and methyl-α-methoxycarbonyl-p-methoxycinnamate,

sterically hindered amines, such as bis(2,2,6,6-tetramethylpiperidin-4-yl) sebacate, bis(2,2,6,6-tetramethylpiperidin-4-yl) succinate, bis(1,2,2,6,6-pentamethylpiperidin-4-yl) sebacate, bis(1-octyloxy-2,2,6,6-tetramethylpiperidin-4-yl) sebacate, bis(1,2,2,6,6-pentamethylpiperidin-4-yl)-n-butyl-3,5-di-tert-butyl-4-hydroxybenzylmalonate, the condensation product of 1-(2-hydroxyethyl)-2,2,6,6-tetramethyl-4-hydroxypiperidine and succinic acid, the condensation product of N,N′-bis(2,2,6,5-tetramethylpiperidin-4-yl)hexamethylenediamine and 4-tert-octylamino-2,6-dichloro-1,3,5-triazine, tris(2,2,6,6-tetramethylpiperidin-4-yl) nitrilotriacetate, tetrakis(2,2,6,6-tetramethylpiperidin-4-yl) 1,2,3,4-butanetetracarboxylate, 1,1′-(1,2-ethylene)bis(3,3,5,5-tetramethylpiperazinone), 4-benzoyl-2,2,6,6-tetramethylpiperidine, 4-stearyloxy-2,2,6,6-tetramethylpiperidine, bis(1,2,2,6,6-pentamethylpiperidin-4-yl) 2-n-butyl-2-(2-hydroxy-3,5-di-tert-butylbenzyl)malonate, 3-n-octyl-7,7,9,9-tetramethyl-1,3,8-triazaspiro[4.5]decane-2,4-dione, bis(1-octyloxy-2,2,6,6-tetramethylpiperidin-4-yl) sebacate, bis(1-octyloxy-2,2,6,5-tetramethylpiperidin-4-yl) succinate, the condensation product of N,N′-bis(2,2,6,6-tetramethylpiperidin-4-yl)hexamethylenediamine and 4-morpholino-2,6-dichloro-1,3,5-triazine, the condensation product of 2-chloro-4,6-bis(4-n-butylamino-2,2,6,6-tetramethylpiperidin-4-yl)-1,3,5-triazine and 1,2-bis(3-aminopropylamino)ethane, the condensation product of 2-chloro-4,6-di(4-n-butylamino-1,2,2,6,6-pentamethylpiperidin-4-yl)-1,3,5-triazine and 1,2-bis(3-aminopropylamino)ethane, 8-acetyl-3-dodecyl-7,7,9,9-tetramethyl-1,3,8-triazaspiro[4.5]decane-2,4-dione, 3-dodecyl-1-(2,2,6,6-tetramethylpiperidin-4-yl)pyrrolidine-2,5-dione, 3-dodecyl-1-(1,2,2,6,6-pentamethylpiperidin-4-yl)pyrrolidine-2,5-dione, a mixture of 4-hexadecyloxy- and 4-stearyloxy-2,2,6,6-tetramethylpiperidine, the condensation product of N,N′-bis(2,2,6,6-tetramethylpiperidin-4-yl)hexamethylenediamine and 4-cyclohexylamino-2,6-dichloro-1,3,5-triazine, the condensation product of 1,2-bis(3-aminopropylamino)ethane and 2,4,6-trichloro-1,3,5-triazine, 4-butylamino-2,2,6,6-tetramethylpiperidine, N-(2,2,6,6-tetramethylpiperidin-4-yl)-n-dodecylsuccinimide, N-(1,2,2,6,6-pentamethylpiperidin-4-yl)-n-dodecylsuccinimide, 2-undecyl-7,7,9,9-tetramethyl-1-oxa-3,8-diaza-4-oxospiro[4.5]decane, the condensation product of 7,7,9,9-tetramethyl-2-cycloundecyl-1-oxa-3,8-diaza-4-oxospiro-[4.5]decane and epichlorohydrin, the condensation products of 4-amino-2,2,6,6-tetramethylpiperidine with tetramethylolacetylenediureas and poly(methoxypropyl-3-oxy)-[4(2,2,6,6-tetramethyl)piperidinyl]siloxane, oxamides, such as 4,4′-dioctyloxyoxanilide, 2,2′-diethoxyoxanilide, 2,2′-dioctyloxy-5,5′-di-tert-butoxanilide, 2,2′-didodecyloxy-5,5′-di-tert-butoxanilide, 2-ethoxy-2′-ethyloxanilide, N,N′-bis(3-dimethylaminopropyl)oxamide, 2-ethoxy-5-tert-butyl-2′-ethoxanilide and its mixture with 2-ethoxy-2′-ethyl-5,4′-di-tert-butoxanilide, and mixtures of ortho-, para-methoxy-disubstituted oxanilides and mixtures of ortho- and para-ethoxy-disubstituted oxanilides, and

2-(2-hydroxyphenyl)-1,3,5-triazines, such as 2,4,6-tris-(2-hydroxy-4-octyloxyphenyl)-1,3,5-triazine, 2-(2-hydroxy-4-octyloxyphenyl)-4,6-bis(2,4-dimethylphenyl)-1,3,5-triazine, 2-(2,4-dihydroxyphenyl)-4,6-bis(2,4-dimethylphenyl)-1,3,5-triazine, 2,4-bis(2-hydroxy-4-propyloxyphenyl)-6-(2,4-dimethylphenyl)-1,3,5-triazine, 2-(2-hydroxy-4-octyloxyphenyl)-4,6-bis(4-methyl-5 phenyl)-1,3,5-triazine, 2-(2-hydroxy-4-dodecyloxyphenyl)-4,6-bis(2,4-dimethylphenyl)-1,3,5-triazine, 2-(2-hydroxy-4-tridecyloxyphenyl)-4,6-bis(2,4-dimethylphenyl)-1,3,5-triazine, 2-[2-hydroxy-4-(2-hydroxy-3-butyloxypropoxy)phenyl]-4,6-bis(2,4-dimethyl)-1,3,5-triazine, 2-[2-hydroxy-4-(2-hydroxy-3-octyloxypropoxy)phenyl]-4,6-bis(2,4-dimethyl)-1,3,5-triazine, 2-[4-(dodecyloxy/tridecyloxy-2-hydroxypropoxy)-2-hydroxyphenyl]-4,6-bis(2,4-dimethylphenyl)-1,3,5-triazine, 2-[2-hydroxy-4-(2-hydroxy-3-dodecyloxypropoxy)phenyl]-4,6-bis-(2,4-dimethylphenyl)-1,3,5-triazine, 2-(2-hydroxy-4-hexyloxyphenyl)-4,6-diphenyl-1,3,5-triazine, 2-(2-hydroxy-4-methoxyphenyl)-4,6-diphenyl-1,3,5-triazine, 2,4,6-tris[2-hydroxy-4-(3-butoxy-2-hydroxypropoxy)phenyl]-1,3,5-triazine and 2-(2-hydroxyphenyl)-4-(4-methoxyphenyl)-6-phenyl-1,3,5-triazine.

The present disclosure(s) also provides methods suitable for making 3-dimensional structures comprising a plurality of polymer layers and 3-dimensional patterns.

Some embodiments provide methods of patterning a polymeric image on a substrate, each method comprising;
(a) depositing a layer of photocurable composition of any one of the compositions described herein on the substrate;
(b) irradiating a portion of the layer of photocurable composition with a light having appropriate wavelength(s), thereby providing a patterned layer of polymerized and unpolymerized regions. Certain other embodiments further comprise removing the unpolymerized region of the pattern.

The method may comprise depositing a plurality of layers of a photocurable composition on a substrate before irradiation, at least one of which is the photocurable composition of the present invention.

The irradiated portion is patterned through use of a photomask, by a direct writing application of light, by interference, nanoimprint, or diffraction gradient lithography, by inkjet 3D printing, stereolithography, holography, LCD or digital light projection (DLP).

The photocurable compositions may be irradiated by any variety of methods known in the art. Patterning may be achieved by photolithography, using a positive or negative image photomask, by interference lithography (i.e., using a diffraction grating), by proximity field nanopatterning by diffraction gradient lithography, or by a direct laser writing application of light, such as by multi-photon lithography, by nanoimprint lithography, by inkjet 3D printing, stereolithography and the digital micromirror array variation of stereolithography (commonly referred to as digital light projection (DLP). The photocurable compositions are especially amenable to preparing structures using stereolithographic methods, for example including digital light projection (DLP). The photocurable compositions may be processed as bulk structures, for example using vat polymerization, wherein the photopolymer is cured directly onto a translated or rotated substrate, and the irradiation is patterned via stereolithography, holography, or digital light projection (DLP).

Stereolithography (SLA) is a form of three-dimensional (3D) printing technology used for creating models, prototypes, patterns and production parts in a layer by layer fashion (so-called “additive manufacturing”) using photo-polymerization, a process by which light causes chains of molecules to link, forming polymers. Those polymers then make up the body of a three-dimensional solid. Typically, an SLA additive manufacturing process uses a build platform having a build tray submerged in a liquid photosensitive material. A 3D model of the item to be manufactured is imported into an associated 3D printer software, which software slices the 3D model into 2D images that are then projected onto the build platform to expose the photopolymer.

FIG. 3 of U.S. Pat. No. 4,575,330 depicts a known prior art “top-down” approach to printing. A container 21 is filled with a UV curable liquid 22 or the like, to provide a designated working surface 23. A programmable source of ultraviolet (UV) light 26 produces a spot of ultraviolet light 27 in the plane of surface 23. The spot 27 is movable across the surface 23 by the motion of mirrors or other optical or mechanical elements that are a part of light source 26. The position of the spot 27 on surface 23 is controlled by a computer 28. A movable elevator platform 29 inside container 21 is moved up and down selectively, the position of the platform being controlled by the computer 28. The elevator platform may be driven mechanically, pneumatically, hydraulically or electrically, and it typically uses optical or electronic feedback to precisely control its position. As the device operates, it produces a three-dimensional object 30 by step-wise buildup of integrated laminate such as 30a, 30b, 30c. During this operation, the surface of the UV curable liquid 22 is maintained at a constant level in the container 21, and the spot of UV light 27 is moved across the working surface 23 in a programmed manner. As the liquid 22 cures and solid material forms, the elevator platform 29 that was initially just below surface 23 is moved down from the surface in a programmed manner by any suitable actuator. In this way, the solid material that was initially formed is taken below surface 23 and new liquid 22 flows across the surface 23. A portion of this new liquid is, in turn, converted to solid material by the programmed UV light spot 27, and the new material adhesively connects to the material below it. This process is continued until the entire three-dimensional object 30 is formed.

A computer controlled pump (not shown) may be used to maintain a constant level of the liquid 22 at the working surface 23. Appropriate level detection system and feedback networks can be used to drive a fluid pump or a liquid displacement device to offset changes in fluid volume and maintain constant fluid level at the surface 23. Alternatively, the source 26 can be moved relative to the sensed level 23 and automatically maintain sharp focus at the working surface 23. All of these alternatives can be readily achieved by conventional software operating in conjunction with the computer control system 28.

An alternative approach is to build the item from the “bottom-up” as depicted in FIG. 4 of U.S. Pat. No. 4,575,330. In this approach, the UV curable liquid 22 floats on a heavier UV transparent liquid 32 that is non-miscible and non-wetting with the curable liquid 22. By way of example, ethylene glycol or heavy water are suitable for the intermediate liquid layer 32. In the system of FIG. 4, the three-dimensional object 30 is pulled up from the liquid 22, rather than down and further into the liquid medium, as shown in the system of FIG. 3. In particular, the UV light source 26 in FIG. 4 focuses the spot 27 at the interface between the liquid 22 and the non-miscible intermediate liquid layer 32, the UV radiation passing through a suitable UV transparent window 33, of quartz or the like, supported at the bottom of the container 21.

According WO2018106977, and in lieu of printing just from resin in its liquid phase, one or more layers of the item are printed from resin that is foamed (at the build surface 23).

FIG. 3 of WO2018106977 depicts a representative implementation of an additive manufacturing method and apparatus wherein resin foam is the source material for the printer. A top-down printing method is depicted. In this example embodiment, the SLA apparatus comprises a radiation source 300 (e.g., DLP, laser, electron beam (EB), x-ray, etc. and scanner), a movement control mechanism 302 (e.g., a stepper motor) that moves a build platform 304 vertically up and down within a tank 305 that holds the photopolymer resin 306, and a sweeper 308 (also known as a “recoater” blade) that sweeps horizontally. These elements are used to print a part 310 in the manner previously described. The SLA apparatus is augmented with a foam producing and dispensing mechanism to facilitate production of resin foam at the printer interface, namely, the layer being printed. To this end, the mechanism comprises a foaming or pressure vessel 312, an electromechanical valve 314, and a hose or tube 316. A manifold 318 is attached to the sweeper 308 to evenly distribute the foamed resin across the top layer of the build surface. In particular, and as depicted, the foaming vessel receives liquid resin and a suitable gas (e.g., CO₂, N₂O, etc.). Gas is dissolved in the liquid resin within the foaming vessel (e.g., by shaking, missing, agitation, etc.) and selectively delivered to the build plate/platform via the hose 316 when the valve 314 is actuated, e.g., by a solenoid or other electromechanical, pneumatic, optical or electronic control device. Typically, the mechanism is under program control using a computer, which may be the same computer used to control the printer. In this embodiment, the mechanism includes a frother 320 (e.g., a mechanical agitator, an ultrasonic device, etc.) to shake or otherwise dissolve the gas within the liquid vessel if needed to produce foam.

Upon delivery of the resin and gas mixture (directly onto the build plate via the manifold 318), the gas spontaneously evolves out of the liquid mixture (due to the lower pressure) to produce a foam that is radiation-curable. The sweeper 308 spreads the foam evenly onto the plate, and the light engine is then activated to display the appropriate image to cure (solidify) the foam into a layer. Once the layer is formed, the movement control mechanism moves the platform down so that the next layer of the item can be built; the process is then repeated, once again preferably using the foam layer at the print interface.

While the preferred technique uses layer-wise additive manufacturing, other manufacturing processes may be used to process the foam to produce the build item, such as, for example, laser holography, wherein two lasers intersect in a tank of foamed resin and cure the resin at that spot.

The photocurable composition of the present invention is preferably used in vat photopolymerization (stereolithography) and photopolymer jetting/printing.

In addition, the present invention is directed to a method for producing a three-dimensional article, comprising
a) providing the photocurable composition of the present invention,
b) exposing the photocurable composition to actinic radiation to form a cured crossection,
c) repeating steps (a) and (b) to build up a three-dimensional article.

In a preferred embodiment the method comprises a vat photopolymerization, wherein the photocurable of the present invention in step b) is cured directly onto a translated or rotated substrate, and the irradiation is patterned via stereolithography, holography, or digital light projection (DLP).

In another preferred embodiment the method comprises
a) applying a layer of the photocurable composition of the present invention onto a surface; b) exposing the layer imagewise to actinic radiation to form an imaged cured cross-section;
c) applying a second layer of the photocurable composition onto the previously exposed imaged cross-section;
d) exposing the layer from step (c) imagewise to actinic radiation to form an additional imaged cross-section, wherein the radiation causes curing of the second layer in the exposed areas and adhesion to the previously exposed cross-section; and
e) repeating steps (c) and (d) in order to build up a three-dimensional article.

Accordingly, the present invention is also directed to a three-dimensional article produced by the method of the present invention, or a three-dimensional article, which is a cured product of the photocurable composition of the present invention.

The photocurable compositions of the present invention may be used in dual cure stereolithography resins suitable for stereolithography techniques (particularly for CLIP). Reference is made to U.S. Pat. No. 9,453,142, US2016/0136889, US2016/0137838 and US2016/016077. These resins usually include a first polymerizable system typically polymerized by light (sometimes referred to as “Part A”) from which an intermediate object is produced, and also include at least a second polymerizable system (“Part B”) which is usually cured after the intermediate object is first formed, and which impart desirable structural and/or tensile properties to the final object. The photocurable compositions of the present invention may be comprised by Part A.

The following examples illustrate the invention without restricting it.

### EXAMPLES

### Example 1

Photocurable Composition 1

| Component | Compound | % by weight |
|---|---|---|
| (A1) | ACMO | 9-59 |
| (A2) | UCECOAT ® 6569 | 11-59 |
| (B1b) | Cyclic trimethylolpropane formal | 9-59 |
| | acrylate | |
| (C) | Photoinitiator | 0.5-5 |

### Example 2

Photocurable Composition 2

| Component | Compound | % by weight |
|---|---|---|
| (A1) | ACMO | 9-59 |
| (A1) | Polyethylene glycol (200) diacrylate | 0.9-39 |
| (A2) | UCECOAT ® 6569 | 11-59 |
| (B1a) | Trimethylolpropane triacrylate | 0.9-39 |
| (C) | Photoinitiator | 0.5-5 |

### Example 3

Photocurable Composition 3

| | | % by |
|---|---|---|
| Component | Compound | weight |
| (A1) | ACMO | 9-59 |
| (A2) | UCECOAT ® 6569 | 11-59 |
| (B1b) | Cyclic trimethylolpropane formal acrylate | 9-59 |
| (B1a) | Trimethylolpropane triacrylate (TMPTA) | 0.9-39 |
| (B1b) | Triethylene glycol dimethacrylate | 0.9-39 |
| | (TEGDMA) | |
| (C) | Photoinitiator | 0.5-5 |

### Example 4

Photocurable Composition 4

| | | % by |
|---|---|---|
| Component | Compound | weight |
| (A1) | ACMO | 9-59 |
| (A2) | UCECOAT ® 6569 | 11-59 |
| (B1b) | Cyclic trimethylolpropane formal acrylate | 9-59 |
| (B1a) | Trimethylolpropane triacrylate (TMPTA) | 0.9-39 |
| (A1) | Poly(ethylene glycol) diacrylate (average | 0.9-39 |
| | Mn 250; PEGDA250) | |
| (C) | Photoinitiator | 0.5-5 |

### Example 5

Photocurable Composition 5

| Component | Compound | % by weight |
|---|---|---|
| (A1) | N-vinyl-5-methyl oxazolidinone (NVMO) | 9-59 |
| (A2) | UCECOAT ® 6569 | 11-59 |
| (B2) | GENOMER ® 4247 (urethane methacrylate) | 0.9-29 |
| (B1b) | Triethylene glycol dimethacrylate | 0.9-29 |
| | (TEGDMA) | |
| (C) | Photoinitiator | 0.5-5 |

### Example 6

Photocurable Composition 6

| Component | Compound | % by weight |
|---|---|---|
| (A1) | N-vinyl-5-methyl oxazolidinone (NVMO) | 9-59 |
| (A2) | UCECOAT ® 6569 | 11-59 |
| (B2) | GENOMER ® 4247 (urethane methacrylate) | 0.9-29 |
| (B1a) | Trimethylolpropane triacrylate (TMPTA) | 0.9-29 |
| (B1a) | Ethoxylated (3) trimethylolpropane triacrylate | 0.9-29 |
| (C) | Photoinitiator | 0.5-5 |

### Example 7

Photocurable Composition 7

| Component | Compound | % by weight |
|---|---|---|
| (B1b) | 2-[[(Butylamino)carbonyl]oxy]ethyl acrylate | 0.9-9 |
| | (Genomer ® 1122) | |
| (A2) | UCECOAT ® 6569 | 11-59 |
| (B1b) | Cyclic trimethylolpropane formal acrylate | 9-59 |
| | (LR 8887) | |
| (B1a) | Trimethylolpropane triacrylate (TMPTA) | 0.9-29 |
| (B2) | GENOMER ® 4247 (urethane methacrylate) | 0.9-29 |
| (C) | Photoinitiator | 0.5-5 |

### Example 8

Photocurable Composition 8

| Component | Compound | % by weight |
|---|---|---|
| (A2) | UCECOAT® 6569 | 21-59 |
| (B1b) | Cyclic trimethylolpropane formal acrylate | 19-59 |
| | (LR 8887) | |
| (B1a) | Trimethylolpropane triacrylate (TMPTA) | 0.9-29 |
| (B2) | GENOMER ® 4247 (urethane | 0.9-29 |
| | methacrylate) | |
| (B2) | Ebecryl ® 4587 (urethane acrylate) | 0.9-29 |
| (C) | Photoinitiator | 0.5-5 |

### Example 9

Photocurable Composition 9

| | | % by |
|---|---|---|
| Component | Compound | weight |
| (A1) | N-Vinyl-caprolactam (NVC) | 9-59 |
| (A2) | UCECOAT ® 6569 | 11-59 |
| (B2) | GENOMER ® 4247 (urethane methacrylate) | 0.9-39 |
| (B2) | Ebecryl ® 4587 (urethane acrylate) | 0.9-59 |
| (C) | Photoinitiator | 0.5-5 |

Hot water having a temperature of less than 60° C. could improve the clearness after water washing, due to the solubility increase of slightly soluble monomers as well as the reduction of resin viscosity.

The cleaning liquid used is only pure water with no addition of organic solvent, alkali, acid, detergent, surfactant, absorbent or any extra chemicals to assist cleaning. The cleaning operation can be performed in various manners: apply heat, ultrasonic, different forms of different forms of water flow (static, vortex, shake, jet) etc.

After sufficient cleaning the surface of 3D printed object is dried by air completely before subjected to post-curing and further treatment(s).

Preparation of Inventive Photopolymers and Specimen for Mechanical Testing

The components of the photocurable compositions were mixed at a ratio as specified in Table 2 and 1.5 wt-% photoinitiator TPO by stirring at 70° C. for 30 minutes in a water bath using a 100 ml glass jar which was protected against daylight with aluminum foil. To start printing, the resulting clear mixtures were poured into the resin tank installed in MoonRay D75 DLP printer. The printing was conducted using the light source of 405 nm wavelength at the intensity of 3 mW/cm². The thickness of the layer being cured at each time of irradiation was 50 μm. Stl files of standard specimens sliced for the desired layer were created and imported to the DLP printer. Specimens for tensile test were printed in x-direction and specimens for impact test were printed in y-direction. After finishing printing the specimens were removed from the picker, wiped off residual resins, water washed according to the above-described approaches for 60 seconds and air-blow dried for 30 seconds to obtain the cleaned specimens, which were post-cured in the NextDent™ LC 3D Printbox (equipped with UV-A and blue lamps) for 40 minutes.

After storage for 24 hours at 50% relative humidity the mechanical properties of the specimen were tested according to DIN EN ISO 527-1 (specimen type 5A) using Zwick Roell 10 kN Pro Line and DIN EN ISO 180 using a Zwick Roell HIT pendulum impact tester B5113.300 (5.5 J pendulum).

The viscosities of the photopolymers were determined at 50° C. at 100 s⁻¹ shear rate using a cone/plate (60 mm diameter, 2° cone angle) rheometer (HR-1 Discovery, TA Instruments).

All UV doses were measured with a UV-Control 3CT, UV-technik meyer Gmbh.

| | Example | Example | | |
|---|---|---|---|---|
| | 9 | 10 | Example 11 | Example 12 |
| Component | Wt-% | Wt-% | Wt-% | Wt-% |
| ACMO (A1) | 39.4 | 32.9 | — | — |
| UCECOAT ® 6569 (A2) | 24.6 | 16.4 | 19.7 | 19.7 |
| Cyclic trimethylolpropane formal | 34.5 | 20.5 | — | 28.1 |
| acrylate (B1b) | | | | |
| Trimethylolpropane triacrylate | | 16.4 | — | 19.7 |
| (TMPTA) (B1a) | | | | |
| Poly(ethylene glycol) diacrylate | — | 12.3 | — | — |
| (average Mn 250; PEGDA250) | | | | |
| (A1) | | | | |
| N-Vinyl-caprolactam (NVC) (A1) | — | — | — | 21.2 |
| GENOMER ® 4247 (urethane | — | — | 19.7 | 9.8 |
| methacrylate) (B2) | | | | |
| N-vinyl-5-methyl oxazolidinone | | | 39.4 | |
| (NVMO) | | | | |
| Triethylene glycol dimethacrylate | | | 19.7 | |
| (TEGDMA) (B1b) | | | | |
| Omnirad ® TPO (C) | 1.50 | 1.50 | 1.5 | 1.50 |
| Total | 100.00 | 100.00 | 100 | 100.00 |
| Viscosity [mPas] at 25° C./100 s⁻¹ | 182 | 90 | 90 | 136¹⁾ |
| E modulus [MPa] | 1720 | 2660 | 2730 | 2430 |
| Tensile strength at break [MPa]²⁾ | 42 | 57 | 72 | 59 |
| Elongation at break [%] | 9.3 | 2.6 | 6.3 | 3.9 |
| Tg [° C.] ( by DMA tan delta)³⁾ | 73 | | 129 | |

¹⁾Viscosity [mPas] at 30° C./100 s⁻¹.
²⁾Determined according to ISO 527-5A.
3)Dynamic mechanical analysis using the dissipation peak to determine the glass transition temperature of cured resin.

After the 3D product is formed by using 3D-printer and the compositions of Examples 9 to 12, any uncured composition is removed by washing with water. That means, the 3D printed object is just rinsed and/or soaked in pure water at room temperature for a short period of time (in particular less than 5 minutes to prevent water absorption) to dissolve any uncured, or partly cured composition.

1.-17. (canceled)

18. A radiation curable composition, comprising
(A1) at least one water-soluble reactive diluent (A1);
(A2) at least one water-soluble reactive oligomer (A2);
(B) at least one reactive component selected from the group consisting of a water insoluble reactive diluent (B1a), a slightly water-soluble reactive diluent (B1b) and a water insoluble, or slightly water-soluble reactive oligomer (B2); and
(C) optionally a photoinitiator (C), wherein the amount of component (A1) and (A2) is greater than 20% by weight, especially 30% by weight based on the amount of components (A1), (A2), (B1a), (B1b) and (B2) and the amount of components (B1a), (B1b) and (B2) is greater than 10% by weight, especially 20% by weight based on the amount of components (A1), (A2), (B1a), (B1b) and (B2), or
a radiation curable composition, comprising
(A1′) at least one slightly water-soluble reactive diluent (B1b);
(A2) at least one water-soluble reactive oligomer (A2);
(B) at least one reactive component selected from the group consisting of a water insoluble reactive diluent (B1a) and a water insoluble, or slightly water-soluble reactive oligomer (B2); and
(C) optionally a photoinitiator (C), wherein the amount of component (B1b) and (A2) is greater than 40% by weight, especially 50% by weight based on the amount of components (A2), (B1a), (B1b) and (B2) and the amount of component (B1a) and (B2) is greater than 10% by weight, especially 20% by weight based on the amount of components (A2), (B1a), (B1b) and (B2).

19. The radiation curable composition according to claim 18, wherein the water-soluble reactive diluent (A1) is selected from
monofunctional (meth)acrylacrylamides,
N-vinyloxazolidinones of formula 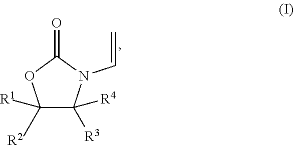
wherein
R₁, R², R³ and R⁴ are independently of each other a hydrogen atom or an organic group having not more than 10 carbon atoms; polyethylene glycol (200) diacrylate (PEG200DA), polyethylene glycol (400) diacrylate, N-vinyl-caprolactam (NVC), N-vinyl-pyrrolidone (NVP) and N-vinyl-imidazole (VIM).

20. The radiation curable composition according to claim 18, wherein the water-soluble reactive diluent (A1) is selected from acryloylmorpholine, polyethylene glycol (200) diacrylate, N-vinyl-caprolactam (NVC), N-vinyloxazolidinone, N-vinyl-5-methyl oxazolidinone and mixtures thereof.

21. The radiation curable composition according to claim 18, wherein the water soluble oligomer (A2) is a water soluble urethane (meth)acrylate, epoxy (meth)acrylate, polyester (meth)acrylate, (meth)acrylic (meth)acrylate, or a mixture thereof, especially a water-dilutable (meth)acrylated polyurethane which is obtained from the reaction of at least one polyisocyanate compound (i), at least one polyester polyol (vi) comprising at least one polyethylene glycol segment and at least one pendant hydrophilic group, and at least one (meth)acrylated compound (iv) containing at least one reactive group capable to react with isocyanate groups.

22. The radiation curable composition according to claim 18, wherein the water insoluble oligomer (B2) is selected from polyester acrylates, polyether acrylates, epoxy acrylates, urethane acrylates and urethane methacrylates.

23. The radiation curable composition according to claim 18, wherein the water insoluble oligomer (B2) is obtained by reacting
(b1) a hydroxyalkylacrylate, or hydroxyalkylmethacrylate,
(b2) an aliphatic diisocyanate, an aliphatic polyisocyanate, a cycloaliphatic diisocyanate, a cycloaliphatic polyisocyanate, an aromatic diisocyanate, or an aromatic polyisocyanate, or mixtures thereof,
(b3) a polyester polyol, which is derived from aliphatic dicarboxylic acids and aliphatic diols, and
(b4) optionally a secondary polyol.

24. The radiation curable composition according to claim 22, wherein the water insoluble oligomer (B2) is obtained by reacting a polyalkylene glycol with a lactone of formula 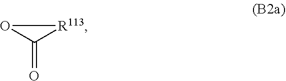
at least one cycloaliphatic or asymmetric aliphatic diisocyanate and an hydroxyalkyl(meth)acrylate, or by reacting a lactone of formula (B2a) with at least one cycloaliphatic or asymmetric aliphatic diisocyanate and an hydroxyalkyl(meth)acrylate, wherein R¹¹³ is a divalent alkylene radical having 1 to 12 carbon atoms and which may optionally be substituted by C₁ to C₄ alkyl groups and/or interrupted by one or more oxygen atoms.

25. The radiation curable composition according to claim 22, wherein the water insoluble oligomer (B2) is obtained by reacting aliphatic, aromatic, or cyclic diisocyanates with hydroxyalkyl(meth)acrylate.

26. The radiation curable composition according to claim 23, wherein the water-insoluble reactive diluent (B1a) is selected from adamantyl acrylate, 2-methyl-2-adamantyl acrylate, 2-ethyl-2-adamantyl acrylate, norbornyl (meth)acrylate, isobornyl (meth)acrylate, tetrahydrofurfuryl (meth)acrylate, cyclohexyl (meth)acrylate, cyclopentyl (meth)acrylate, cycloheptyl (meth)acrylate, cyclooctyl (meth)acrylate, cyclodecyl (meth)acrylate, dicyclodecyl (meth)acrylate, 3,3,5-trimethylcyclohexyl (meth)acrylate, 4-t-butylcyclohexyl (meth)acrylate, trimethylolpropane triacrylate (TMPTA), trimethylolpropane trimethacrylate (TMPTMA), trimethylolpropane ethoxy triacrylate (TMPEO3TA) and tricyclodecanedimethanol diacrylate.

27. The radiation curable composition according to claim 18, wherein the slightly water-soluble reactive diluent (B1b) is selected from cyclic trimethylolpropane formal acrylate, hydroxypropyl methacrylate, tripropylene glycol diacrylate, 2-[[(butylamino)carbonyl]oxy]ethyl acrylate and triethylene glycol dimethacrylate (TEGDMA).

28. The radiation curable composition according to claim 18,
which comprises

| Component | Compound | % by weight |
|---|---|---|
| (A1) | Acryloylmorpholine | 9-59 |
| (A2) | Water dilutable aliphatic urethane acrylate | 11-59 |
| (B1b) | Cyclic trimethylolpropane formal acrylate | 9-59 |
| (Q | Photoinitiator | 0.5-5 |
| | | % by |
|---|---|---|
| Component | Compound | weight |
| (A1) | Acryloylmorpholine | 9-59 |
| (A1) | Polyethylene glycol (200) diacrylate | 0.9-39 |
| (A2) | Water dilutable aliphatic urethane acrylate | 11-59 |
| (B1a) | Trimethylolpropane triacrylate | 0.9-39 |
| (C) | Photoinitiator | 0.5-5 |
| | | % by |
|---|---|---|
| Component | Compound | weight |
| (A1) | Acryloylmorpholine | 9-59 |
| (A2) | Water dilutable aliphatic urethane acrylate | 11-59 |
| (B1b) | Cyclic trimethylolpropane formal acrylate | 9-59 |
| (B1a) | Trimethylolpropane triacrylate | 0.9-39 |
| (B1b) | Triethylene glycol dimethacrylate | 0.9-39 |
| (C) | Photoinitiator | 0.5-5 |
| Component | Compound | % by weight |
|---|---|---|
| (A1) | Acryloylmorpholine | 9-59 |
| (A2) | Water dilutable aliphatic urethane acrylate | 11-59 |
| (B1b) | Cyclic trimethylolpropane formal acrylate | 9-59 |
| (B1a) | Trimethylolpropane triacrylate | 0.9-39 |
| (A1) | Poly(ethylene glycol) diacrylate (average Mn | 0.9-39 |
| | 250; PEGDA250) | |
| (C) | Photoinitiator | 0.5-5 |
| Component | Compound | % by weight |
|---|---|---|
| (A1) | N-vinyl-5-methyl oxazolidinone | 9-59 |
| (A2) | Water dilutable aliphatic urethane acrylate | 11-59 |
| (B2) | 2-functional aliphatic urethane methacrylate | 0.9-39 |
| (B1b) | Triethylene glycol dimethacrylate | 0.9-29 |
| (C) | Photoinitiator | 0.5-5 |
| Component | Compound | % by weight |
|---|---|---|
| (A1) | N-vinyl-5-methyl oxazolidinone | 9-59 |
| (A2) | Water dilutable aliphatic urethane acrylate | 11-59 |
| (B2) | Urethane methacrylate | 0.9-29 |
| (B1a) | Trimethylolpropane triacrylate | 0.9-29 |
| (B1a) | Ethoxylated (3) trimethylolpropane triacrylate | 0.9-29 |
| (C) | Photoinitiator | 0.5-5 |
| Component | Compound | % by weight |
|---|---|---|
| (B1b) | 2- [[(Butylamino)carbonyl]oxy]ethyl acrylate | 0.9-9 |
| (A2) | Water dilutable aliphatic urethane acrylate | 11-59 |
| (B1b) | Cyclic trimethylolpropane formal acrylate | 9-59 |
| (B1a) | Trimethylolpropane triacrylate | 0.9-29 |
| (B2) | Urethane methacrylate | 0.9-29 |
| (C) | Photoinitiator | 0.5-5 |
| Component | Compound | % by weight |
|---|---|---|
| (A2) | Water dilutable aliphatic urethane acrylate | 21-59 |
| (B1b) | Cyclic trimethylolpropane formal acrylate | 19-59 |
| (B1a) | Trimethylolpropane triacrylate | 0.9-29 |
| (B2) | Urethane methacrylate | 0.9-29 |
| (B2) | Urethane acrylate | 0.9-29 |
| (C) | Photoinitiator | 0.5-5 |
| Component | Compound | % by weight |
|---|---|---|
| (A1) | N-Vinyl-caprolactam | 9-59 |
| (A2) | Water dilutable aliphatic urethane acrylate | 11-59 |
| (B2) | Urethane methacrylate | 0.9-39 |
| (B2) | Urethane acrylate | 0.9-59 |
| (Q | Photoinitiator | 0.5-5 |

29. The radiation curable composition according to claim 18, wherein the photoinitiator (C) is a compound of the formula 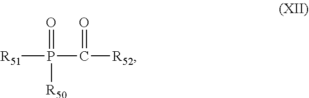
wherein
R₅₀ is unsubstituted cyclohexyl, cyclopentyl, phenyl, naphthyl or biphenylyl; or is cyclohexyl, cyclopentyl, phenyl, naphthyl or biphenylyl substituted by one or more halogen, C₁-C₁₂alkyl, C₁-C₁₂alkoxy, C₁-C₁₂alkylthio or by NR₅₃R₅₄,
or R₅₀ is unsubstituted C₁-C₂₀alkyl or is C₁-C₂₀alkyl which is substituted by one or more halogen, C₁-C₁₂alkoxy, C₁-C₁₂alkylthio, NR₅₃R₅₄ or by —(CO)—O—C₁-C₂₄alkyl;
R₅₁ is unsubstituted cyclohexyl, cyclopentyl, phenyl, naphthyl or biphenylyl; or is cyclohexyl, cyclopentyl, phenyl, naphthyl or biphenylyl substituted by one or more halogen, C₁-C₁₂alkyl, C₁-C₁₂alkoxy, C₁-C₁₂alkylthio or by NR₅₃R₅₄; or R₅₁ is —(CO)R′₅₂; or R⁵¹ is C₁-C₁₂alkyl which is unsubstituted or substituted by one or more halogen, C₁-C₁₂alkoxy, C₁-C₁₂alkylthio, or by NR₅₃R₅₄;
R₅₂ and R′₅₂ independently of each other are unsubstituted cyclohexyl, cyclopentyl, phenyl, naphthyl or biphenylyl, or are cyclohexyl, cyclopentyl, phenyl, naphthyl or biphenylyl substituted by one or more halogen, C₁-C₄alkyl or C₁-C₄alkoxy; or R₅₂ is a 5- or 6-membered heterocyclic ring comprising an S atom or N atom;
R₅₃ and R₅₄ independently of one another are hydrogen, unsubstituted C₁-C₁₂alkyl or C₁-C₁₂alkyl substituted by one or more OH or SH wherein the alkyl chain optionally is interrupted by one to four oxygen atoms; or R₅₃ and R₅₄ independently of one another are C₂-C₁₂-alkenyl, cyclopentyl, cyclohexyl, benzyl or phenyl, or the photoinitiator (C) is a mixture of a compound of the formula (XII) and a compound of the formula 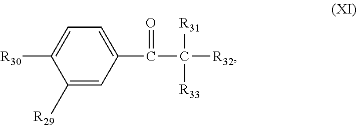
wherein
R₂₉ is hydrogen or C₁-C₁₈alkoxy;
R₃₀ is hydrogen, C₁-C₁₈alkyl, C₁-C₁₂hydroxyalkyl, C₁-C₁₈alkoxy, OCH₂CH₂—OR₃₄, morpholino, S—C₁-C₁₈alkyl, a group —HC═CH₂, —C(CH₃)═CH₂, 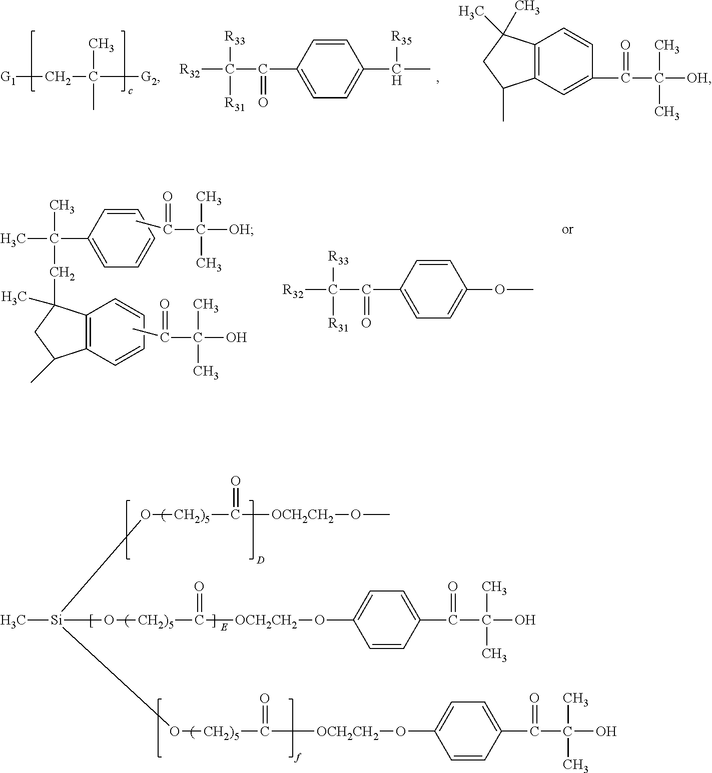
D, E and f are 1-3;
c is 2-10;
G₁ and G₂ independently of one another are end groups of the polymeric structure, preferably hydrogen or methyl;
R³⁴ is hydrogen, 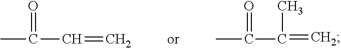
R³¹ is hydroxy, C₁-C₁₆alkoxy, morpholino, dimethylamino or —O(CH₂CH₂O)_{g}—C₁-C₁₆alkyl;
g is 1-20;
R³² and R³³ independently of one another are hydrogen, C₁-C₆alkyl, C₁-C₁₆alkoxy or —O(CH₂CH₂O)_{g}—C₁-C₁₆alkyl; or are unsubstituted phenyl or benzyl; or phenyl or benzyl substituted by C₁-C₁₂-alkyl; or R₃₂ and R₃₃ together with the carbon atom to which they are attached form a cyclohexyl ring;
R₃₅ is hydrogen, OR₃₆ or NR₃₇R₃₈;
R³⁶ is hydrogen, C₁-C₁₂alkyl which optionally is interrupted by one or more non-consecutive O-atoms and which uninterrupted or interrupted C₁-C₁₂alkyl optionally is substituted by one or more OH,
or R₃₆ is 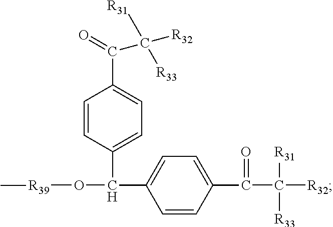
R₃₇ and R₃₈ independently of each other are hydrogen or C₁-C₁₂alkyl which is unsubstituted or is substituted by one or more OH;
R₃₉ is C₁-C₁₂alkylene which optionally is interrupted by one or more non-consecutive O, —(CO)—NH—C₁-C₁₂alkylene-NH—(CO)— or 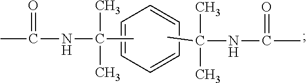
with the proviso that R₃₁, R₃₂ and R₃₃ not all together are C₁-C₁₆alkoxy or —O(CH₂CH₂O)_{g}—C₁-C₁₆alkyl, or the photoinitiator is a mixture of different compounds of the formula (XII), or the photoinitiator is a mixture of compounds of the formula (XII) and (XI).

30. Use of the radiation curable composition according to claim 18 in a photopolymerization 3D printing process, especially for producing dental molds.

31. Use according to claim 30, wherein the photopolymerization 3D printing process is vat photopolymerisation.

32. A method for producing a three-dimensional article, comprising
a) providing the radiation curable composition according to claim 18,
b) exposing the radiation curable composition to actinic radiation to form a cured crossection,
c) repeating steps (a) and (b) to build up a green three-dimensional article,
d) washing the three-dimensional article with pure water to remove the uncured, or partially cured components of the composition on the surfaces of the three-dimensional article; and
e) post-curing the three-dimensional article.

33. The method according to claim 32, comprising a vat photopolymerization, wherein the radiation curable composition according to claim 18 in step b) is cured directly onto a translated or rotated substrate, and the irradiation is patterned via stereolithography, holography, LCD, or digital light projection (DLP).

34. A three-dimensional article produced by the method according to claim 32, or a three-dimensional article, which is a cured product of the radiation curable composition according to claim 18.
